(19) United States
(12) Patent Application Publication
(10) Pub. No.: US 2014/0318697 A1
(43) Pub. Date: Oct. 30, 2014

(54) MANUFACTURING METHOD OF SEMICONDUCTOR DEVICE

(71) Applicant: FUJIFILM Corporation, Tokyo (JP)

(72) Inventors: Shiro TAN, Haibara-gun (JP); Kazuhiro FUJIMAKI, Haibara-gun (JP); Atsushi NAKAMURA, Haibara-gun (JP); Yu IWAI, Haibara-gun (JP); Ichiro KOYAMA, Haibara-gun (JP)

(73) Assignee: FUJIFILM CORPORATION, Tokyo (JP)

(21) Appl. No.: 14/328,191

(22) Filed: Jul. 10, 2014

Related U.S. Application Data
(63) Continuation of application No. PCT/JP2013/056381, filed on Mar. 1, 2013.

(30) Foreign Application Priority Data
Mar. 2, 2012 (JP) 2012-046855
Jun. 13, 2012 (JP) 2012-134187
Oct. 19, 2012 (JP) 2012-232417

(51) Int. Cl. H01L 21/673

(52) U.S. Cl. CPC H01L 21/673
USPC 156/247

(57) ABSTRACT

A method for manufacturing a semiconductor device with a treated member, includes: subjecting an adhesive support having a substrate and an adhesive layer capable of increasing or decreasing in adhesiveness upon irradiation with an actinic ray or radiation to pattern exposure of the adhesive layer to provide a high adhesive region and a low adhesive region in the adhesive layer, adhering a first surface of a to-be-treated member to the adhesive layer of the adhesive support, applying a mechanical or chemical treatment to a second surface different from the first surface of the to-be-treated member to obtain a treated member, and detaching the first surface of the treated member from the adhesive layer of the adhesive support.

### CROSS REFERENCE TO RELATED APPLICATION

This is a continuation of International Application No. PCT/JP2013/056381 filed on Mar. 1, 2013, and claims priority from Japanese Patent Application No. 2012-046855 filed on Mar. 2, 2012, Japanese Patent Application No. 2012-134187 filed on Jun. 13, 2012 and Japanese Patent Application No. 2012-232417 filed on Oct. 19, 2012, the entire disclosures of which are incorporated herein by reference.

### TECHNICAL FIELD

The present invention relates to a manufacturing method of a semiconductor device.

### BACKGROUND ART

Conventionally, in the process of producing a semiconductor device such as IC and LSI, a number of IC chips are usually formed on a semiconductor silicon wafer and individualized by dicing.

In response to needs for more size reduction and higher performance of an electronic device, the IC chip mounted in an electronic device is also required to satisfy more size reduction and higher density packaging, but the high density packaging of integrated circuits in the surface direction of a silicon substrate is reaching the near limit.

As to the method for establishing an electrical connection from an integrated circuit within an IC chip to an external terminal of the IC chip, a wire bonding method has been heretofore widely known, but in order to realize size reduction of an IC chip, a method of providing a through hole in a silicon substrate so that a metal plug as an external terminal can be passed through the through hole and thereby connected to an integrated circuit (a method of forming a so-called through-silicon via (TSV)) is recently known. However, only with the method of forming a through-silicon via, the recent needs for higher density packaging in an IC chip cannot be sufficiently responded.

In consideration of these things, a technique of fabricating multilayer integrated circuits within an IC chip and thereby increasing the integration degree per unit area of a silicon substrate is known. However, fabrication of multilayer integrated circuits increases the thickness of the IC chip, and thinning of a member constituting the IC chip is required. As to such thinning of a member, for example, thinning of a silicon substrate is being studied and this not only leads to size reduction of an IC chip but also enables labor saving in the step of forming a through hole in a silicon substrate at the production of a through-silicon via and therefore, is promising.

A wafer having a thickness of approximately from 700 to 900 μm is widely known as the semiconductor silicon wafer used in the process of producing a semiconductor device, but in recent years, for the purpose of achieving, for example, size reduction of an IC chip, an attempt is being made to reduce the thickness of the semiconductor silicon wafer to 200 μm or less.

However, the semiconductor silicon wafer having a thickness of 200 μm or less is very thin and in turn, a member for the production of a semiconductor device, which uses this wafer as the base material, is very thin, making it difficult to stably support the member without a damage, for example, when applying a further treatment to the member or merely moving the member.

In order to solve such a problem, there is known a technique of temporarily adhering an unthinned semiconductor wafer having provided on the surface a device to a supporting substrate for processing with a pressure-sensitive adhesive, grinding the back surface of the semiconductor wafer to achieve thinning, perforating the semiconductor wafer, providing a through-silicon via, and thereafter detaching the supporting substrate for processing from the semiconductor wafer (see, JP-A-2011-119427 (the term “JP-A” as used herein means an “unexamined published Japanese patent application”)). It suggested that according to this technique, all of grinding resistance at the back surface grinding of semiconductor wafer, heat resistance in an anisotropic dry etching step or the like, chemical resistance at the plating or etching, smooth separation from the final supporting substrate for processing, and low contamination for adherend can be satisfied at the same time.

Also, there is known a technique which is a tentative joining method for temporarily adhering a device surface of a device wafer having provided on the surface thereof a device to a carrier substrate for supporting the device wafer, wherein a packed layer not contributing to joining is interposed between the central region of the device surface and the carrier substrate and the marginal part of the device surface is temporarily adhered to the carrier substrate by edge bonding (see, JP-T-2011-510518 (the term “JP-T” as used herein means a published Japanese translation of a PCT patent application)). It is suggested that according to this technique, when separating the carrier substrate from the device wafer, the damage of the device wafer and the internal damage of the device can be reduced.

### SUMMARY OF INVENTION

In the case where a semiconductor wafer surface provided with a device (that is, the device surface of the device wafer) is temporarily adhered (temporarily bonded) to a supporting substrate (carrier substrate) through a layer composed of a pressure-sensitive adhesive known in JP-A-2011-119427 or the like, a certain high degree of tackiness is required of the pressure-sensitive adhesive layer so as to stably support the semiconductor wafer.

Therefore, in the case of temporarily adhering the entire device surface of the semiconductor wafer to the supporting substrate through a pressure-sensitive adhesive layer, as the temporary adhesion of the semiconductor wafer to the supporting substrate is made stronger so as to stably support the semiconductor wafer without causing damage, there is more readily caused a trouble that due to excessively strong temporary adhesion between the semiconductor wafer and the supporting substrate, at the time of detaching the semiconductor wafer from the supporting substrate, the device is damaged or the device is detached from the semiconductor wafer.

Also, in the method where, as in JP-T-2011-510518, the surface of the semiconductor wafer is divided into an adhesion region and a non-adhesion region and the member in the adhesion region, which is used as the layer interposed between the semiconductor wafer and the supporting substrate, is different from that in the non-adhesion region, for example, when grinding or polishing is applied to the back surface of the semiconductor wafer while keeping the semiconductor wafer surface and the supporting substrate in a temporarily adhering state, there arises a difference in the grinding pressure or polishing pressure between the back surface region on the back side of the adhesion region and the back surface region on the back side of the non-adhesion region, as a result, a difference is likely to be produced in the thickness of the semiconductor wafer. As thinning of the semiconductor wafer proceeds, the thickness difference in the semiconductor wafer becomes hard to ignore in view of quality of the finally obtained semiconductor device.

Under these circumstances, the present invention has been made, and an object of the present invention is to provide a manufacturing method of a semiconductor device, ensuring that a to-be-treated member (such as semiconductor wafer) can be temporarily supported in a reliable and easy manner while suppressing the effect on the treatment accuracy when applying a mechanical or chemical treatment to the to-be-treated member and at the same time, the temporary support for the treated member can be easily released without damaging the treated member.

The present inventors have made intensive studies to attain the above-described object, as a result, the present invention has been accomplished.

That is, a first configuration of the present invention is as follows.

A method for manufacturing a semiconductor device with a treated member, comprising:

a step of subjecting an adhesive support having a substrate and an adhesive layer capable of increasing or decreasing in the adhesiveness upon irradiation with an actinic ray or radiation to pattern exposure of the adhesive layer to provide a high adhesive region and a low adhesive region in the adhesive layer,

a step of adhering a first surface of a to-be-treated member to the adhesive layer of the adhesive support,

a step of applying a mechanical or chemical treatment to a second surface different from the first surface of the to-be-treated member to obtain a treated member, and

a step of detaching the first surface of the treated member from the adhesive layer of the adhesive support.

A second configuration of the present invention is as follows.

A method for manufacturing a semiconductor device with a treated member, comprising:

a step of preparing an adhesive support having a substrate and an adhesive layer in which a high adhesive region and a low adhesive region are provided to form a dot pattern,

a step of adhering a first surface of a to-be-treated member to the adhesive layer of the adhesive support,

a step of applying a mechanical or chemical treatment to a second surface different from the first surface of the to-be-treated member to obtain a treated member, and

a step of detaching the first surface of the treated member from the adhesive layer of the adhesive support.

In the case of applying a mechanical or chemical treatment to a to-be-treated member, the to-be-treated member must be stably supported so as to perform the desired treatment. Therefore, the adhesive force between the to-be-treated member and the adhesive support must be strong to an extent that it can withstand the treatment, albeit temporary adhesion.

On the other hand, if the adhesive force between the to-be-treated member and the adhesive support is too strong, the treated member can be hardly detached from the adhesive support or a trouble such as damage to the treated member is likely to be produced.

In this way, the adhesive force between the to-be-treated member and the adhesive support is required to be at a subtle degree.

According to the first configuration of the present invention, at the beginning, a high adhesive region and a low adhesive region are provided in the adhesive layer of the adhesive support by pattern exposure, where the contents of pattern in the pattern exposure can be easily changed, for example, by changing the kind of the mask in mask exposure or changing the lithography data in lithography exposure.

Also, the area and shape of each of the light-transmitting region and the light-shielding region in the mask or the shape of the image pattern drawn by lithography exposure can be controlled on the micron to nano order and therefore, the area and shape of each of the high adhesive region and the low adhesive region formed in the adhesive layer by pattern exposure can be finely controlled.

As a result, the adhesiveness as the entire adhesive layer can be easily controlled with high accuracy to such a degree of adhesiveness that the to-be-treated member can be temporarily supported without fail and the temporary support for the treated member can be easily released without damaging the treated member.

The high adhesive region and the low adhesive region in the adhesive support are caused to have different surface properties by pattern exposure but are integrated as a structure. Accordingly, there is no great difference in the mechanical properties between the high adhesive region and the low adhesive region and even when a first surface of a to-be-treated member is adhered to the adhesive layer of the adhesive support and subsequently, a second surface of the to-be-treated member is mechanically or chemically treated, the high and low adhesive regions in the adhesive layer of the present invention less affect the treatment accuracy in the mechanical or chemical treatment.

For these reasons, the manufacturing method of a semiconductor device can ensure that a to-be-treated member can be temporarily supported in a reliable and easy manner while suppressing the effect on the treatment accuracy when applying a mechanical or chemical treatment to the to-be-treated member and at the same time, the temporary support for the treated member can be easily released without damaging the treated member.

According to the second configuration of the present invention, a high adhesive region and a low adhesive region are provided in the adhesive layer of the adhesive support, and the high adhesive region and the low adhesive region form a dot pattern. Thanks to such a configuration, it is found that while keeping a good adhesive force in the horizontal direction with respect to the adhesion surface (the sliding direction between a to-be-treated member and the adhesive support), the low adhesive region triggers separation when the adhesive support is pulled in the direction perpendicular to the adhesive surface (the separation direction of the to-be-treated member from the adhesive support) and the separation is facilitated.

The method for creating high and low adhesive regions forming a dot pattern is not limited, but these regions can be produced by various printing methods. For example, there is a method of drawing a high adhesive region and a low adhesive region on a substrate by an inkjet method or a screen printing method by using a high-adhesiveness adhesive and a low-adhesiveness adhesive.

A method of providing a high adhesive region and a low adhesive region by dot-imagewise pattern exposure may be also used. This is a preferred method, because the contents of pattern in the dot-imagewise pattern exposure can be easy changed, as described above, by changing the kind of the mask in mask exposure or changing the lithography data in lithography exposure.

In the above-described methods to create high and low adhesive regions forming a dot pattern, the area and shape of each of the high and low adhesive regions created in the adhesive layer can be finely controlled (particularly, in the case of a method using pattern exposure, the area and shape of each of the light-transmitting region and the light-shielding region in the mask or the shape of the image pattern drawn by lithography exposure can be controlled on the micron to nano order).

As a result, the adhesiveness as the entire adhesive layer can be easily controlled with high accuracy to such a degree of adhesiveness that the to-be-treated member can be temporarily supported without fail and the temporary support for the treated member can be easily released without damaging the treated member.

The high and low adhesive regions forming a dot pattern have different surface properties but are substantially integrated as a structure by creating them, for example, based on the above-described representative methods. Accordingly, there is no great difference in the mechanical properties between the high adhesive region and the low adhesive region and even when a first surface of a to-be-treated member is adhered to the adhesive layer of the adhesive support and subsequently, a second surface of the to-be-treated member is mechanically or chemically treated, the high and low adhesive regions in the adhesive layer of the present invention less affect the treatment accuracy in the mechanical or chemical treatment.

For these reasons, the manufacturing method of a semiconductor device can ensure that a to-be-treated member can be temporarily supported in a reliable and easy manner while suppressing the effect on the treatment accuracy when applying a mechanical or chemical treatment to the to-be-treated member and at the same time, the temporary support for the treated member can be easily released without damaging the treated member.

According to the present invention, a manufacturing method of a semiconductor device, ensuring that a to-be-treated member can be temporarily supported in a reliable and easy manner while suppressing the effect on the treatment accuracy when applying a mechanical or chemical treatment to the to-be-treated member and at the same time, the temporary support for the treated member can be easily released without damaging the treated member, can be provided.

### BRIEF DESCRIPTION OF DRAWING

FIG. 1A is a schematic cross-sectional view explaining exposure applied to the adhesive support in the first embodiment of the present invention, and FIGS. 1B and 1C are, respectively, a schematic top view of the mask and a schematic top view of the adhesive support, which are used in the first embodiment of the present invention.

FIG. 2A is a schematic cross-sectional view showing one embodiment of the pattern-exposed adhesive support, FIG. 2B is a schematic cross-sectional view showing another embodiment of the pattern-exposed adhesive support, and FIG. 2C is a schematic top view of the pattern-exposed adhesive support.

FIGS. 3A and 3B are, respectively, a schematic cross-sectional view explaining temporary adhesion of the adhesive support to a device wafer and a schematic cross-sectional view showing the thinned state of the device wafer temporarily adhered by the adhesive support, in the first embodiment of the present invention.

FIGS. 4A, 4B, 4C and 4D are, respectively, a schematic cross-sectional view showing the state of the high adhesive region being removed from the adhesive support, a schematic cross-sectional view explaining a step of attaching a tape to a thin device wafer, a schematic cross-sectional view explaining a step of sliding the thin device wafer with respect to the adhesive support, and a schematic cross-sectional view explaining a step of separating the thin device wafer from the adhesive support, in the first embodiment of the present invention.

FIG. 5 is a schematic cross-sectional view explaining release of the temporarily adhered state between a conventional adhesive support and a device wafer.

FIGS. 6A, 6B and 6C are, respectively, a schematic top view of the device wafer, a schematic top view of the mask, and a schematic top view of the adhesive support, which are used in the second embodiment of the present invention.

FIGS. 7A, 7B, 7C, 7D, 7E and 7F are, respectively, a schematic perspective view explaining temporary adhesion of the adhesive support to a device wafer, a schematic perspective view showing the thinned state of the device wafer temporarily adhered by the adhesive support, a schematic perspective view explaining a step of sliding the thin device wafer with respect to the adhesive support, a schematic perspective view explaining a step of separating the thin device wafer from the adhesive support, and a schematic perspective view of the finally obtained thin device wafer, in the second embodiment of the present invention.

FIGS. 8A and 8B are, respectively, a schematic top view of the mask, and a schematic top view of the adhesive support, which are used in the third embodiment of the present invention.

FIGS. 9A, 9B and 9C are, respectively, a schematic perspective view explaining temporary adhesion of the adhesive support to a device wafer, a schematic perspective view showing the thinned state of the device wafer temporarily adhered by the adhesive support, and a schematic perspective view explaining a step of contacting an organic solvent with the outer edge part of the adhesive support, in the third embodiment of the present invention, and FIG. 9D is a schematic top-down view of the interface between the thin device wafer and the adhesive support in FIG. 9C.

FIGS. 10A, 10B, 10C and 10D are, respectively, a schematic cross-sectional view explaining temporary adhesion of the adhesive support to a device wafer with a protective layer, a schematic cross-sectional view showing the thinned state of the protective layer-attached device wafer temporarily adhered by the adhesive support, a schematic cross-sectional view showing the protective layer-attached thin device wafer separated from the adhesive support, and a schematic cross-sectional view showing the thin device wafer.

FIGS. 11A and 11B are, respectively, a schematic cross-sectional view explaining the thinned state of a device wafer temporarily adhered by the adhesive support, and a schematic cross-sectional view explaining the thinned state of a protective layer-attached device wafer temporarily adhered by the adhesive support.

FIG. 12 is a schematic cross-sectional view explaining temporary adhesion of the adhesive support to a device wafer in the embodiment of the present invention.

FIG. 13 is a schematic top view of the adhesive support in the fourth embodiment of the present invention.

FIG. 14 is a schematic cross-sectional view of the adhesive support test piece used in the measurement of adhesiveness.

### DESCRIPTION OF REFERENCE NUMERALS AND SIGNS

1, 2: Wafer
11, 11′, 21, 22, 23, 31, 32, 33: Adhesive layer
12: Carrier substrate
21A, 22A, 23A, 23B, 31A, 33A: Low adhesive region
21B, 22B, 23C, 31B, 33B: High adhesive region
40, 43, 46: Mask
41, 44, 47: Light-transmitting region
42, 45, 48, 49: Light-shielding region
50: Actinic ray or radiation
60, 64: Device wafer
60′, 64′: Thin device wafer
61, 61′: Silicon substrate
62: Device chip
63: Bump
70: Tape
80: Protective layer
90: First solvent-aided separation layer
91: Second solvent-aided separation layer
100, 100′, 110, 120: Adhesive support
160: Device wafer with protective layer
S: Organic solvent

### DESCRIPTION OF EMBODIMENTS

The embodiments of the present invention are described in detail below based on the drawings.

In the description of the present invention, the term “actinic ray” or “radiation” indicates, for example, a bright line spectrum of mercury lamp, a far ultraviolet ray typified by excimer laser, an extreme-ultraviolet ray (EUV light), an X-ray or an electron beam (EB). Also, in the present invention, the “light” means an actinic ray or radiation.

In the description of the present invention, unless otherwise indicated, the “exposure” encompasses not only exposure to a mercury lamp, a far ultraviolet ray typified by excimer laser, an X-ray, EUV light or the like but also lithography with a particle beam such as electron beam and ion beam.

Incidentally, in the embodiments described below, the member and the like described in the drawings already referred to are indicated by the same or like symbols in the figure and their description is simplified or omitted.

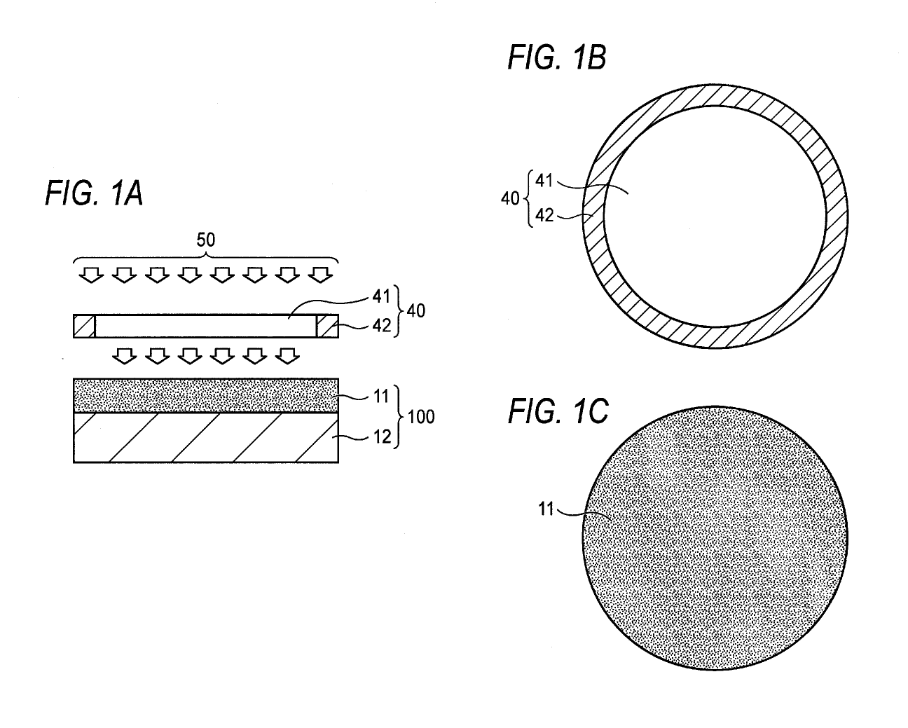

FIG. 1A is a schematic cross-sectional view explaining exposure applied to the adhesive support in the first embodiment of the present invention, and FIGS. 1B and 1C are, respectively, a schematic top view of the mask and a schematic top view of the adhesive support, which are used in the first embodiment of the present invention.

In the first embodiment of the present invention, as shown in FIGS. 1A and 1C, an adhesive support 100 obtained by providing an adhesive layer 11 on a carrier substrate 12 is first prepared.

The material for the carrier substrate 12 is not particularly limited, and examples thereof include a silicon substrate, a glass substrate, and a metal substrate. In view of causing less contamination of a silicon substrate that is typically used as the substrate of a semiconductor device or allowing use of an electrostatic chuck employed for general-purpose applications in the manufacturing step of a semiconductor device, the substrate is preferably a silicon substrate.

The thickness of the carrier substrate 12 is, for example, from 300 μm to 5 mm but is not particularly limited.

The adhesive layer 11 is an adhesive layer capable of decreasing in the adhesiveness upon irradiation with an actinic ray or radiation. Specifically, the adhesive layer 11 is a layer having adhesiveness before being irradiated with an actinic ray or radiation but is a layer capable of decreasing or losing the adhesiveness in the region irradiated with an actinic ray or radiation.

The adhesive layer 11 can be formed by coating an adhesive composition containing an adhesive capable of decreasing in the adhesiveness upon irradiation with an actinic ray or radiation and a solvent on the carrier substrate 12 by using, for example, a conventionally known spin coating method, spraying method, roller coating method, flow coating method, doctor coating method or dipping method, and drying it.

The thickness of the adhesive layer 11 is, for example, from 1 to 500 μm but is not particularly limited.

As for the adhesive capable of decreasing in the adhesiveness upon irradiation with an actinic ray or radiation, a known adhesive described, for example, in JP-A-2004-09738 can be used.

As for the solvent, known solvents can be used without limitation as long as the adhesive layer can be formed.

The adhesive composition may contain, if desired, optional components such as photopolymerization initiator, thermal polymerization initiator, release agent, surfactant, antioxidant and plasticizer, in addition to the adhesive and the solvent.

The adhesive composition which can form the adhesive layer 11 (that is, the adhesive layer capable of decreasing in the adhesiveness upon irradiation with an actinic ray or radiation) is described in detail later.

Subsequently, the adhesive layer 11 of the adhesive support 100 is irradiated with an actinic ray or radiation 50 (that is, exposed) through a mask 40.

As shown in FIGS. 1A and 1B, the mask 40 consists of a light-transmitting region 41 provided in the central region and a light-shielding region 42 provided in the peripheral region.

Accordingly, the above-described exposure is pattern exposure where the central region of the adhesive layer 11 is exposed but the peripheral region surrounding the central region is not exposed.

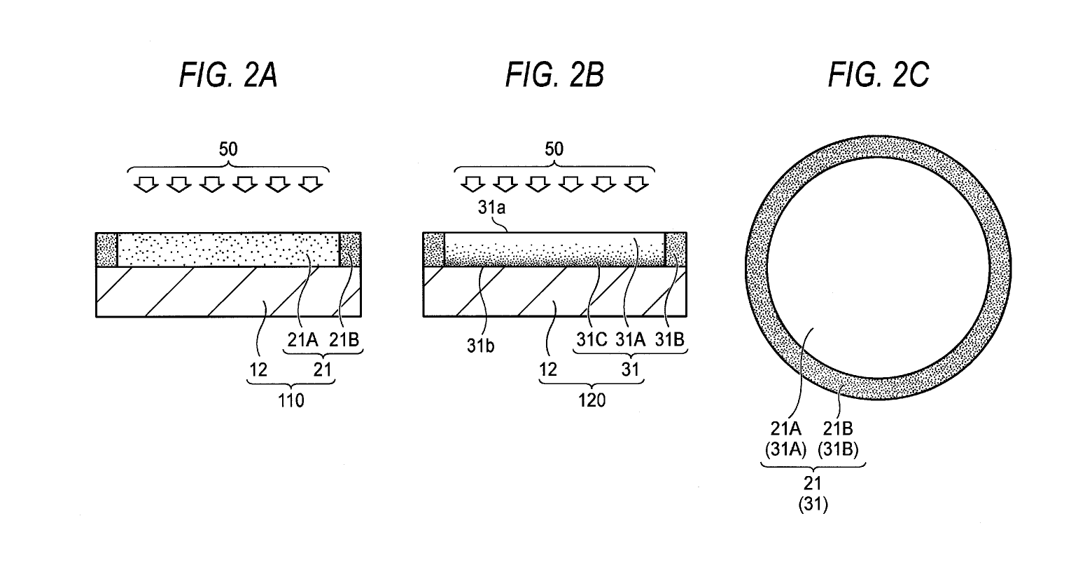

FIG. 2A is a schematic cross-sectional view showing one embodiment of the pattern-exposed adhesive support, FIG. 2B is a schematic cross-sectional view showing another embodiment of the pattern-exposed adhesive support, and FIG. 2C is a schematic top view of the pattern-exposed adhesive support according to the embodiment.

As described above, the adhesive layer 11 is an adhesive layer capable of decreasing in the adhesiveness upon irradiation with an actinic ray or radiation. Therefore, when the pattern exposure is performed, as shown in FIGS. 2A and 2C, the adhesive layer 11 is converted into an adhesive layer 21 where a low adhesive region 21A and a high adhesive region 21B are formed in the central region and the peripheral region, respectively.

The “low adhesive region” as used in the description of the present invention means a region having low adhesiveness as compared with the “high adhesive region” and encompasses a region having no adhesiveness (that is, a “non-adhesive region”). Similarly, the “high adhesive region” means a region having high adhesiveness as compared with the “low adhesive region”.

In the adhesive support 110 where an adhesive layer 21 is provided on a carrier substrate 12, exposure extends sufficiently from the surface layer part to the deep layer part of the adhesive layer 21, whereby in the exposed area of the adhesive layer 21, the low adhesive region 21A is formed over the entire area in the thickness direction.

On the other hand, as shown in FIGS. 2B and 2C, the low adhesive region 31A may be also formed by performing pattern exposure such that the adhesiveness of an adhesive layer 31 decreases toward the outer surface 31a from the inner surface 31b on the carrier substrate 12 side. Such an adhesive layer 31 can be easily formed by adjusting the exposure dose to sufficiently expose the surface layer part of the adhesive layer 31 but keep light from reaching the deep layer part.

In this embodiment, the adhesive layer 11 is converted into an adhesive layer 31 where a low adhesive region 31A is formed in the surface layer part of the central region and at the same time, a high adhesive region 31B and a high adhesive region 31C are formed in the peripheral region and the deep layer part of the central region, respectively.

In the first embodiment of the present invention, both an adhesive support 120 obtained by providing the adhesive layer 31 on the carrier substrate 12 and the above-described adhesive support 110 may be suitably used, but the adhesive support 120 is more preferred in many cases, because the adhesive layer 31 adheres to the carrier substrate 12 throughout the surface 31b in the carrier substrate direction and the adhesion of the adhesive layer 31 to the carrier substrate 12 results in a stronger adhesion.

For this reason, the following steps are described by using the adhesive support 120.

Temporary adhesion of the adhesive support obtained by pattern exposure to a device wafer, thinning of the device wafer, and detachment of the device wafer from the adhesive support are described in detail below.

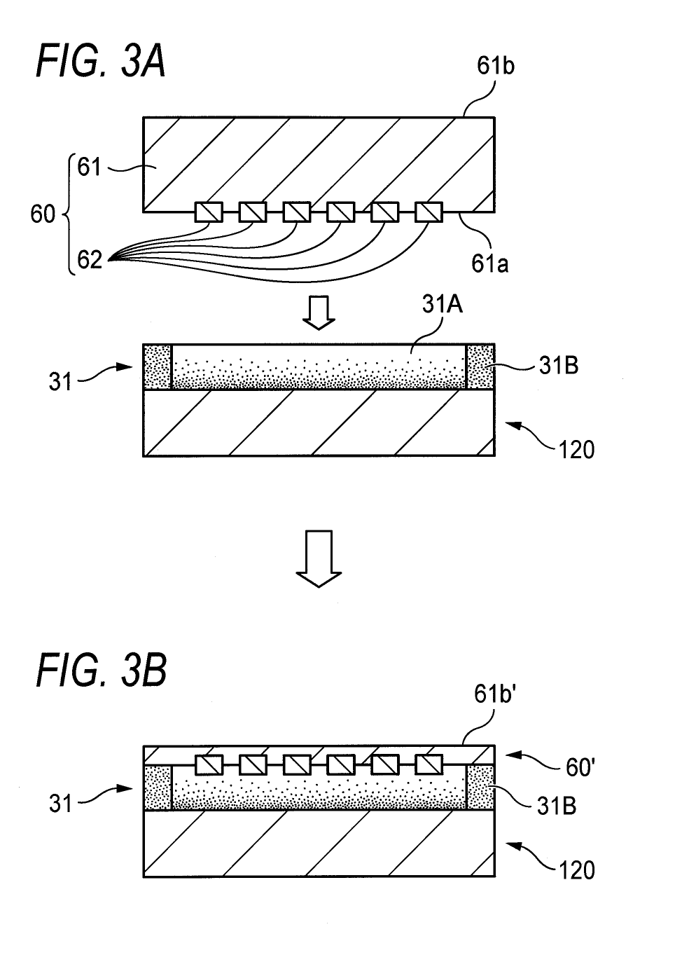

FIGS. 3A and 3B are, respectively, a schematic cross-sectional view explaining temporary adhesion of the adhesive support to a device wafer and a schematic cross-sectional view showing the thinned state of the device wafer temporarily adhered by the adhesive support, in the first embodiment of the present invention.

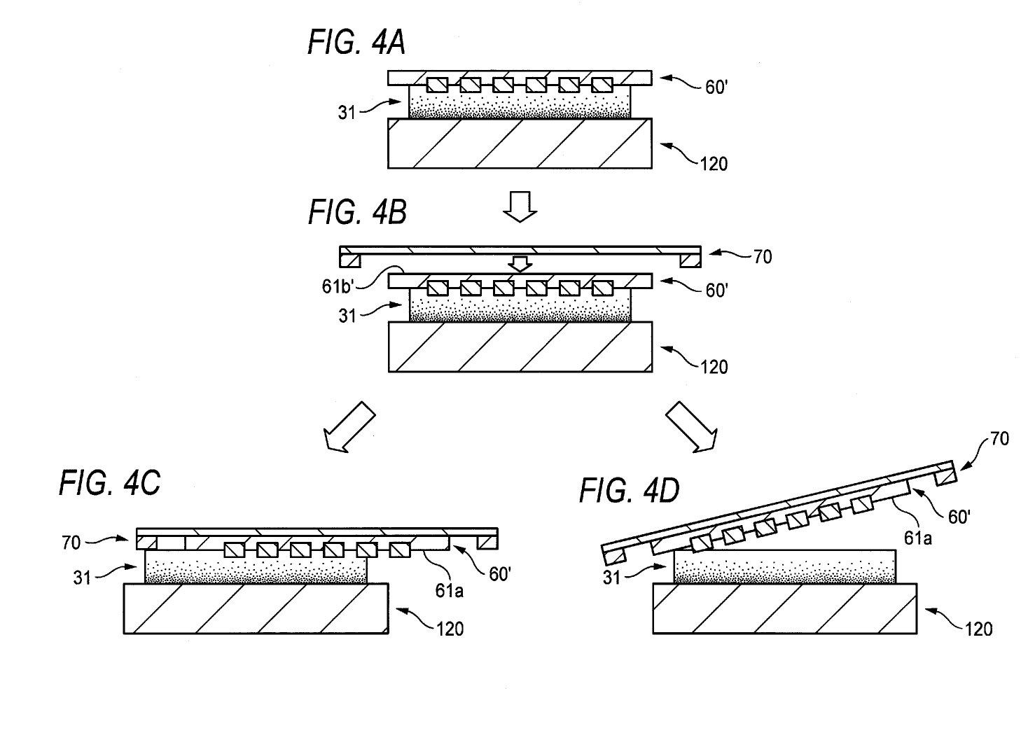

FIGS. 4A, 4B, 4C and 4D are, respectively, a schematic cross-sectional view showing the state of the high adhesive region being removed from the adhesive support, a schematic cross-sectional view explaining a step of attaching a tape to a thin device wafer, a schematic cross-sectional view explaining a step of sliding the thin device wafer with respect to the adhesive support, and a schematic cross-sectional view explaining a step of separating the thin device wafer from the adhesive support, in the first embodiment of the present invention.

As shown in FIG. 3A, a device wafer 60 (to-be-treated member) is obtained by providing a plurality of device chips 62 on a surface 61a of a silicon substrate 61.

Here, the thickness of the silicon substrate 61 is, for example, from 200 to 1,200 μm.

The surface 61a of the silicon substrate 61 is pressed against an adhesive layer 31 of an adhesive support 120, whereby the surface 61a of the silicon substrate 61 adheres to a high adhesive region 31B of the adhesive layer 31 to establish temporary adhesion of the adhesive support 120 to the device wafer 60.

At this time, the low adhesive region 31A of the adhesive layer 31 may not contribute to the temporary adhesion between the adhesive support 120 and the device wafer 60.

If desired, the adhesion assembly of the adhesive support 120 and the device wafer 60 may be thereafter heated to increase the adhesiveness.

Subsequently, a mechanical or chemical treatment, specifically, a thinning treatment such as grinding or chemical-mechanical polishing (CMP), is applied to the back surface 61b of the silicon substrate 61, whereby the thickness of the silicon substrate 61 is reduced (for example, to a thickness of 1 to 200 μm), as shown in FIG. 3B, to obtain a thin device wafer 60′.

As the mechanical or chemical treatment, a treatment of forming a through hole (not shown) penetrating the silicon substrate from the back surface 61b′ of the thin device wafer 60′ and further forming a through-silicon via (not shown) in the through hole may be performed, if desired, after the thinning treatment.

Thereafter, as shown in FIG. 4A, the high adhesive region 31B is removed from the adhesive support 120. The method for removing the high adhesive region 31B is not particularly limited, but preferred examples thereof include a method of dissolving and removing the high adhesive region 31B by contacting an organic solvent with the outer edge part of the adhesive layer 31.

By removing the high adhesive region 31B in this way, the subsequent detachment of the thin device wafer 60′ from the adhesive support 120 can be more facilitated.

Subsequently, a tape (for example, a dicing tape) 70 is attached to the back surface 61b′ of the thin device wafer 60′ as shown in FIG. 4B, and the thin device wafer 60′ is slid with respect to the adhesive support 120 as shown in FIG. 4C or the thin device wafer 60′ is separated from the adhesive support 120 as shown in FIG. 4D, whereby the surface 61a of the thin device wafer 60′ is detached from the adhesive layer 31 of the adhesive support 120.

If desired, various known treatments are thereafter applied to the thin device wafer 60′ to manufacture a semiconductor device having a thin device wafer 60′.

In the above-described embodiment, the high adhesive region 31B is removed from the adhesive support 120 as shown in FIGS. 4A to 4D, but as long as detaching of the thin device wafer 60′ from the adhesive support 120 is not inhibited, the surface 61a of the thin device wafer 60′ may be detached from the adhesive layer 31 of the adhesive support 120 without applying any treatment to the adhesive layer 31 of the adhesive support 120 (for example, without removing the high adhesive region 31B from the adhesive support 120).

A conventional embodiment is described below.

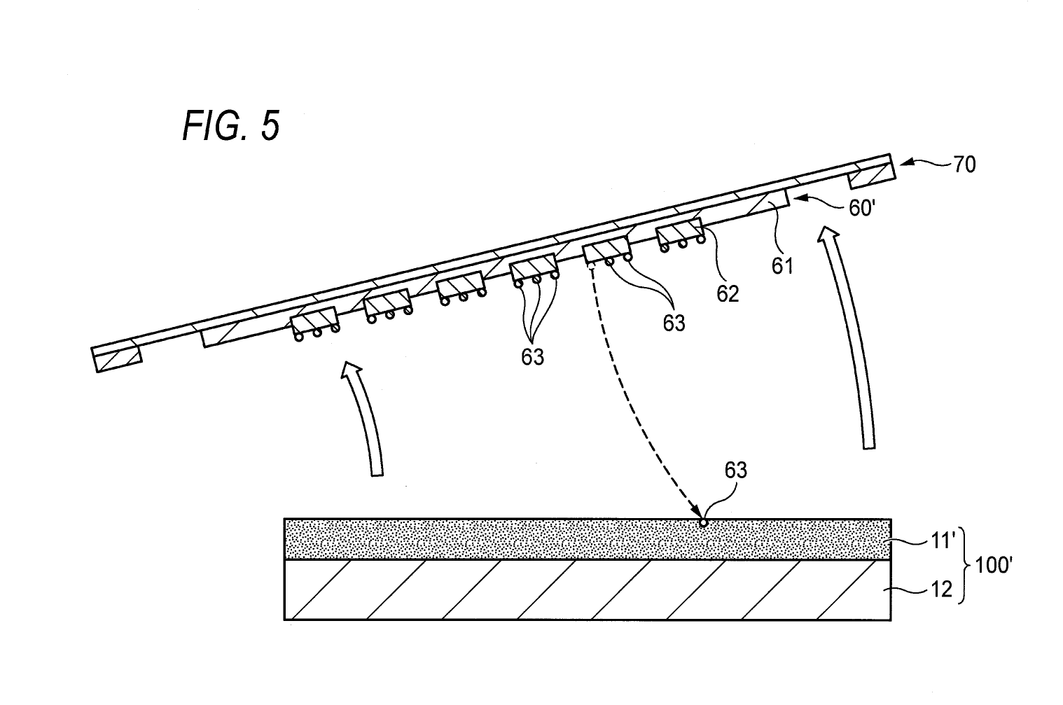

FIG. 5 is a schematic cross-sectional view explaining release of the temporarily adhered state between a conventional adhesive support and a device wafer.

In the conventional embodiment, as shown in FIG. 5, except for using, as the adhesive support, an adhesive support 100′ obtained by providing a normal adhesive layer 11′ with no photosensitivity on a carrier substrate 12, temporary adhesion of the adhesive support 100′ to a device wafer and a thinning treatment of the silicon substrate in the device wafer are performed by the same procedure as that described with reference to FIGS. 3A and 3B, and a thin device wafer 60′ is separated from the adhesive support 100′ by the same procedure as that described with reference to FIGS. 4B and 4D.

However, as the temporary adhesion of the device wafer to the carrier substrate is made stronger so as to stably support the semiconductor wafer without causing damage, there is more readily caused a trouble that due to excessively strong temporary adhesion between the device wafer and the carrier substrate, as shown in FIG. 5, at the time of detaching the thin device wafer 60′ from the carrier substrate 100′, for example, a device chip 62 having provided thereon a bump 63 is damaged resulting from detachment of the bump 63 from the device chip 62.

On the other hand, in the above-described embodiment of the present invention, both the adhesive support 110 and the adhesive support 120 have a low adhesive region 21A or 31A and a high adhesive region 21B or 31B which are provided by pattern exposure using a mask 40. The area and shape of each of the light-transmitting region and the light-shielding region in the mask 40 can be controlled on the micron to nano order and therefore, the area, shape and the like of each of the high adhesive region 21B or 31B and the low adhesive region 21A or 31A, which are formed in the adhesive layer 21 or 31 of the adhesive support 110 or 120 by pattern exposure, can be finely controlled, as a result, the adhesiveness as the entire adhesive layer can be easily controlled with high accuracy to such a degree of adhesiveness that the silicon substrate 61 of the device wafer 60 can be temporarily supported without fail and the temporary support for the silicon substrate of the thin device wafer 60′ can be easily released without damaging the thin device wafer 60′.

The high adhesive region 21B or 31B and the low adhesive region 21A or 31A in the adhesive support 110 or 120 are caused to have different surface properties by pattern exposure but are integrated as a structure. Accordingly, there is no great difference in the mechanical properties between the high adhesive region 21B or 31B and the low adhesive region 21A or 31A and even when the surface 61a of the silicon substrate 61 of the device wafer 60 is adhered to the adhesive layer 21 or 31 of the adhesive support 110 or 120 and subsequently, the back surface 61b of the silicon substrate 61 is subjected to a thinning treatment or a treatment of forming a through-silicon via, there can hardly arise a difference in the treatment pressure (for example, a grinding pressure or a polishing pressure) between the back surface 61b region corresponding to the high adhesive region 21B or 31B of the adhesive layer 21 or 31 and the back surface 61b region corresponding to the low adhesive region 21A or 31A, lessening the effect of the high adhesive region 21B or 31B and the low adhesive region 21A or 31A on the treatment accuracy in the treatment. This is effective particularly in the case of obtaining, for example, a thin device wafer 60′ having a thickness of 1 to 200 μm, which is likely to involve the above-described problem.

For these reasons, according to the first embodiment of the present invention, the silicon substrate 61 can be temporarily supported in a reliable and easy manner while suppressing the effect on the treatment accuracy when applying the above-described treatment to the silicon substrate 61 of the device wafer 60 and at the same time, the temporary support for the thin device wafer 60′ can be easily released without damaging the thin device wafer 60′.

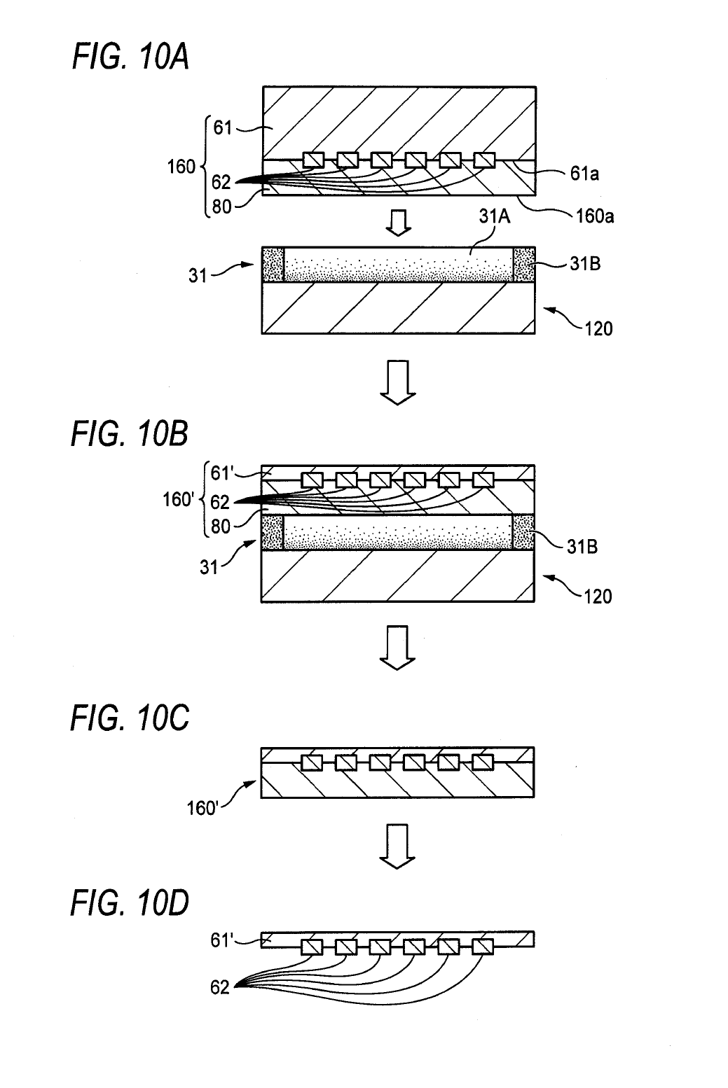

FIGS. 10A, 10B, 10C and 10D are, respectively, a schematic cross-sectional view explaining temporary adhesion of the adhesive support to a device wafer with a protective layer, a schematic cross-sectional view showing the thinned state of the protective layer-attached device wafer temporarily adhered by the adhesive support, a schematic cross-sectional view showing the protective layer-attached thin device wafer separated from the adhesive support, and a schematic cross-sectional view showing the thin device wafer.

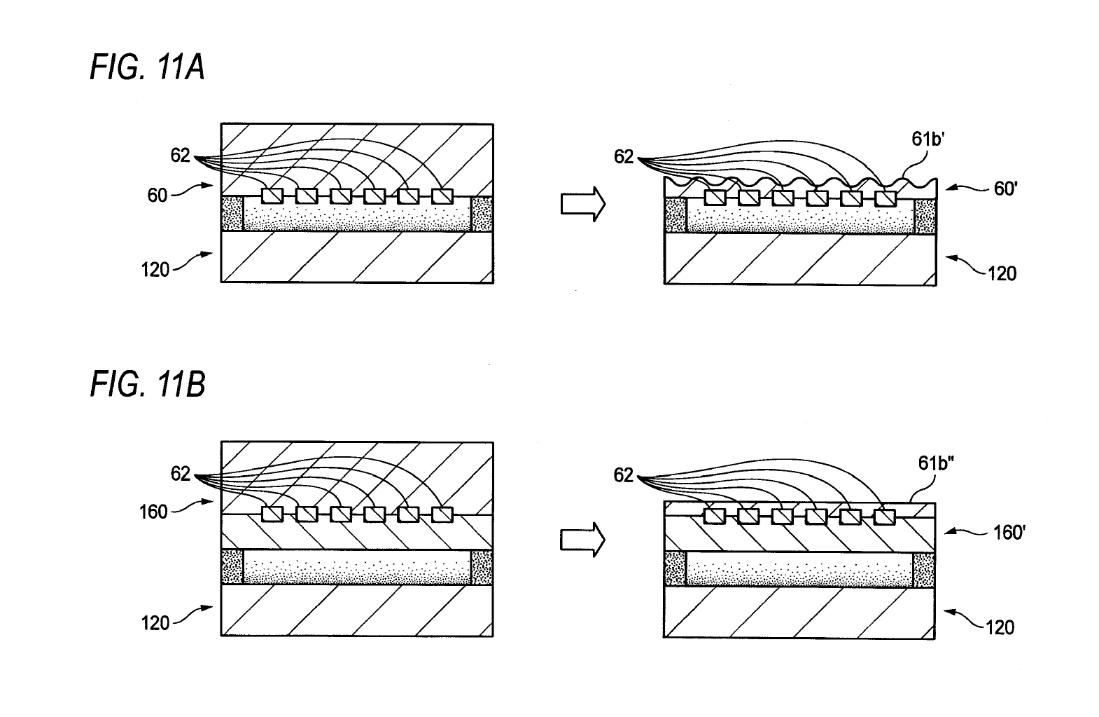

FIGS. 11A and 11B are, respectively, a schematic cross-sectional view explaining the thinned state of a device wafer temporarily adhered by the adhesive support, and a schematic cross-sectional view explaining the thinned state of a protective layer-attached device wafer temporarily adhered by the adhesive support.

In the first embodiment of the present invention, as shown in FIG. 10A, a protective layer-attached device wafer 160 (untreated member) may be used in place of the device wafer 60.

Here, the protective layer-attached device wafer 160 has a silicon substrate 61 (to-be-treated base material) having provided on the surface 61a thereof a plurality of device chips 62 and a protective layer 80 that is provided on the surface 61a of the silicon substrate 61 and protects the device chips 62.

The thickness of the protective layer 80 is, for example, from 1 to 1,000 μm.

As for the protective layer 80, known materials may be used without limitation, but a material capable of unfailingly protecting the device chip 62 is preferred.

Examples of the material constituting the protective layer 80 include a synthetic resin such as terpene resin, terpene phenol resin, modified terpene resin, hydrogenated terpene resin, hydrogenated terpene phenol resin, rosin, rosin ester, hydrogenated rosin, hydrogenated rosin ester, polymerized rosin, polymerized rosin ester, modified rosin, rosin-modified phenol resin, alkyl phenol resin, aliphatic petroleum resin, aromatic petroleum resin, hydrogenated petroleum resin, modified petroleum resin, alicyclic petroleum resin, coumarone petroleum resin, indene petroleum resin, olefin copolymer (e.g., methyl pentene copolymer), cycloolefin copolymer (e.g., norbornene copolymer, dicyclopentadiene copolymer, tetracyclododecene copolymer), novolak resin, phenol resin, epoxy resin, melamine resin, urea resin, unsaturated polyester resin, alkyd resin polyurethane, polyimide, polyethylene, polypropylene, polyvinyl chloride, polystyrene, polyvinyl acetate, Teflon (registered trademark), ABS resin, AS resin, acrylic resin, cellulose resin, polyamide, polyacetal, polycarbonate, polyphenylene ether, polybutylene terephthalate, polyethylene terephthalate, cyclic polyolefin, polyphenylene sulfide, polysulfone, polyethersulfone, polyarylate, polyether ether ketone and polyamideimide, and a natural resin such as natural rubber. Among these, a cellulose resin, a terpene resin, a polyimide, an acrylic resin and a polyamide are preferred, a polyimide and a polyamide are more preferred, and a polyimide is most preferred.

The protective layer may be constructed by combining two or more of these resins.

A surface 160a (a protective layer 80 surface opposite the silicon substrate 61) of the protective layer-attached device wafer 160 is pressed against an adhesive layer 31 of an adhesive support 120, whereby the surface 160a of the protective layer-attached device wafer 160 adheres to a high adhesive region 31B of the adhesive layer 31 to establish temporary adhesion of the adhesive support 120 to the device wafer 60.

Subsequently, similarly to the above, the thickness of the silicon substrate 61 is reduced (for example, to form a silicon substrate 61′ having a thickness of 1 to 200 μm) as shown in FIG. 10B to obtain a protective layer-attached thin device wafer 160′.

Thereafter, similarly to the above, the surface 160a of the protective layer-attached thin device wafer 160′ is detached from the adhesive layer 31 of the adhesive support 120 to obtain a protective layer-attached thin device wafer 160′ as shown in FIG. 10C.

Furthermore, the protective layer 80 in the protective layer-attached thin device wafer 160′ is removed from the silicon substrate 61′ and the device chip 62 to obtain, as shown in FIG. 10D, a thin device wafer where device chips 62 are provided on a silicon substrate 61′.

For the removal of the protective layer 80, all known methods may be employed, but examples thereof include (1) a method of dissolving and removing the protective layer 80 with a solvent; (2) a method of attaching a release tape or the like to the protective layer 80 and mechanically separating the protective layer 80 from the silicon substrate 61′ and the device chip 62; and (3) a method of subjecting the protective layer 80 to exposure to light such as ultraviolet ray and infrared ray or irradiation with a laser, thereby decomposing the protective layer 80 or enhancing the releasability of the protective layer 80.

The methods (1) and (3) are advantageous in that the action of the method extends over the entire surface of the protective film and therefore, removal of the protective layer 80 is facilitated.

The method (2) can be advantageously performed at room temperature without requiring any special apparatus.

The embodiment using, as the to-be-treated member, a protective layer-attached device wafer 160 in place of a device wafer 60 is effective when attempting to more reduce TTV (Total Thickness Variation) of a thin device wafer obtained by thinning the device wafer 60 temporarily adhered by the adhesive support 120 (that is, when attempting to more enhance the flatness of the thin device wafer).

More specifically, in the case of thinning the device wafer 60 temporarily adhered by the adhesive support 120, as shown in FIG. 11A, the uneven profile of the device wafer 60, which is created by a plurality of device chips 62, tends to be transferred to the back surface 61b′ of the thin device wafer 60′ and may work out to a TTV-increasing factor.

On the other hand, in the case of thinning the protective layer-attached device wafer 160 temporarily adhered by the adhesive support 120, as shown in FIG. 11B, a plurality of device chips 62 are protected by a protective layer and therefore, the uneven profile can be substantially eliminated on the contact surface of the protective layer-attached device wafer 160 with the adhesive support 120. Accordingly, even when such a protective layer-attached device wafer 160 is thinned in the state of being supported by the adhesive support 120, the profile attributable to a plurality of device chips 62 is less likely to be transferred to the back surface 61b″ of the protective layer-attached thin device wafer 160′, as a result, TTV of the finally obtained thin device wafer can be more reduced.

The second embodiment of the present invention is described below.

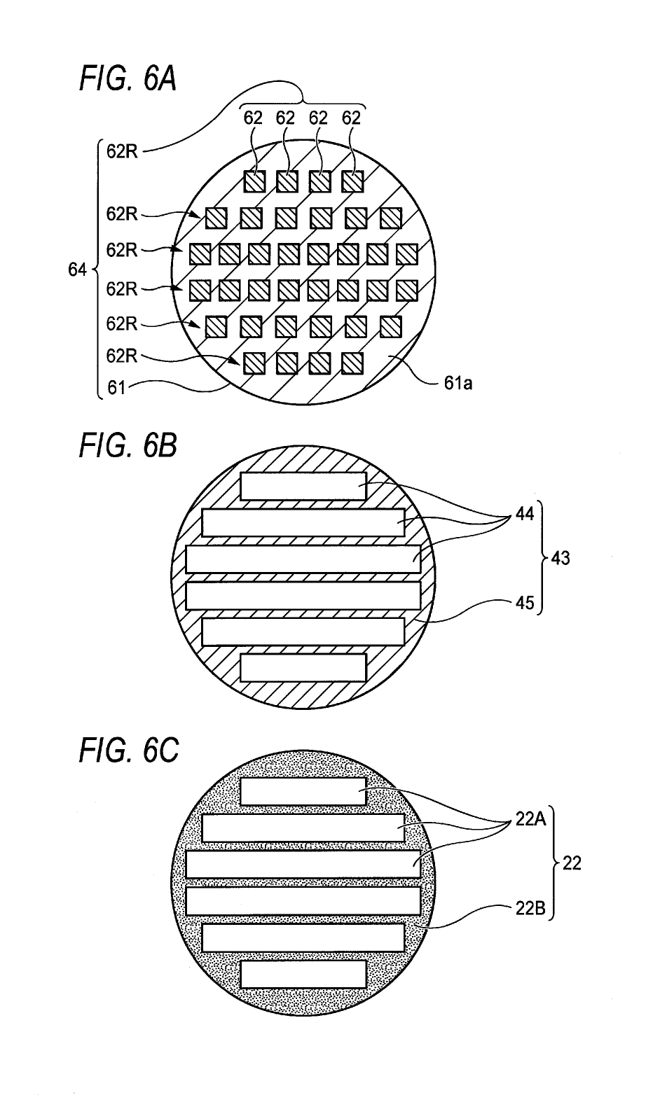

FIGS. 6A, 6B and 6C are, respectively, a schematic top view of the device wafer, a schematic top view of the mask, and a schematic top view of the adhesive support, which are used in the second embodiment of the present invention.

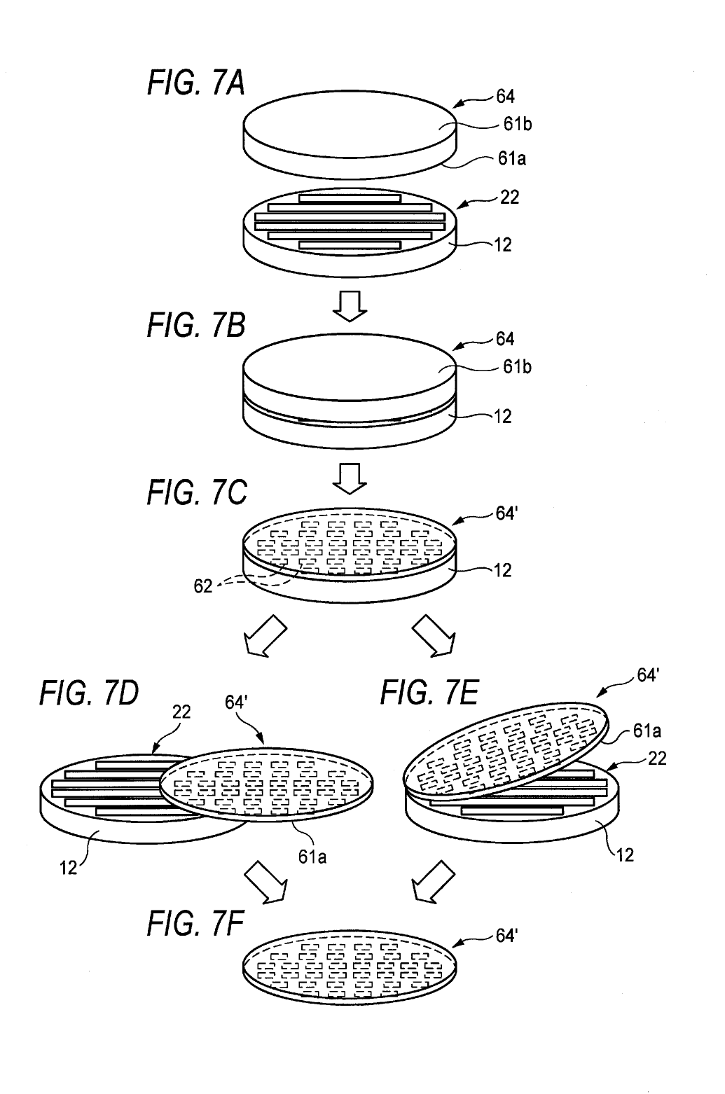

FIGS. 7A, 7B, 7C, 7D, 7E and 7F are, respectively; a schematic perspective view explaining temporary adhesion of the adhesive support to a device wafer, a schematic perspective view showing the thinned state of the device wafer temporarily adhered by the adhesive support, a schematic perspective view explaining a step of sliding the thin device wafer with respect to the adhesive support, a schematic perspective view explaining a step of separating the thin device wafer from the adhesive support, and a schematic perspective view of the finally obtained thin device wafer, in the second embodiment of the present invention.

As shown in FIG. 6A, the device wafer 64 (to-be-treated member) used in the second embodiment of the present invention is obtained by providing a plurality of device chips 62 on a surface 61a of a silicon substrate 61. More specifically, device chip rows 62R each formed by arranging a plurality of device chips 62 in the row direction are further arranged in the column direction.

Also, as shown in FIG. 6B, the mask 43 used in the second embodiment of the present invention consists of a plurality of belt-like light-transmitting regions 44 arranged in the column direction and a light-shielding region 45 except for the light-transmitting regions 44.

The adhesive layer 11 of the adhesive support 100 is irradiated with an actinic ray or radiation 50 (that is, exposed) through the mask 43.

Accordingly, the above-described exposure is pattern exposure where in the adhesive layer 11, a first region composed of a plurality of belt-like regions, corresponding to the light-transmitting region 44 in the mask 43, is exposed but a second region different from the first region is not exposed. Here, the first region composed of a plurality of belt-like regions in the adhesive layer 11 is determined to correspond to the arraying position (arranged position) of the device chip row 62R in the device wafer 64.

By performing the above-described pattern exposure, the adhesive layer 11 is converted into an adhesive layer 22 where, as shown in FIG. 6C, a low adhesive region 22A is formed in the first region composed of a plurality of belt-like regions and a high adhesive region 22B is formed in the second region different from the first region.

Subsequently, as shown in FIGS. 7A and 7B, the surface 61a of the silicon substrate 61 is pressed against the adhesive layer 22 of the adhesive support such that the device chip row 62R is put into contact with the first region of the adhesive layer 11, that is, the low adhesive region 22A, whereby the surface 61a of the silicon substrate 61 adheres to the high adhesive region 22B of the adhesive layer 22 to establish temporary adhesion of the adhesive support to a device wafer 64.

At this time, the low adhesive region 22A of the adhesive layer 22 may not contribute to the temporary adhesion between the adhesive support and the device wafer 64.

If desired, the adhesion assembly of the adhesive support and the device wafer 64 may be thereafter heated to increase the adhesiveness.

As the to-be-treated member, a protective layer-attached device wafer (not shown) where the above-described protective layer 80 is provided on the surface 61a of the silicon substrate 61 so as to protect the device chip row 62R in the device wafer 64 may be used in place of the device wafer 64.

Subsequently, as shown in FIG. 7C, the same thinning treatment as that described in the first embodiment is applied to the back surface 61b of the silicon substrate 61, whereby the thickness of the silicon substrate 61 is reduced (for example, to a thickness of 1 to 200 μm) to obtain a thin device wafer 64′.

Similarly to the first embodiment, as the mechanical or chemical treatment, a treatment of forming a through hole (not shown) penetrating the silicon substrate from the back surface of the thin device wafer 64′ and further forming a through-silicon via (not shown) in the through hole may be performed, if desired, after the thinning treatment.

Thereafter, for example, similarly to the first embodiment, a tape is attached to the back surface of the thin device wafer 64′, and the thin device wafer 64′ is slid with respect to the adhesive support as shown in FIG. 7D or the thin device wafer 64′ is separated from the adhesive support as shown in FIG. 7E, whereby the surface 61a of the thin device wafer 64′ is detached from the adhesive layer 22 of the adhesive support to obtain a thin device wafer 64′ shown in FIG. 7F.

If desired, similarly to the first embodiment, various known treatments are thereafter applied to the thin device wafer 64′ to manufacture a semiconductor device having a thin device wafer 64′.

As described above, according to the second embodiment of the present invention, a low adhesive region 22A is provided in the adhesive layer 22 of the adhesive support to correspond to the arranged position of the device chip 62 in the device wafer 64. Therefore, the region of the adhesive layer 22, not corresponding to the arranged position of the device chip 62, can serve as a high adhesive region and in turn, the contact area between the device wafer 64 and the adhesive support can be adequately ensured, as a result, the device wafer 64 can be temporarily supported by the adhesive support in a more reliable manner. On the other hand, in this temporarily supported state, the device chip 62 is contacted with the low adhesive region 22A of the adhesive layer 22, so that when detaching a thin device wafer 64′ from the adhesive support after applying a mechanical or chemical treatment such as thinning treatment to the device wafer 64, the risk of damaging the thin device wafer 64′ can be more reduced.

The third embodiment of the present invention is described below.

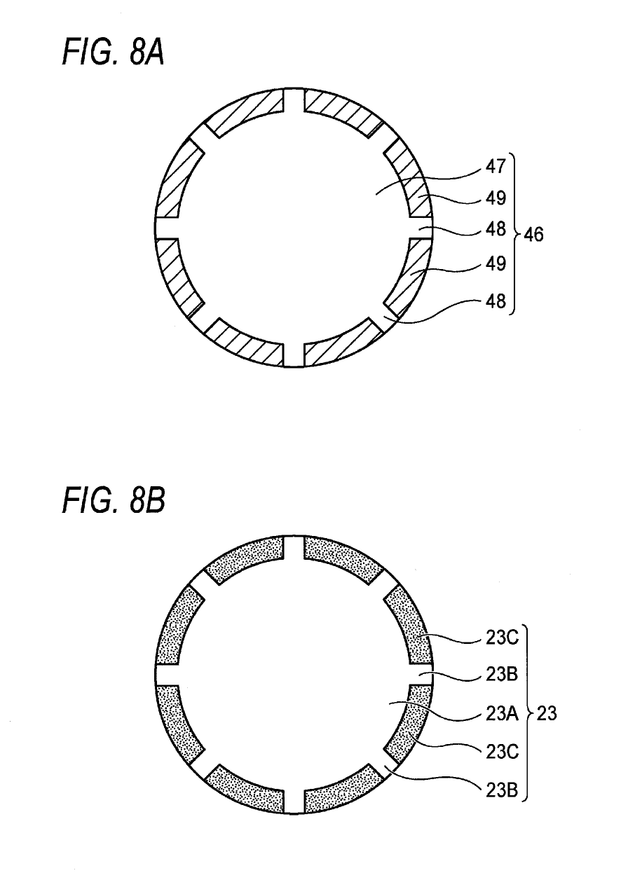

FIGS. 8A and 8B are, respectively, a schematic top view of the mask, and a schematic top view of the adhesive support, which are used in the third embodiment of the present invention.

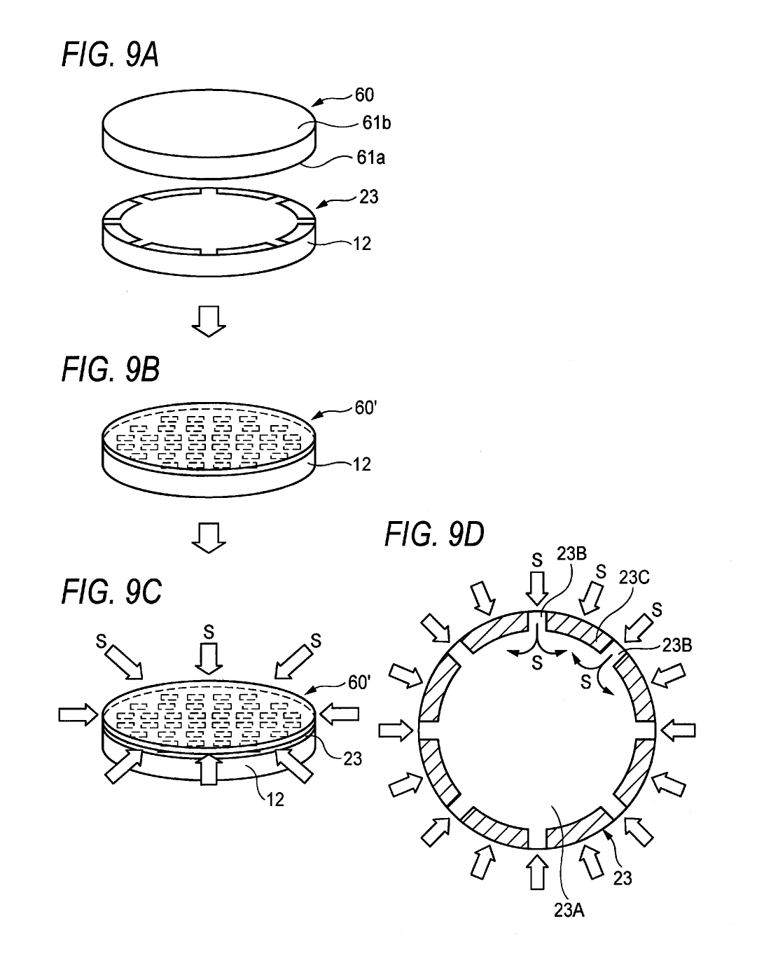

FIGS. 9A, 9B and 9C are, respectively, a schematic perspective view explaining temporary adhesion of the adhesive support to a device wafer, a schematic perspective view showing the thinned state of the device wafer temporarily adhered by the adhesive support, and a schematic perspective view explaining a step of contacting an organic solvent with the outer edge part of the adhesive support, in the third embodiment of the present invention, and FIG. 9D is a schematic top-down view of the interface between the thin device wafer and the adhesive support in FIG. 9C.

As shown in FIG. 8A, the mask 46 used in the third embodiment of the present invention consists of a light-transmitting region 47 provided in the central region, a plurality of light-transmitting regions 48, and a plurality of light-shielding regions 49. The plurality of light-transmitting regions 48 and the plurality of light-shielding regions 49 are provided to surround the light-transmitting region 47 and at the same time, alternately arrange a light-transmitting region 48 and a light-shielding region 49.

The adhesive layer 11 of the adhesive support 100 is irradiated with an actinic ray or radiation 50 (that is, exposed) through the mask 46.

Accordingly, the above-described exposure is pattern exposure where in the adhesive layer 11, a first region corresponding to the light-transmitting regions 47 and 48 in the mask 43 is exposed but a second region different from the first region is not exposed.

By performing the above-described pattern exposure, the adhesive layer 11 is converted into an adhesive layer 23 where, as shown in FIG. 8B, low adhesive regions 23A and 23B are formed, respectively, in the central region and a plurality of first peripheral regions surrounding the central region and a high adhesive region 23C is formed in the second region surrounding the central region and differing from the plurality of first peripheral regions.

Subsequently, as shown in FIG. 9A, the surface 61a of the silicon substrate 61 is pressed against the adhesive layer 23 of the adhesive support, whereby the surface 61a of the silicon substrate 61 adheres to the high adhesive region 23C of the adhesive layer 23 to establish temporary adhesion of the adhesive support to a device wafer 60 (to-be-treated member).

As the to-be-treated member, the above-described protective layer-attached device wafer 160 may be used in place of the device wafer 60.

If desired, the adhesion assembly of the adhesive support and the device wafer 60 may be thereafter heated to increase the adhesiveness.

Subsequently, as shown in FIG. 9B, the same thinning treatment as that described in the first embodiment is applied to the back surface 61b of the silicon substrate 61, whereby the thickness of the silicon substrate 61 is reduced (for example, to a thickness of 1 to 200 μm) to obtain a thin device wafer 60′.

Similarly to the first embodiment, as the mechanical or chemical treatment, a treatment of forming a through hole (not shown) penetrating the silicon substrate from the back surface of the thin device wafer 60′ and further forming a through-silicon via (not shown) in the through hole may be performed, if desired, after the thinning treatment.

Thereafter, as shown in FIGS. 9C and 9D, an organic solvent S is contacted with the outer edge part of the adhesive layer 23 of the adhesive support to dissolve and remove the high adhesive region 23C. Furthermore, for example, similarly to the first embodiment, a tape is attached to the back surface of the thin device wafer 60′, and the thin device wafer 60′ is slid with respect to the adhesive support or the thin device wafer 60′ is separated from the adhesive support, whereby the thin device wafer 60′ is detached from the adhesive layer 23 of the adhesive support to obtain a thin device wafer 60′.

If desired, similarly to the first embodiment, various known treatments are thereafter applied to the thin device wafer 60′ to manufacture a semiconductor device having a thin device wafer 60′.

According to the third embodiment of the present invention, as shown in FIGS. 9C and 9D, an organic solvent S is contacted with the outer edge part of the adhesive layer 23.

Here, as compared with the high adhesive region 23C, the low adhesive regions 23A and 23B have a more flexible internal structure to facilitate impregnation with the organic solvent in many cases and furthermore, since there is low or no adhesiveness between the low adhesive regions 23A and 23B and the thin device wafer 60′, the organic solvent S readily enters through the low adhesive region 23B constituting the outer edge part of the adhesive layer 23 or through the interface between the low adhesive region 23B and the thin device wafer 60′ and intrudes into the low adhesive region 23A in the central region or into the interface between the low adhesive region 23A and the thin device wafer 60′.

As a result, the organic solvent S is likely to come into contact with not only the outer edge part but also the inner edge part of the high adhesive region 23C, so that the high adhesive region 23C can be easily removed and the subsequent detachment of the thin device wafer 60′ from the adhesive support can be facilitated.

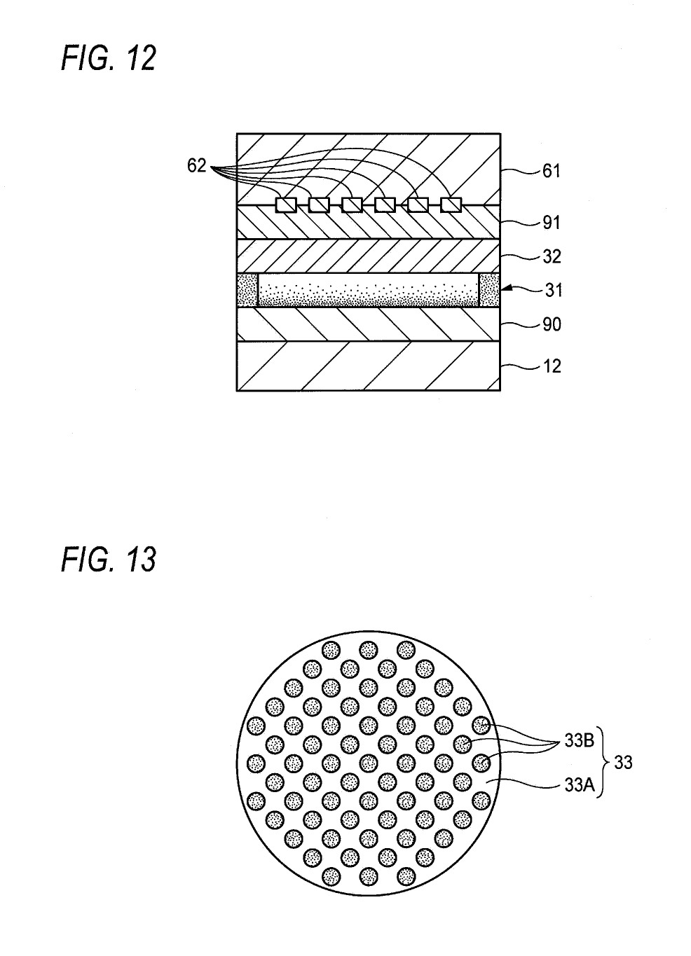

FIG. 12 is a schematic cross-sectional view explaining temporary adhesion of the adhesive support to a device wafer in the embodiment of the present invention.

In the embodiment of the present invention, as shown in the schematic cross-sectional view of FIG. 12, an adhesive layer (for example, an adhesive layer 31) having formed therein a low adhesive region and a high adhesive region is provided on a carrier substrate 12 through a first solvent-aided separation layer 90 separable with a solvent and at the same time, the adhesive layer (for example, an adhesive layer 31) may be adhered to a silicon substrate 61 through, in order, another adhesive layer 32 and a second solvent-aided separation layer 91 separable with a solvent.

In this embodiment, as the material constituting each of the first solvent-aided separation layer 90 and the second solvent-aided separation layer 91, known materials can be used, and the thickness thereof is preferably from 0.5 to 3 μm, more preferably from 1 to 1.5 μm.

Also, in this embodiment, the thickness of the adhesive layer (for example, the adhesive layer 31) having formed therein a low adhesive region and a high adhesive region is preferably 35 μm or less, more preferably from 1 to 35 μm, still more preferably from 1 to 25 μm.

The thickness of the another adhesive layer 32 is preferably 24 μm or more, more preferably from 45 to 200 μm, still more preferably from 50 to 150 μm.

FIG. 13 is a schematic top view of the adhesive support in the fourth embodiment of the present invention.

As shown in FIG. 13, in the fourth embodiment of the present invention, the adhesive layer 33 in the adhesive support is a layer where a high adhesive region 33B as a dot region and a low adhesive region 33A as the peripheral region surrounding the dot region are formed, that is, a low adhesive region 33A and a high adhesive region 33B form a dot pattern.

The method for forming the low adhesive region 33A and the high adhesive region 33B is not particularly limited, and a method of drawing a high adhesive region and a low adhesive region on a carrier substrate by an inkjet method or a screen printing method by using a high-adhesiveness adhesive and a low-adhesiveness adhesive may be employed, or similarly to the above-described embodiments, a method of applying dot-imagewise pattern exposure to an adhesive layer capable of increasing or decreasing in the adhesiveness upon irradiation with an actinic ray or radiation may be employed.

The dot-imagewise pattern exposure is preferably exposure defining the dot region of the dot pattern in the adhesive layer as the high adhesive region and the peripheral region surrounding the dot region as the low adhesive region.

The area of the dot region is preferably from 0.0001 to 9 mm², more preferably from 0.1 to 4 mm², and most preferably from 0.01 to 2.25 mm².

The dot-imagewise pattern exposure may be mask exposure or lithography exposure, but mask exposure through a photomask having a dot pattern formed by a light-transmitting region and a light-shielding region is preferred and in this case, in view of adhesiveness and easy releasability, the area ratio of the light-shielding region is preferably from 1 to 20%, more preferably from 1 to 10%, and most preferably from 1 to 5%, of the mask.

The morphology (such as size and shape) of the light-shielding region corresponding to the dot in the dot pattern of the photomask can be freely selected, and for example, the light-shielding region may have a circular, square, rectangular, rhombic, triangular or star-like shape or a shape formed by combining two or more thereof, in an arbitrary dimension.

With respect to other contents in the fourth embodiment of the present invention, the same as those in respective embodiments above can be employed.

The manufacturing method of a semiconductor device of the present invention is not limited to these embodiments but, for example, appropriate modifications or improvements may be made therein.

For example, in the above-described embodiments, an adhesive layer capable of decreasing in the adhesiveness upon irradiation with an actinic ray or radiation is used as the adhesive layer in the adhesive support, but instead, an adhesive layer capable of increasing in the adhesiveness upon irradiation with an actinic ray or radiation may be used.

The adhesive layer capable of increasing in the adhesiveness upon irradiation with an actinic ray or radiation is a layer having substantially no adhesiveness or low adhesiveness before being irradiated with an actinic ray or radiation but is a layer capable of increasing the adhesiveness in the region irradiated with an actinic ray or radiation.

As the adhesive capable of increasing in the adhesiveness upon irradiation with an actinic ray or radiation, a known adhesive can be used.

Similarly to the first embodiment, an adhesive composition containing such an adhesive, a solvent and optional components which are used, if desired, is coated on a carrier substrate and then dried, whereby an adhesive layer capable of increasing in the adhesiveness upon irradiation with an actinic ray or radiation can be formed.

In the case where the adhesive layer in the adhesive support is an adhesive layer capable of increasing in the adhesiveness upon irradiation with an actinic ray or radiation, the pattern in pattern exposure is not particularly limited, but by reversing the exposed area and the unexposed area (that is, reversing the light-transmitting region and the light-shielding region of the mask) in the above-described embodiments, the positions of high and low adhesive regions formed in the adhesive layer become the same as in those embodiments.

In the embodiments above, the mask used in the pattern exposure may be either a binary mask or a halftone mask as long as a high adhesive region and a low adhesive region can be formed in the adhesive layer of the adhesive support.

In the embodiments above, the exposure is mask exposure through a mask but may be selective exposure by lithography using also an electron beam or the like.

In the embodiments above, the adhesive layer has a single-layer structure, but the adhesive layer may have a multilayer structure. Examples of the method for forming an adhesive layer having a multilayer structure include a method of stepwise coating an adhesive composition by the above-described conventionally known method before applying irradiation with an actinic ray or radiation, and a method of coating an adhesive composition by the above-described conventionally known method after applying irradiation with an actinic ray or radiation. In the mode where the adhesive layer has a multilayer structure, for example, when the adhesive layer 11 is an adhesive layer capable of decreasing in the adhesiveness upon irradiation with an actinic ray or radiation, the adhesiveness as an entire adhesive layer can be decreased also by decreasing the adhesiveness between respective layers by irradiation with an actinic ray or radiation.

In the embodiments above, the to-be-treated member supported by the adhesive support is a silicon substrate, but the to-be-treated member is not limited thereto and may be any to-be-treated member which can be subjected to a mechanical or chemical treatment in the manufacturing method of a semiconductor device.

For example, the to-be-treated member includes a compound semiconductor substrate, and specific examples of the compound semiconductor substrate include an SiC substrate, an SiGe substrate, a ZnS substrate, a ZnSe substrate, a GaAs substrate, an InP substrate and a GaN substrate.

In the embodiments above, the mechanical or chemical treatment applied to the silicon substrate supported by the adhesive support is a thinning treatment of the silicon substrate or a treatment of forming a through-silicon via, but the mechanical or chemical treatment is not limited thereto and may be any treatment required in the manufacturing method of a semiconductor device.

In addition, the shape, dimension, number, arrangement portion and the like of light-transmitting and light-shielding regions in the mask, high and low adhesion regions in the adhesive layer, device chip in the device wafer, and tape and the like, which are exemplified in the embodiments above, are arbitrary and not limited as long as the present invention can be achieved.

The adhesive composition capable of forming the adhesive layer 11 (that is, the adhesive layer capable of decreasing in the adhesiveness upon irradiation with an actinic ray or radiation) is described in detail below.

### (A) Resin

The adhesive composition preferably contain a resin (hereinafter, sometimes referred to as the resin (A)).

Examples of the resin (A) include a synthetic resin such as hydrocarbon resin, (meth)acrylic polymer, polyurethane resin, polyvinyl alcohol resin, polyvinylbutyral resin, polyvinylformal resin, polyamide resin, polyester resin, epoxy resin, novolak resin, phenol resin, melamine resin, urea resin, unsaturated polyester resin, alkyd resin, polyurethane, polyimide, polyethylene, polypropylene, polyvinyl chloride, polystyrene, polyvinyl acetate, Teflon (registered trademark), ABS resin, AS resin, acrylic resin, polyacetal, polycarbonate, polyphenylene ether, polybutylene terephthalate, polyethylene terephthalate, cyclic polyolefin, polyphenylene sulfide, polysulfone, polyethersulfone, polyarylate, polyether ether ketone and polyamideimide, and a natural resin such as natural rubber. Among these, a (meth)acrylic polymer, a polyurethane resin, a novolak resin, polyimide and polystyrene are preferred.

As the hydrocarbon resin, an arbitrary hydrocarbon rein can be used. The hydrocarbon resin means a resin fundamentally composed of only a carbon atom and a hydrogen atom, but as long as the basic skeleton is a hydrocarbon resin, the resin may contain other atoms as a side chain. The hydrocarbon resin as used in the present invention does not include a resin where a functional group other than a hydrocarbon group is directly bonded to the main chain, such as acrylic resin, polyvinyl alcohol resin, polyvinylacetal resin and polyvinylpyrrolidone resin.

Examples of the hydrocarbon resin meeting the requirement above include a polystyrene resin, a terpene resin, a terpene phenol resin, a modified terpene resin, a hydrogenated terpene resin, a hydrogenated terpene phenol resin, rosin, a rosin ester, a hydrogenated rosin, a hydrogenated rosin ester, a polymerized rosin, a polymerized rosin ester, a modified rosin, a rosin-modified phenol resin, an alkylphenol resin, an aliphatic petroleum resin, an aromatic petroleum resin, a hydrogenated petroleum resin, a modified petroleum resin, an alicyclic petroleum resin, a coumarone petroleum resin, an indene petroleum resin, an olefin monomer polymer (such as methylpentene copolymer), and a cycloolefin monomer polymer (such as norbornene copolymer, dicyclopentadiene copolymer and tetracyclododecene copolymer).

Among others, a polystyrene resin, a terpene resin, rosin, a petroleum resin, a hydrogenated rosin, a polymerized rosin, an olefin monomer polymer or a cycloolefin monomer polymer is preferred, a polystyrene resin, a terpene resin, rosin, an olefin monomer polymer or a cycloolefin monomer polymer is more preferred, a polystyrene resin, a terpene resin, rosin, an olefin monomer polymer, a polystyrene resin or a cycloolefin monomer polymer is still more preferred, a polystyrene resin, a terpene resin, rosin, a cycloolefin monomer polymer or an olefin monomer polymer is yet still more preferred, and a polystyrene resin or a cycloolefin monomer polymer is most preferred.

Examples of the cyclic olefin-based resin for use in the production of a cycloolefin copolymer include a norbornene-based polymer, a monocyclic cyclic olefin polymer, a cyclic conjugated diene polymer, a vinyl alicyclic hydrocarbon polymer, and hydrides of these polymers. Preferred examples thereof include an addition (co)polymer cyclic olefin-based resin containing at least one or more repeating units represented by the following formula (II), and an addition (co)polymer cyclic olefin-based resin further containing, if desired, at least one or more repeating units represented by formula (I). Other preferred examples include a ring-opened (co)polymer containing at least one cyclic repeating unit represented by formula (III).

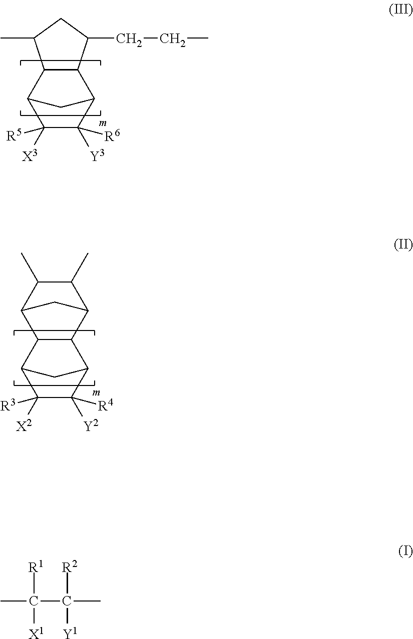

In the formulae, m represents an integer of 0 to 4, each of R¹ to R⁶ represents a hydrogen atom or a hydrocarbon group having a carbon number of 1 to 10, and each of X¹ to X³ and Y¹ to Y³ represents a hydrogen atom, a hydrocarbon group having a carbon number of 1 to 10, a halogen atom, a halogen atom-substituted hydrocarbon group having a carbon number of 1 to 10, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)NR¹⁵R¹⁶, —(CH₂)ₙOZ or —(CH₂)ₙW or represents (—CO)₂O or (—CO)₂NR¹⁷ constituted by X¹ and Y¹, X² and Y², or X³ and Y³. Here, each of R¹¹, R¹², R¹³, R¹⁴, R¹⁵, R¹⁶ and R¹⁷ represents a hydrogen atom or a hydrocarbon group having a carbon number of 1 to 20, Z represents a hydrocarbon group or a halogen-substituted hydrocarbon group, W represents SiR¹⁸ₚD₃₋ₚ (R¹⁸ represents a hydrocarbon group having a carbon number of 1 to 10, D represents a halogen atom, —OCOR¹⁸ or —OR¹⁸, and p represents an integer of 0 to 3), and n represents an integer of 0 to 10.

The norbornene-based addition (co)polymer is disclosed, for example, in JP-A-10-7732, JP-T-2002-504184 (the term “JP-T” as used herein means a “published Japanese translation of a PCT patent application”), US2004/229157A1 and WO2004/070463A1. This (co)polymer can be obtained by addition-polymerizing norbornene-based polycyclic unsaturated compounds with each other. If desired, a norbornene-based polycyclic unsaturated compound may be addition-polymerized with ethylene, propylene, butene, a conjugated diene such as butadiene and isoprene, or a non-conjugated diene such as ethylidene norbornene. Such a norbornene-based addition (co)polymer is available under the trade name of APL from Mitsubishi Chemical Corp., including grades differing in the glass transition temperatures (Tg), such as APL8008T (Tg: 70° C.), APL6013T (Tg: 125° C.) and APL6015T (Tg: 145° C.). Also, a pellet such as TOPAS 8007, TOPAS 5013, TOPAS 6013 and TOPAS 6015 is available from Polyplastics Co., Ltd.

Furthermore, Appear 3000 is available from Ferrania Company.

The norbornene-based polymer hydride can be produced by subjecting a polycyclic unsaturated compound to addition polymerization or ring-opening metathesis polymerization and then to hydrogenation, as disclosed, for example, in JP-A-1-240517, JP-A-7-196736, JP-A-60-26024, JP-A-62-19801, JP-A-2003-1159767 and JP-A-2004-309979.

In the formulae above, each of R⁵ and R⁶ is preferably a hydrogen atom or —CH₃, each of X³ and Y³ is preferably a hydrogen atom, and other groups are appropriately selected. This norbornene-based resin is available under the trade name of Arton G or Arton F from JSR Corp. or under the trade name of Zeonor ZF14, ZF16, Zeonex 250, Zeonex 280 or Zeonex 480R from ZEON Corp., and these products can be used.

The resin (A) is preferably a resin containing a repeating unit having a polymerizable group. The polymerizable group in the resin (A) is not particularly limited, but examples thereof include an unsaturated group (such as ethylenically unsaturated group), an epoxy group and an oxetane group, with an unsaturated group being preferred.

In this case, the polymerizable group in the resin (A) is a group capable of developing adhesiveness and undergoing a reaction upon irradiation with an actinic ray or radiation to lose the polymerization activity and decrease the adhesiveness. That is, the resin (A) having a polymerizable group can function as the above-described “adhesive capable of decreasing in the adhesiveness upon irradiation with an actinic ray or radiation”.

The content of the polymerizable group-containing repeating unit is preferably from 1 to 30 mol %, more preferably from 5 to 15 mol %, based on all repeating units in the resin (A).

The resin (A) is also preferably an alkali-soluble resin having a polymerizable group.

The alkali-soluble resin can be appropriately selected from alkali-soluble resins which are a linear organic high molecular polymer and contain at least one alkali solubility-promoting group in the molecule (preferably the molecule having an acryl-based copolymer or a styrene-based copolymer as the main chain). In view of heat resistance, the alkali-soluble resin is preferably a polyhydroxystyrene-based resin, a polysiloxane-based resin, a polyurethane resin, an acrylic resin, an acrylamide-based resin or an acryl/acrylamide copolymer resin.

Examples of the alkali solubility-promoting group (hereinafter, sometimes referred to as “acid group”) include a carboxyl group, a phosphoric acid group, a sulfonic acid group, and a phenolic hydroxyl group, and a (meth)acryloyl group is particularly preferred. Only one of these acid groups may be used, or two or more thereof may be used.

The alkali-soluble resin may be obtained, for example, by polymerizing, as a monomer component, an acid group-containing monomer and/or a monomer capable of imparting an acid group after polymerization (hereinafter, sometimes referred to as “monomer for acid group introduction”).

Incidentally, in the case of introducing an acid group by using, as a monomer component, a monomer capable of imparting an acid group after polymerization, for example, the later-described treatment for imparting an acid group is required after polymerization.

Examples of the acid group-containing monomer include a carboxyl group-containing monomer such as (meth)acrylic acid and itaconic acid, a phenolic hydroxyl group-containing monomer such as N-hydroxyphenylmaleimide, and a carboxylic anhydride group-containing monomer such as maleic anhydride and itaconic anhydride. Among these, a (meth)acrylic acid is preferred.

Examples of the monomer capable of imparting an acid group after polymerization include a hydroxyl group-containing monomer such as 2-hydroxyethyl (meth)acrylate, an epoxy group-containing monomer such as glycidyl (meth)acrylate, and an isocyanate group-containing monomer such as 2-isocyanatoethyl (meth)acrylate. Only one of these monomers for acid group introduction may be used, or two or more thereof may be used.

In the case of using a monomer capable of imparting an acid group after polymerization, the treatment for imparting an acid group includes a treatment of modifying a part of polar groups in the polymer side chain by a polymer reaction.

The linear organic high molecular polymer used as the alkali-soluble resin is preferably a polymer having a carboxylic acid in the side chain, and examples thereof include a methacrylic acid copolymer, an acrylic acid copolymer, an itaconic acid copolymer, a crotonic acid copolymer, a maleic acid copolymer, a partially esterified maleic acid copolymer, an alkali-soluble phenol resin such as novolak resin, an acidic cellulose derivative having a carboxylic acid in the side chain, and a resin obtained by adding an acid anhydride to a polymer having a hydroxyl group. In particular, a copolymer of a (meth)acrylic acid and another monomer copolymerizable therewith is suitable as the alkali-soluble resin. The another monomer copolymerizable with a (meth)acrylic acid includes, for example, an alkyl (meth)acrylate, an aryl (meth)acrylate, and a vinyl compound. Examples of the alkyl (meth)acrylate and aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, and cyclohexyl (meth)acrylate. Examples of the vinyl compound include styrene, α-methylstyrene, vinyltoluene, glycidyl methacrylate, acrylonitrile, vinyl acetate, N-vinylpyrrolidone, tetrahydrofurfuryl methacrylate, a polystyrene macromonomer, a polymethyl methacrylate macromonomer, and an N-substituted maleimide monomer described in JP-A-10-300922, such as N-phenylmaleimide and N-cyclohexylmaleimide. As for the another monomer copolymerizable with the (meth)acrylic acid, only one kind of a monomer may be used, or two or more kinds of monomers may be used.

The alkali-soluble resin is also preferably (a) a polymer obtained by polymerizing a monomer component mandatorily containing a compound represented by the following formula (ED) (hereinafter, sometimes referred to as “ether dimer”). Thanks to this polymer, the adhesive composition of the present invention can form an adhesive layer very excellent in the transparency as well as in the heat resistance. Formula (ED):

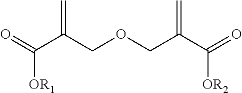

(In formula (ED), each of R₁ and R₂ independently represents a hydrogen atom or a hydrocarbon group having a carbon number of 1 to 25, which may have a substituent.)

In formula (ED) showing an ether dimer, the hydrocarbon group represented by R₁ and R₂ having a carbon number of 1 to 25, which may have a substituent, is not particularly limited, but examples thereof include a linear or branched alkyl group such as methyl, ethyl, n-propyl, isopropyl, n-butyl, isobutyl, tert-butyl, tert-amyl, stearyl, lauryl and 2-ethylhexyl; an aryl group such as phenyl; an alicyclic group such as cyclohexyl, tert-butylcyclohexyl, dicyclopentadienyl, tricyclodecanyl, isobornyl, adamantyl and 2-methyl-2-adamantyl; an alkoxy-substituted alkyl group such as 1-methoxyethyl and 1-ethoxyethyl; and an aryl group-substituted alkyl group such as benzyl. Among these, a substituent of primary or secondary carbon, which is less likely to leave by the action of an acid or heat, such as methyl, ethyl, cyclohexyl and benzyl, is preferred in view of heat resistance.

Specific examples of the ether dimer include dimethyl-2,2′-[oxybis(methylene)]bis-2-propenoate, diethyl-2,2′-[oxybis(methylene)]bis-2-propenoate, di(n-propyl)-2,2′-[oxybis(methylene)]bis-2-propenoate, di(isopropyl)-2,2′-[oxybis(methylene)]bis-2-propenoate, di(n-butyl)-2,2′-[oxybis(methylene)]bis-2-propenoate, di(isobutyl)-2,2′-[oxybis(methylene)]bis-2-propenoate, di(tert-butyl)-2,2′-[oxybis(methylene)bis-2-propenoate, di(tert-amyl)-2,2′-[oxybis(methylene)]bis-2-propenoate, di(stearyl)-2,2′-[oxybis(methylene)]bis-2-propenoate, di(lauryl)-2,2′-[oxybis(methylene)]bis-2-propenoate, di(2-ethylhexyl)-2,2′-[oxybis(methylene)]bis-2-propenoate, di(1-methoxyethyl)-2,2′-[oxybis(methylene)]bis-2-propenoate, di(1-ethoxyethyl)-2,2′-[oxybis(methylene)]bis-2-propenoate, dibenzyl-2,2′-[oxybis(methylene)]bis-2-propenoate, biphenyl-2,2′-[oxybis(methylene)]bis-2-propenoate, dicyclohexyl-2,2′-[oxybis(methylene)]bis-2-propenoate, di(tert-butylcyclohexyl)-2,2′-[oxybis(methylene)]bis-2-propenoate, di(dicyclopentadienyl)-2,2′-[oxybis(methylene)]bis-2-propenoate, di(tricyclodecanyl)-2,2′-[oxybis(methylene)]bis-2-propenoate, di(isobornyl)-2,2′-[oxybis(methylene)]bis-2-propenoate, diadamantyl-2,2′-[oxybis(methylene)]bis-2-propenoate, and di(2-methyl-2-adamantyl)-2,2′-[oxybis(methylene)]bis-2-propenoate. Among these, dimethyl-2,2′-[oxybis(methylene)]bis-2-propenoate, diethyl-2,2′-[oxybis(methylene)]bis-2-propenoate, dicyclohexyl-2,2′-[oxybis(methylene)]bis-2-propenoate, and dibenzyl-2,2′-[oxybis(methylene)]bis-2-propenoate are preferred. Only one of these ether dimers may be used, or two or more thereof may be used. An alkali-soluble resin may be also obtained by copolymerizing the compound represented by formula (ED) with another monomer.

The alkali-soluble phenol resin includes, for example, a novolak resin and a vinyl polymer.

The novolak resin includes, for example, a resin obtained by fusing phenols and aldehydes in the presence of an acid catalyst. Examples of the phenols include phenol, cresol, ethylphenol, butylphenol, xylenol, phenylphenol, catechol, resorcinol, pyrogallol, naphthol, and bisphenol A.

Examples of the aldehydes include formaldehyde, paraformaldehyde, acetaldehyde, propionaldehyde, and benzaldehyde.

One of these phenols and aldehydes may be used alone, or two or more thereof may be used in combination.

Specific examples of the novolak resin include metacresol, paracresol, and a condensation product of a mixture thereof and formalin.

The molecular weight distribution of the novolak resin may be adjusted by using fractionation or the like. Also, a low molecular weight component having a phenolic hydroxyl group such as bisphenol C and bisphenol A may be mixed with the novolak resin.

As the alkali-soluble resin, among others, a benzyl (meth)acrylate/(meth)acrylic acid copolymer and a multi-copolymer composed of benzyl (meth)acrylate/(meth)acrylic acid/another monomer are preferred. Other examples include a copolymer of 2-hydroxyethyl methacrylate; and a 2-hydroxypropyl (meth)acrylate/polystyrene macromonomer/benzyl methacrylate/methacrylic acid copolymer, a 2-hydroxy-3-phenoxypropyl acrylate/polymethyl methacrylate macromonomer/benzyl methacrylate/methacrylic acid copolymer, a 2-hydroxyethyl methacrylate/polystyrene macromonomer/methyl methacrylate/methacrylic acid copolymer, and a 2-hydroxyethyl methacrylate/polystyrene macromonomer/benzyl methacrylate/methacrylic acid copolymer, which are described in JP-A-7-140654.

The acid value of the alkali-soluble resin is preferably from 30 to 200 mgKOH/g, more preferably from 50 to 150 mgKOH/g, and most preferably from 70 to 120 mgKOH/g.

The alkali-soluble resin having a polymerizable group is preferably obtained by introducing a polymerizable group into the above-described alkali-soluble resin (more preferably by incorporating a polymerizable group-containing repeating unit into the alkali-soluble resin).

As the alkali-soluble resin having a polymerizable group, for example, an alkali-soluble resin containing, in the side chain, an allyl group, a (meth)acryl group or an allyloxyalkyl group is useful. Examples of the polymer containing a polymerizable group include DIANAL NR Series (produced by Mitsubishi Rayon Co., Ltd.), Photomer 6173 (COOH-containing polyurethane acrylic oligomer, produced by Diamond Shamrock Co., Ltd.), Viscoat R-264, KS Resist 106 (both produced by Osaka Organic Chemical Industry Ltd.), CYCLOMER P Series, PLACCEL CF200 Series (all produced by Daicel Chemical Industries, Ltd.), and Ebecryl 3800 (produced by Daicel-UCB Company Ltd.). Preferred examples of the alkali-soluble resin having a polymerizable group include a urethane-modified polymerizable double bond-containing acrylic resin obtained by previously reacting an isocyanate group and an OH group while leaving one unreacted isocyanate group, and reacting a (meth)acryloyl group-containing compound and a carboxyl group-containing acrylic resin; an unsaturated group-containing acrylic resin obtained by reacting a carboxyl group-containing acrylic resin and a compound having both an epoxy group and a polymerizable double bond in the molecule; an acid pendant-type epoxy acrylate resin; a polymerizable double bond-containing acrylic resin obtained by reacting an OH group-containing acrylic resin and a polymerizable double bond-containing dibasic acid anhydride; a resin obtained by reacting an OH group-containing acrylic resin and a compound having an isocyanate and a polymerizable group; and a resin obtained by applying a basic treatment to a resin containing, in the side chain, an ester group having a leaving group such as halogen atom or sulfonate group at the α- or β-position, described in JP-A-2002-229207 and JP-A-2003-335814.

The content of the repeating unit having an alkali-soluble group (acid group) is preferably from 1 to 30 mol %, more preferably from 5 to 20 mol %, based on all repeating units in the resin (A).

In the production of the resin (A), for example, a method by a known radical polymerization process can be applied. Various polymerization conditions when producing the alkali-soluble resin by the radical polymerization process, such as temperature, pressure, kind and amount of radical initiator, and kind of solvent, can be easily set by one skilled in the art, and the conditions may be also experimentally determined.

In one preferred embodiment of the present invention, the resin is a polyurethane resin. In this case, the polyurethane resin having a carboxyl group is typically a polyurethane resin having, as a basic skeleton, a structural unit represented by a reaction product between at least one diisocyanate compound represented by the following formula (2) and at least one diol compound represented by formula (3):

OCN—X⁰—NCO (2)

HO—Y⁰—OH (3)

(wherein each of X⁰ and Y⁰ represents a divalent organic residue).

The diisocyanate compound is preferably a diisocyanate compound represented by the following formula (4):

OCN-L¹-NCO (4)

In the formula, L¹ represents a divalent aliphatic or aromatic hydrocarbon group which may have a substituent. If desired, L¹ may have another functional group incapable of reacting with an isocyanate group, such as ester group, urethane group, amide group and ureido group.

### I) Diisocyanate Compound

The diisocyanate compound represented by formula (4) specifically includes the followings:

an aromatic diisocyanate compound such as 2,4-tolylene diisocyanate, dimer of 2,4-tolylene diisocyanate, 2,6-tolylenedilene diisocyanate, p-xylylene diisocyanate, m-xylylene diisocyanate, 4,4′-diphenylmethane diisocyanate, 1,5-naphthylene diisocyanate and 3,3′-dimethylbiphenyl-4,4′-diisocyanate; an aliphatic diisocyanate compound such as hexamethylene diisocyanate, trimethylhexamethylene diisocyanate, lysine diisocyanate and dimer acid diisocyanate; an alicyclic diisocyanate compound such as isophorone diisocyanate, 4,4′-methylenebis(cyclohexyl isocyanate), methylcyclohexane-2,4 (or 2,6) diisocyanate and 1,3-(isocyanatomethyl)cyclohexane; and a diisocyanate compound that is a reaction product between a diol and a diisocyanate, such as adduct of 1 mol of 1,3-butylene glycol and 2 mol of tolylene diisocyanate.

### II) Diol Compound

The diol compound widely includes a polyether diol compound, a polyester diol compound, a polycarbonate diol compound, and the like.

The polyether diol compound includes compounds represented by the following formulae (5), (6), (7), (8) and (9) and a random copolymer of ethylene oxide and propylene oxide each having a hydroxyl group at the terminal.

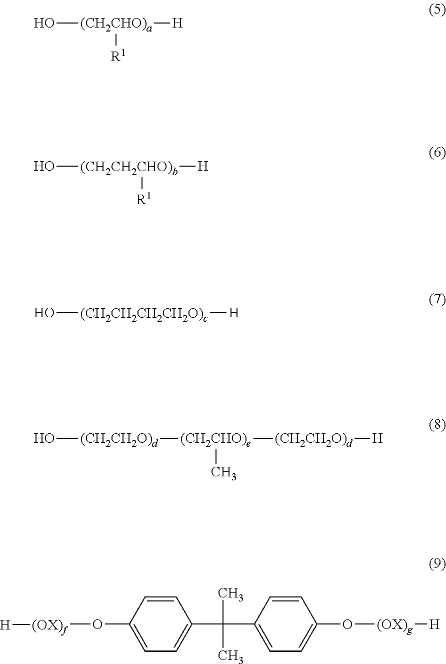

In the formulae, R¹ represents a hydrogen atom or a methyl group, and X represents the following group:

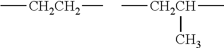

Each of a, b, c, d, e, f and g represents an integer of 2 or more and is preferably an integer of 2 to 100.

The polyether diol compounds represented by formulae (5) and (6) specifically include the followings:

that is, diethylene glycol, triethylene glycol, tetraethylene glycol, pentaethylene glycol, hexaethylene glycol, heptaethylene glycol, octaethylene glycol, di-1,2-propylene glycol, tri-1,2-propylene glycol, tetra-1,2-propylene glycol, hexa-1,2-propylene glycol, di-1,3-propylene glycol, tri-1,3-propylene glycol, tetra-1,3-propylene glycol, di-1,3-butylene glycol, tri-1,3-butylene glycol, hexa-1,3-butylene glycol, polyethylene glycol having a weight average molecular weight of 1,000, polyethylene glycol having a weight average molecular weight of 1,500, polyethylene glycol having a weight average molecular weight of 2,000, polyethylene glycol having a weight average molecular weight of 3,000, polyethylene glycol having a weight average molecular weight of 7,500, polypropylene glycol having a weight average molecular weight of 400, polypropylene glycol having a weight average molecular weight of 700, polypropylene glycol having a weight average molecular weight of 1,000, polypropylene glycol having a weight average molecular weight of 2,000, polypropylene glycol having a weight average molecular weight of 3,000, and polypropylene glycol having a weight average molecular weight of 4,000.

The polyether diol compound represented by formula (7) specifically includes the followings:

PTMG650, PTMG1000, PTMG2000, and PTMG3000 (trade names), produced by Sanyo Chemical Industries, Ltd.

The polyether diol compound represented by formula (8) specifically includes the followings:

NEWPOL PE-61, NEWPOL PE-62, NEWPOL PE-64, NEWPOL PE-68, NEWPOL PE-71, NEWPOL PE-74, NEWPOL PE-75, NEWPOL PE-78, NEWPOL PE-108, NEWPOL PE-128, and NEWPOL PE-61 (trade names), produced by Sanyo Chemical Industries, Ltd.

The polyether diol compound represented by formula (9) specifically includes the followings:

NEWPOL BPE-20, NEWPOL BPE-20F, NEWPOL BPE-20NK, NEWPOL BPE-20T, NEWPOL BPE-20G, NEWPOL BPE-40, NEWPOL BPE-60, NEWPOL BPE-100, NEWPOL BPE-180, NEWPOL BPE-2P, NEWPOL BPE-23P, NEWPOL BPE-3P, and NEWPOL BPE-5P (trade names), produced by Sanyo Chemical Industries, Ltd.

The random copolymer of ethylene oxide and propylene oxide each having a hydroxyl group at the terminal include the followings:

NEWPOL 50HB-100, NEWPOL 50HB-260, NEWPOL 50HB-400, NEWPOL 50HB-660, NEWPOL 50HB-2000, and NEWPOL 50HB-5100 (trade names), produced by Sanyo Chemical Industries, Ltd.

The polyester diol compound includes compounds represented by the following formulae (10) and (11):

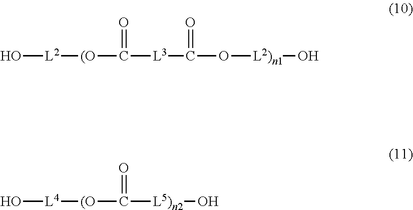

In the formulae, L², L³ and L⁴ may be the same or different and each represents a divalent aliphatic or aromatic hydrocarbon group, and L⁵ represents a divalent aliphatic hydrocarbon group. Preferably, each of L², L³ and L⁴ represents an alkylene group, an alkenylene group, an alkynylene group or an arylene group, and L⁵ represents an alkylene group. Also, in L², L³, L⁴ and L⁵, another functional group incapable of reacting with an isocyanate group, such as ether group, carbonyl group, ester group, cyano group, olefin group, urethane group, amido group, ureido group and halogen atom, may be present. Each of n1 and n2 is an integer of 2 or more, preferably an integer of 2 to 100.

The polycarbonate diol compound includes a compound represented by formula (12):

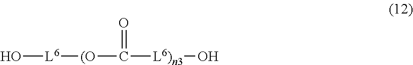

In the formula, L⁶s may be the same or different and each represents a divalent aliphatic or aromatic hydrocarbon group. L⁶ preferably represents an alkylene group, an alkenylene group, an alkynylene group or an arylene group. Also, in L⁶, another functional group incapable of reacting with an isocyanate group, such as ether group, carbonyl group, ester group, cyano group, olefin group, urethane group, amido group, ureido group and halogen atom, may be present. n3 is an integer of 2 or more, preferably an integer of 2 to 100.

The diol compounds represented by formulae (10), (11), and (12) specifically include (Compound No. 1) to (Compound No. 18) illustrated below. In specific examples, n is an integer of 2 or more.

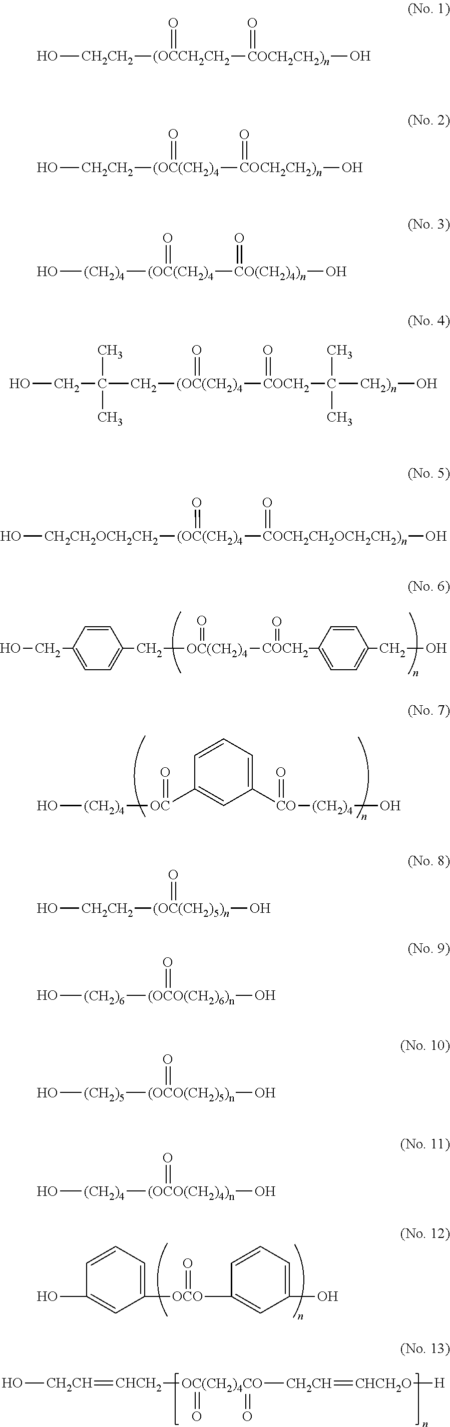

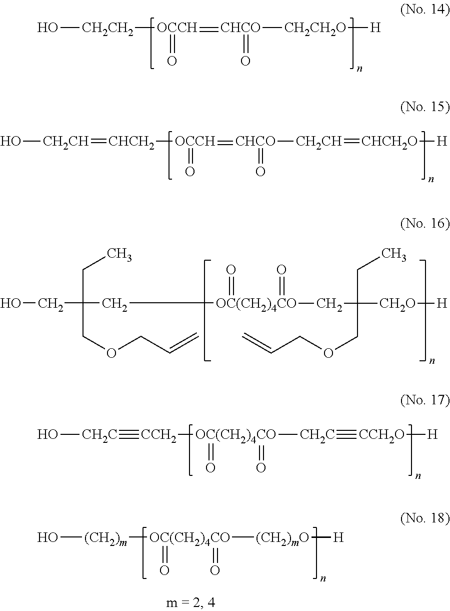

In the case where the polyurethane resin corresponds to the above-described alkali-soluble resin, the polyurethane is preferably a polyurethane resin having a carboxyl group as the acid group.

The polyurethane resin having a carboxyl group includes a polyurethane resin having a structural unit represented by at least one of diol compounds of formulae (13), (14) and (15) and/or a structural unit derived from a compound obtained by ring-opening a tetracarboxylic dianhydride by a diol compound.

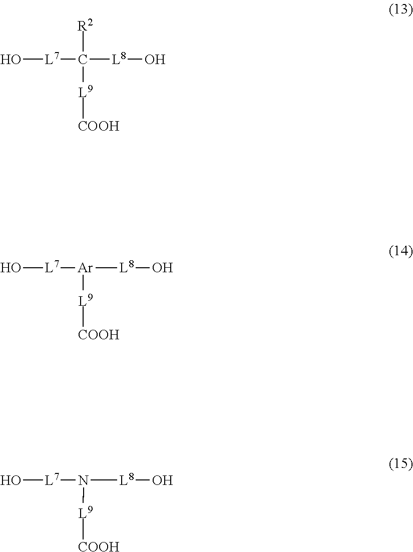

In the formulae, R² represents a hydrogen atom, an alkyl group which may have a substituent (for example, a cyano group, a nitro group, a halogen atom such as —F, —Cl, —Br and —I, or a group of —CONH₂, —COOR³, —OR³, —NHCONHR³, —NHCOOR³, —NHCOR³ or —OCONHR³ (wherein R³ represents an alkyl group having a carbon number of 1 to 10 or an aralkyl group having a carbon number of 7 to 15)), an aralkyl group, an aryl group, an alkoxy group, or an aryloxy group, preferably represents a hydrogen atom, an alkyl group having a carbon number of 1 to 8 or an aryl group having a carbon number of 6 to 15. L⁷, L⁸ and L⁹ may be the same or different and each represents a single bond, or a divalent aliphatic or aromatic hydrocarbon group which may have a substituent (preferably, for example, an alkyl group, an aralkyl group, an aryl group, an alkoxy group or a halogeno group), preferably represents an alkylene group having a carbon number of 1 to 20 or an arylene group having a carbon number of 6 to 15, and more preferably represents an alkylene group having a carbon number of 1 to 8. If desired, each of L⁷, L⁸ and L⁹ may have another functional group incapable of reacting with an isocyanate group, such as carbonyl group, ester group, urethane group, amido group, ureido group and ether group. Incidentally, two or three members out of R², L⁷, L⁸ and L⁹ may form a ring.

Ar represents a trivalent aromatic hydrocarbon group which may have a substituent, and preferably represents an aromatic group having a carbon number of 6 to 15.

### III) Carboxyl Group-Containing Diol Compound

The carboxyl group-containing diol compounds represented by formulae (13) (14) and (15) specifically include the followings:

that is, 3,5-dihydroxybenzoic acid, 2,2-bis(hydroxymethyl)propionic acid, 2,2-bis(2-hydroxyethyl)propionic acid, 2,2-bis(3-hydroxypropyl)propionic aid, bis(hydroxymethyl)acetic acid, bis(4-hydroxyphenyl)acetic acid, 2,2-bis(hydroxymethyl)butyric acid, 4,4-bis(4-hydroxyphenyl)pentanoic acid, tartaric acid, N,N-dihydroxyethylglycine, and N,N-bis(2-hydroxyethyl)-3-carboxy-propionamide.

In the present invention, preferred tetracarboxylic dianhydrides used for synthesis of the carboxyl group-containing polyurethane resin include those represented by formulae (16), (17) and (18):

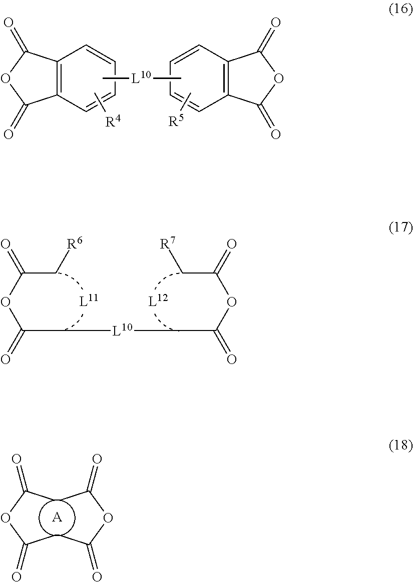

In the formulae, L¹⁰ represents a single bond, a divalent aliphatic or aromatic hydrocarbon group which may have a substituent (preferably, for example, an alkyl group, an aralkyl group, an aryl group, an alkoxy group, a halogeno group, an ester group or an amido group), —CO—, —SO—, —SO₂—, —O— or —S—, preferably represents a single bond, a divalent aliphatic hydrocarbon group having a carbon number of 1 to 15, —CO—, —SO₂—, —O— or —S—. R⁴ and R⁵ may be the same or different and each represents a hydrogen atom, an alkyl group, an aralkyl group, an aryl group, an alkoxy group or a halogeno group, and preferably represents a hydrogen atom, an alkyl group having a carbon number of 1 to 8, an aryl group having a carbon number of 6 to 15, an alkoxy group having a carbon number of 1 to 8 or a halogeno group. Also, two members out of L¹⁰, R⁴ and R⁵ may combine to form a ring.

R⁶ and R⁷ may be the same or different and each represents a hydrogen atom, an alkyl group, an aralkyl group, an aryl group or a halogeno group, and preferably represents a hydrogen atom, an alkyl group having a carbon number of 1 to 8 or an aryl group having a carbon number of 6 to 15. Also, two members out of L¹⁰, R⁶ and R⁷ may combine to form a ring. L¹¹ and L¹² may be the same or different and each represents a single bond, a double bond or a divalent aliphatic hydrocarbon group, and preferably represents a single bond, a double bond or a methylene group. A represents a mononuclear or polynuclear aromatic ring and preferably represents an aromatic ring having a carbon number of 6 to 18.

The compounds represented by formulae (16), (17) and (18) specifically include the followings:

that is, an aromatic tetracarboxylic dianhydride such as pyromellitic dianhydride, 3,3′,4,4′-benzophenonetetracarboxylic dianhydride, 3,3′,4,4′-diphenyltetracarboxylic dianhydride, 2,3,6,7-naphthalenetetracarboxylic dianhydride, 1,4,5,8-naphthalenetetracarboxylic dianhydride, 4,4′-sulfonyldiphthalic dianhydride, 2,2-bis(3,4-dicarboxyphenyl)propane dianhydride, bis(3,4-dicarboxyphenyl)ether dianhydride, 4,4′-[3,3 (alkylphosphoryldiphenylene)-bis(iminocarbonyl)]diphthalic dianhydride,

adduct of hydroquinone diacetate and trimellitic anhydride, and adduct of diacetyldiamine and trimellitic anhydride; an alicyclic tetracarboxylic dianhydride such as 5-(2,5-dioxotetrahydrofuryl)-3-methyl-3-cyclohexy-1,2-dicarboxylic anhydride (EPICLON B-4400, produced by Dainippon Ink and Chemicals Inc.), 1,2,3,4-cyclopentanetetracarboxylic dianhydride, 1,2,4,5-cyclohexanetetracarboxylic dianhydride and tetrahydrofurantetracarboxylic dianhydride; and an aliphatic tetracarboxylic dianhydride such as 1,2,3,4-butanetetracarboxylic dianhydride and 1,2,4,5-pentanetetracarboxylic dianhydride.

Examples of the method for introducing a structural unit derived from a compound obtained by ring-opening such a tetracarboxylic dianhydride by a diol compound into a polyurethane resin include the following methods: a) a method of reacting a diisocyanate compound with an alcohol-terminated compound obtained by ring-opening the tetracarboxylic dianhydride by a diol compound; and b) a method of reacting the tetracarboxylic dianhydride with an alcohol-terminated urethane compound obtained by reacting a diisocyanate compound under diol compound-excess conditions.

The diol compound used here specifically include the followings:

that is, ethylene glycol, diethylene glycol, triethylene glycol, tetraethylene glycol, propylene glycol, dipropylene glycol, polyethylene glycol, polypropylene glycol, neopentyl glycol, 1,3-butylene glycol, 1,6-hexanediol, 2-butene-1,4-diol, 2,2,4-trimethyl-1,3-pentanediol, 1,4-bis-β-hydroxyethoxycyclohexane, cyclohaxanedimethanol, tricyclodecanedimethanol, hydrogenated bisphenol A, hydrogenated bisphenol F, an ethylene oxide adduct of bisphenol A, a propylene oxide adduct of bisphenol A, an ethylene oxide adduct of bisphenol F, a propylene oxide adduct oxide of bisphenol F, an ethylene oxide adduct of hydrogenated bisphenol A, a propylene oxide adduct of hydrogenated bisphenol A, hydroquinonedihydroxyethyl ether, p-xylylene glycol, dihydroxyethylsulfone, bis(2-hydroxyethyl)-2,4-tolylene dicarbamate, 2,4-tolylene-bis(2-hydroxyethylcarbamide), bis(2-hydroxyethyl)-m-xylylene dicarbamate, and bis(2-hydroxyethyl)isophthalate.

### IV) Other Diol Compounds

In addition, for the synthesis of a polyurethane resin having a carboxyl group, another diol compound having no carboxyl group, which may have another substituent incapable of reacting with isocyanate, may be further used in combination.

Such a diol compound includes the following compounds:

HO-L¹³-O—CO-L¹⁴-CO—O-L¹³-OH (19)

HO-L¹⁴-CO—O-L¹³-OH (20)

In the formulae, L¹³ and L¹⁴ may be the same or different and each represents a divalent aliphatic hydrocarbon group, an aromatic hydrocarbon group or a heterocyclic group, which may have a substituent (for example, an alkyl group, an aralkyl group, an aryl group, an alkoxy group, an aryloxy group, or a halogen atom such as —F, —Cl, —Br and —I). If desired, each of L¹³ and L¹⁴ may have another functional group incapable of reacting with an isocyanate group, such as carbonyl group, ester group, urethane group, amido group and ureido group. Incidentally, L¹³ and L¹⁴ may form a ring.

Specific examples of the compounds represented by formulae (19) and (20) include (Compound No. 19) to (Compound No. 35) illustrated below.

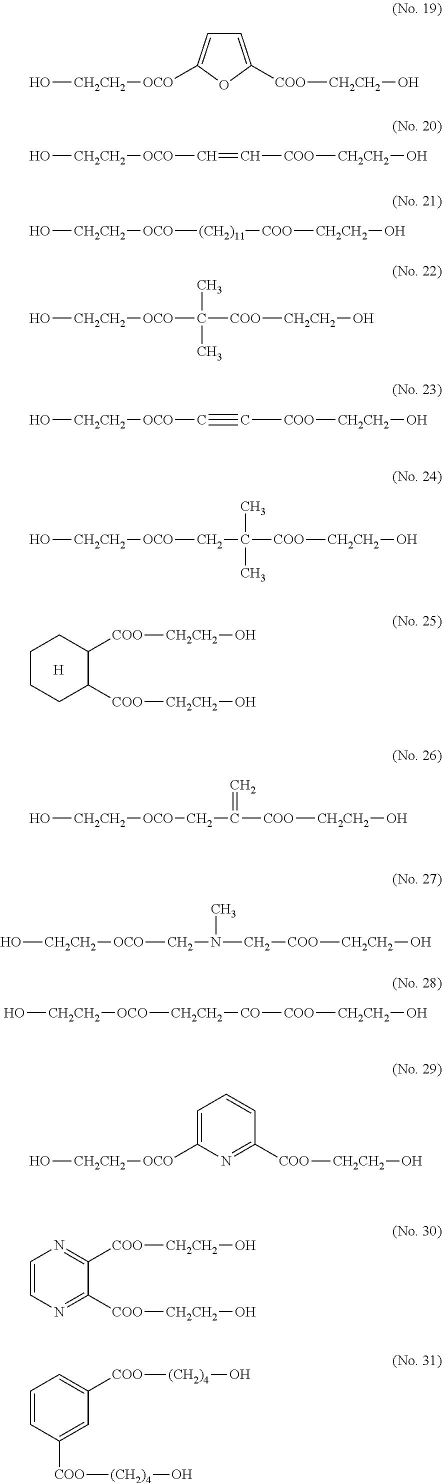

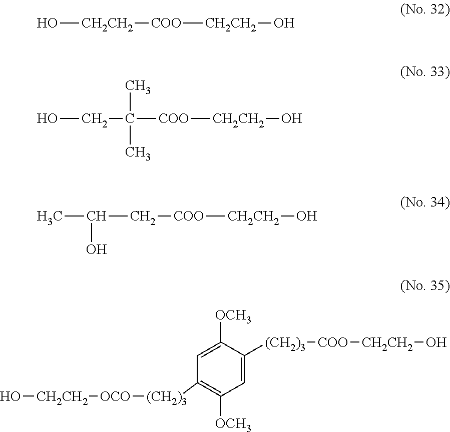

A diol compound represented by the following formula (21) or (22) may be also suitably used.

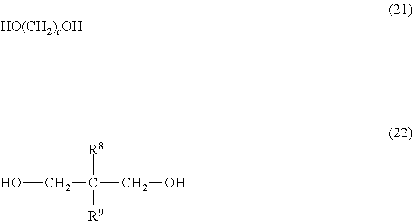

In the formulae, R⁸ and R⁹ may be the same or different and each is an alkyl group which may have a substituent, c represents an integer of 2 or more and is preferably an integer of 2 to 100.

The diol compounds represented by formulae (21) and (22) specifically include the followings:

that is, as formula (21), ethylene glycol, 1,3-propanediol, 1,4-butanediol, 1,5-pentanediol, 1,6-hexanediol, 1,7-heptanediol and 1,8-octanediol; and as formula (22), compounds illustrated below.

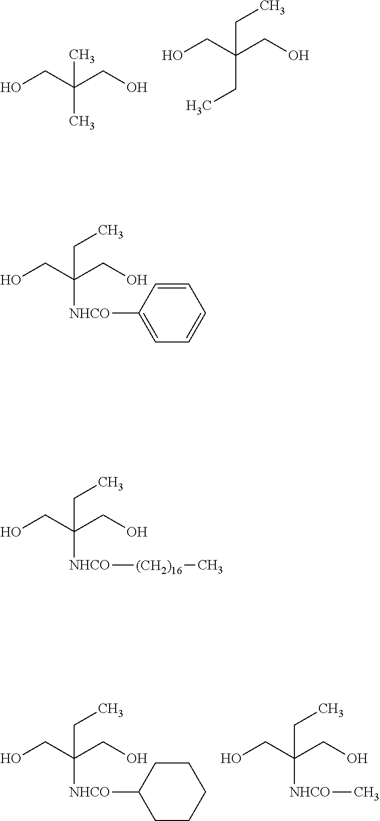

In addition, a diol compound represented by the following formula (23) or (24) may be also suitably used:

HO-L¹⁵-NH—CO-L¹⁶-CO—NH-L¹⁵-OH (23)

HO-L¹⁶-CO—NH-L¹⁵-OH (24)

In the formulae, L¹⁵ and L¹⁶ may be the same or different and each represents a divalent aliphatic hydrocarbon group, an aromatic hydrocarbon group or a heterocycle group, which may have a substituent (for example, an alkyl group, an aralkyl group, an aryl group, an alkoxy group, an aryloxy group or a halogen atom (—F, —Cl, —Br, —I)). If desired, each of L¹⁵ and L¹⁶ may have another functional group incapable of reacting with an isocyanate group, such as carbonyl group, ester group, urethane group, amido group and ureido group. Incidentally, L¹⁵ and L¹⁶ may form a ring.

Specific examples of the compounds represented by formulae (23) and (24) include the compounds illustrated below.

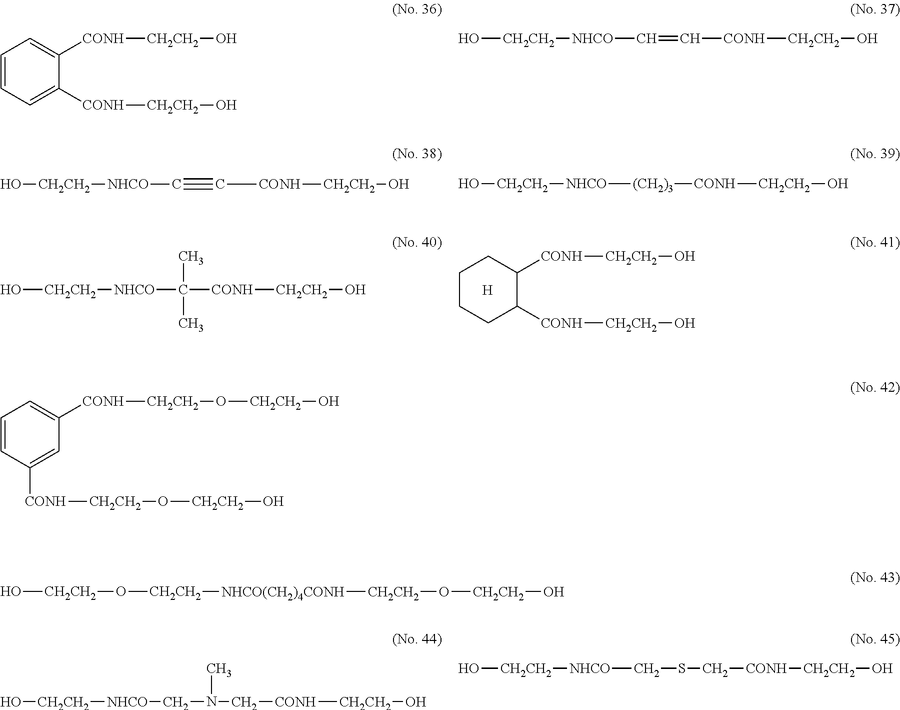

Furthermore, a diol compound represented by the following formula (25) or (25) may be also suitably used.

HO—Ar²-(L¹⁷-Ar³)ₙ—OH (25)

HO—Ar²-L¹⁷-OH (26)

In the formulae, L¹⁷ represents a divalent aliphatic hydrocarbon group which may have a substituent (preferably, for example, an alkyl group, an aralkyl group, an aryl group, an alkoxy group, an aryloxy group or a halogeno group). If desired, L¹⁷ may have another functional group incapable of reacting with an isocyanate group, such as ester group, urethane group, amido group and ureido group. Ar² and Ar³ may be the same or different and each represents a divalent aromatic hydrocarbon group which may have a substituent, and preferably represents an aromatic group having a carbon number 6 to 15. n represents an integer of 0 to 10.

The diol compounds represented by formulae (25) and (26) specifically include the followings:

that is, catechol, resorcin, hydroquinone, 4-methylcatechol, 4-tert-butylcatechol, 4-acetylcatechol, 3-methoxycatechol, 4-phenylcatechol, 4-methylresorcinol, 4-ethylresorcinol, 4-tert-butylresorcinol, 4-hexylresorcinol, 4-chlororesorcinol, 4-benzylresorcinol, 4-acetylresorcinol, 4-carbomethoxyresorcinol, 2-methylresorcinol, 5-methylresorcinol, tert-butylhydroquinone, 2,5-di-tert-butylhydroquinone, 2,5-di-tert-amylhydroquinone, tetramethylhydroquinone, tetrachlorohydroquinone, methylcarboaminohydroquinone, methylureidohydroquinone, methylthiohydroquinone, benzonorbornene-3,6-diol, bisphenol A,

bisphenol S, 3,3′-dichlorobisphenol S, 4,4′-dihydroxybenzophenone, 4,4′-dihydroxybiphenyl, 4,4′-thiodiphenol, 2,2′-dihydroxydiphenylmethane, 3,4-bis(p-hydroxyphenyl)hexane, 1,4-bis(2-(p-hydroxyphenyl)propyl)benzene, bis(4-hydroxyphenyl)methylamine, 1,3-dihydroxynaphthalene, 1,4-dihydroxynaphthalene, 1,5-dihydroxynaphthalene, 2,6-dihydroxynaphthalene, 1,5-dihydroxyanthraquinone, 2-hydroxybenzyl alcohol, 4-hydroxybenzyl alcohol, 2-hydroxy-3,5-di-tert-butylbenzyl alcohol, 4-hydroxy-3,5-di-tert-butylbenzyl alcohol, 4-hydroxyphenethyl alcohol, 2-hydroxyethyl-4-hydroxybenzoate, 2-hydroxyethyl-4-hydroxyphenyl acetate and resorcinol mono-2-hydroxyethyl ether.

A diol compound represented by the following formula (27), (28) or (29) may be also suitably used.

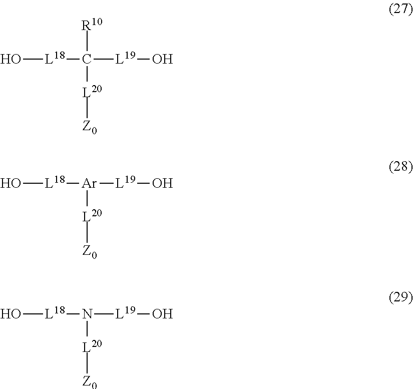

In the formula, R¹⁰ represents a hydrogen atom or an alkyl, aralkyl, aryl, alkoxy or aryloxy group which may have a substituent (for example, a cyano group, a nitro group, a halogen atom (—F, —Cl, —Br, —I), —CONH₂, —COOR¹¹, —OR¹¹, —NHCONHR¹¹, —NHCOOR¹¹, —NHCOR¹¹, —OCONHR¹¹, —CONHR¹¹ (wherein R¹¹ represents an alkyl group having a carbon number of 1 to 10 or an aralkyl group having a carbon number of 7 to 15)), and preferably represents a hydrogen atom, an alkyl group having a carbon number of 1 to 8 or an aryl group having a carbon number of 6 to 15. L¹⁸, L¹⁹ and L²⁰ may be the same or different and each represents a single bond or a divalent aliphatic or aromatic hydrocarbon residue which may have a substituent (preferably, for example, an alkyl group, an aralkyl group, an aryl group, an alkoxy group or a halogen group), preferably represents an alkylene group having a carbon number of 1 to 20 or an arylene group having a carbon number of 6 to 15, and more preferably represents an alkylene group having a carbon number of 1 to 8. If desired, each of L¹⁸, L¹⁹ and L²⁰ may have another functional group incapable of reacting with an isocyanate group, such as carbonyl group, ester group, urethane group, amido group, ureido group and ether group. Incidentally, two or three members out of R¹⁰, L¹⁸, L¹⁹ and L²⁰ may form a ring. Ar represents a trivalent aromatic hydrocarbon group which may have a substituent, and preferably represents an aromatic group having a carbon number of 6 to 15. Z₀ represents the following group:

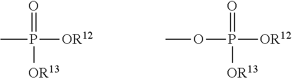

In the formulae, R¹² and R¹³ may be the same or different and each represents a hydrogen atom, sodium, potassium, an alkyl group or an aryl group, preferably a hydrogen atom, an alkyl group having a carbon number of 1 to 8 or an aryl group having a carbon number of 6 to 15.

The diol compounds represented by formulae (27), (28) or (29) having a phosphonic acid group, a phosphoric acid group and/or an ester group thereof are synthesized, for example, by the following method

After protecting, if desired, the hydroxyl group of a halogen compound represented by the following formula (30), (31) or (32), the compound is subjected to phosphonate ester formation by Michaelis-Arbuzov reaction represented by formula (33) and, if desired, further hydrolyzed with hydrogen bromide or the like, whereby the synthesis is performed.

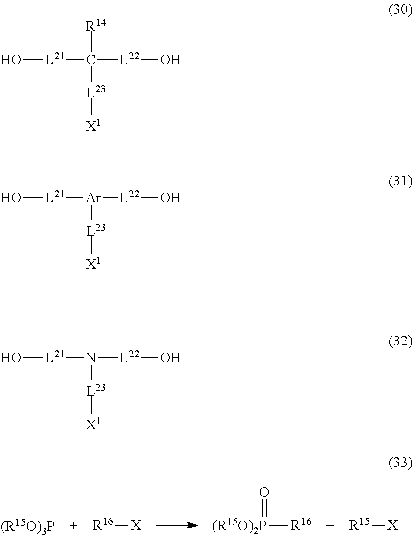

In the formulae, R¹⁴, L²¹, L²², L²³ and Ar have the same meanings as R¹⁰, L¹⁸, L¹⁹, L²⁰ and Ar, respectively, in formulae (27), (28) and (29). R¹⁵ represents an alkyl group or an aryl group, preferably an alkyl group having a carbon number of 1 to 8 or an aryl group having a carbon number of 6 to 15. R¹⁶ is a residue formed by removing X¹ in formula (30), (31) or (32), and X¹ represents a halogen atom, preferably Cl, Br or I.

Also, the synthesis is performed by a method of hydrolyzing the compound after the reaction with a phosphorous oxychloride represented by formula (34):

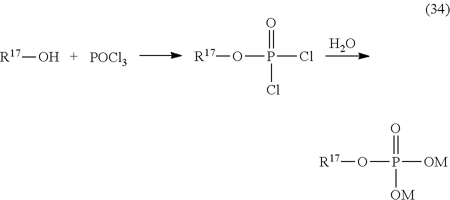

In the formulae, R¹⁷ has the same meaning as R¹⁵ in formula (33), and M represents a hydrogen atom, sodium or potassium.

In the case where the polyurethane resin of the present invention has a phosphonic acid group, the resin may be also synthesized by reacting a diisocyanate compound represented by formula (4) and a phosphoric acid ester group-containing diol compound represented by formula (27), (28) or (29), thereby effecting polyurethane resin formation, and then hydrolyzing the resin with hydrogen bromide or the like.

Similarly to the diol compound, an amino group-containing compound represented by the following formula (35) or (36) may be also reacted with a diisocyanate compound represented by formula (4) to form a urea structure and thereby incorporated into the polyurethane resin structure.

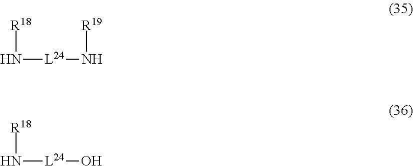

In the formulae, R¹⁸ and R¹⁹ may be the same or different and each represents a hydrogen atom or an alkyl, aralkyl or aryl group which may have a substituent (for example, an alkoxy group, a halogen atom (—F, —Cl, —Br, —I), an ester group or a carboxyl group), preferably represents a hydrogen atom, an alkyl group having a carbon number of 1 to 8, which may have a carboxyl group as the substituent, or an aryl group having a carbon number of 6 to 15. L²⁴ represents a divalent aliphatic hydrocarbon, an aromatic hydrocarbon group or a heterocycle group, which may have a substituent (for example, an alkyl group, an aralkyl group, an aryl group, an alkoxy group, an aryloxy group, a halogen atom (—F, —Cl, —Br, —I) or a carboxyl group). If desired, L²⁴ may have another functional group incapable of reacting with an isocyanate group, such as carbonyl group, ester group, urethane group and amido group. Incidentally, two members out of R¹⁸, L²⁴ and R¹⁹ may form a ring.

Specific examples of the compounds represented by formulae (35) and (36) include the followings:

an aliphatic diamine compound such as ethylenediamine, propylenediamine, tetramethylenediamine, pentamethylenediamine, hexamethylenediamine, heptamethylenediamine, octamethylenediamine, dodecamethylenediamine, propane-1,2-diamine, bis(3-aminopropyl)methyl amine, 1,3-bis(3-aminopropyl)tetramethylsiloxane, piperazine, 2,5-dimethylpiperazine, N-(2-aminoethyl)piperazine, 4-amino-2,2-6,6-tetramethylpiperidine, N,N-dimethylethylenediamine, lysine, L-cystine and isophoronediamine;

an aromatic diamine compound such as o-phenylenediamine, m-phenylenediamine, p-phenylenediamine, 2,4-tolylenediamine, benzidine, o-ditoluidine, o-dianisidine, 4-nitro-m-phenylenediamine, 2,5-dimethoxy-p-phenylenediamine, bis-(4-aminophenyl)sulfone, 4-carboxy-o-phenylenediamine, 3-carboxy-m-phenylenediamine, 4,4′-diaminophenyl ether and 1,8-naphthalenediamine; a heterocyclic amine compound such as 2-aminoimidazole, 3-aminotriazole, 5-amino-1H-tetrazole, 4-aminopyrazole, 2-aminobenzimidazole, 2-amino-5-carboxy-triazole, 2,4-diamino-6-methyl-5-triazine, 2,6-diaminopyridine, L-histidine, DL-tryptophan and adenine; and

an aminoalcohol or aminophenol compound such as ethanolamine, N-methylethanolamine, N-ethylethanolamine, 1-amino-2-propanol, 1-amino-3-propanol, 2-aminoethoxyethanol, 2-aminothioethoxyethanol, 2-amino-2-methyl-1-propanol, p-aminophenol, m-aminophenol, o-aminophenol, 4-methyl-2-aminophenol, 2-chloro-4-aminophenol, 4-methoxy-3-aminophenol, 4-hydroxybenzylamine, 4-amino-1-naphthol, 4-aminosalicylic acid, 4-hydroxy-N-phenylglycine, 2-aminobenzyl alcohol, 4-aminophenethyl alcohol, 2-carboxy-5-amino-1-naphthol and L-tyrosine.

The polyurethane resin is synthesized by heating the above-described isocyanate compound and diol compound in an aprotic solvent having added thereto a known catalyst having activity according to reactivity of each compound. The molar ratio between the diisocyanate compound and the diol compound used is preferably from 0.8:1 to 1.2:1, and when an isocyanate group remains in the polymer terminal, the polymer is treated with alcohols or amines, whereby the resin is finally synthesized with no remaining of an isocyanate group.

As the polyurethane resin, a resin having the above-described polymerizable group (such as unsaturated group) on the terminal, main chain or side chain of the polymer is also suitably used. The unsaturated group is, among others, preferably a carbon-carbon double bond in view of easy occurrence of a crosslinking reaction.

The method for introducing an unsaturated group into the polymer terminal include the following method. That is, the unsaturated group may be introduced by using unsaturated group-containing alcohols or amines in the treatment with alcohols or amines, which is applied when an isocyanate group remains in the polymer chain in the above-described process of synthesizing the polyurethane resin. Such a compound specifically includes the compounds illustrated below.

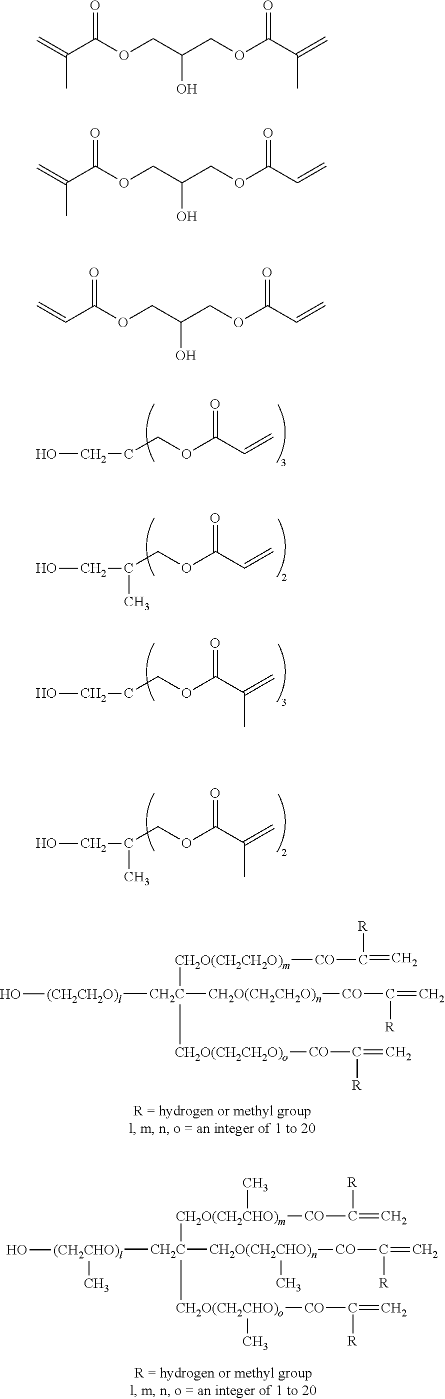

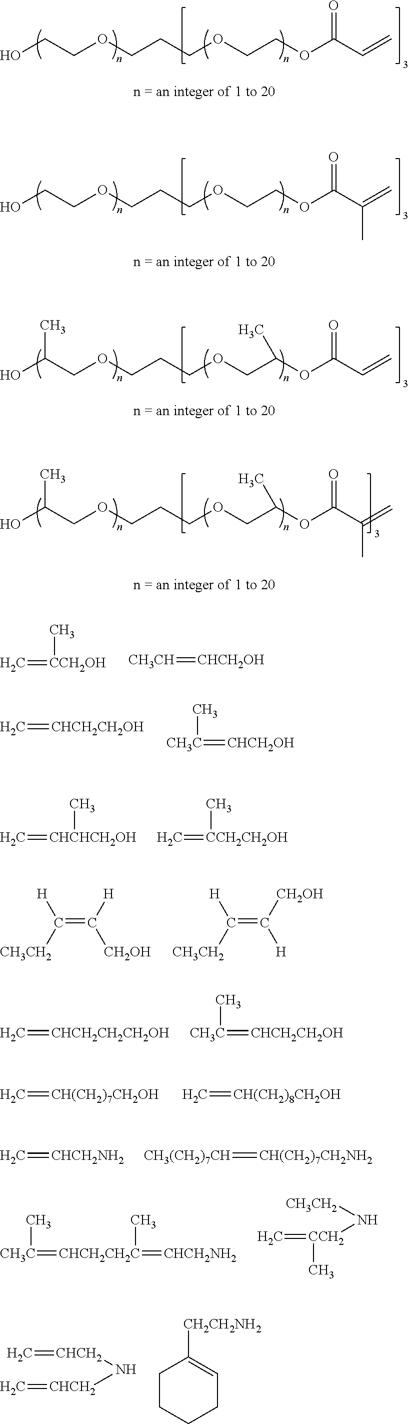

The method for introducing an unsaturated group into the main chain or the side chain includes a method of using a diol compound having an unsaturated group for the synthesis of the polyurethane resin. The diol compound having an unsaturated group specifically includes the following compounds.

Diol compounds represented by formulae (37) and (38). Specific examples thereof include the compounds described below.

HO—CH₂—C≡C—CH₂—OH (37)

HO—CH₂—CH═CH—CH₂—OH (38)

Specific examples of the diol compound represented by formula (37) include 2-butene-1,4-diol, and specific examples of the diol compound represented by formula (38) include cis-2-butene-1,4-diol and trans-2-butene-1,4-diol.

A diol compound having an unsaturated group in the side chain. Specific examples thereof include the compounds illustrated below.

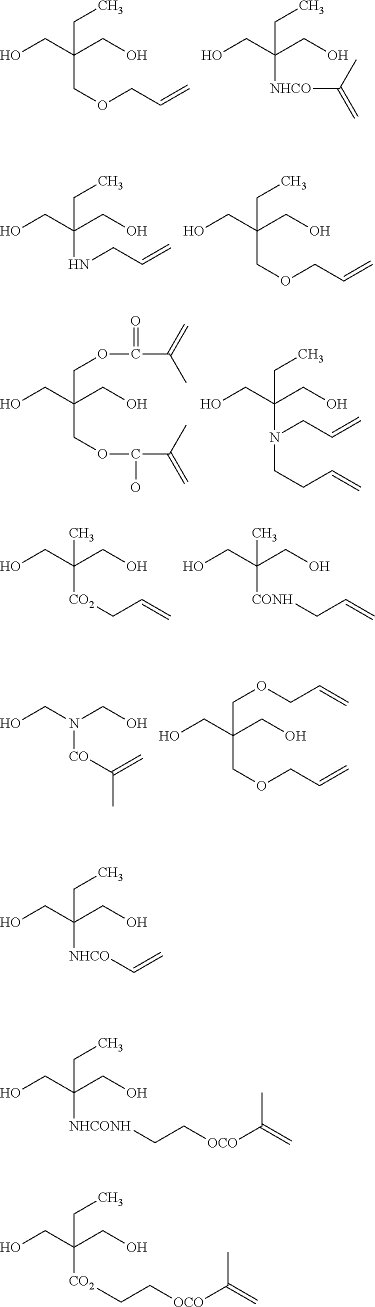

The polyurethane resin preferably contains an aromatic group in the main chain and/or the side chain. More preferably, the content of the aromatic group is from 10 to 80 wt % in the polyurethane resin.

In the case where the polyurethane resin is a polyurethane resin having a carboxyl group, the content of the carboxyl group is preferably 0.4 meq/g or more, more preferably from 0.4 to 3.5 meq/g.

The weight average molecular weight (Mw) of the resin (A) is preferably from 2,000 to 300,000, more preferably from 2,500 to 50,000, and most preferably from 3,000 to 35,000.

As for the resin (A), one resin may be used alone, or two or more resins may be used.

The content of the resin (A) is preferably from 10 to 70 mass %, more preferably from 15 to 65 mass %, still more preferably from 20 to 60 mass %, based on the total solid content of the adhesive composition.

### (B) Polymerizable Compound

The adhesive composition preferably contains a polymerizable compound (hereinafter, sometimes simply referred to as compound (B)).

The compound (B) is different from the resin (A). That is, the compound (B) is typically a low molecular compound and is preferably a low molecular compound having a molecular weight of 2,000 or less, more preferably a low molecular compound having a molecular weight of 1,500 or less, still more preferably a low molecular compound having a molecular weight of 900 or less. The molecular weight is usually 100 or more.

The polymerizable group in the polymerizable compound is a group capable of developing adhesiveness and at the same time, undergoing a reaction upon irradiation with an actinic ray or radiation to lose the polymerization activity and decrease the adhesiveness.

That is, the polymerizable compound can function as the above-described “adhesive capable of decreasing in the adhesiveness upon irradiation with an actinic ray or radiation”.

The polymerizable compound is usually a compound having a polymerizable group, and the polymerizable group is typically a group capable of polymerizing upon irradiation with an actinic ray or radiation or by the effect of a radical or an acid.

The polymerizable group is preferably, for example, a functional group capable of undergoing an addition polymerization reaction, and examples of the functional group capable of undergoing an addition polymerization reaction include an ethylenically unsaturated bond group, an amino group and an epoxy group. In addition, the polymerizable group may be also a functional group capable of generating a radical upon irradiation with light, and examples of such a polymerizable group include a thiol group and a halogen group. Above all, the polymerizable group is preferably an ethylenically unsaturated bond group. The ethylenically unsaturated bond group is preferably a styryl group, a (meth)acryloyl group or an allyl group.

The polymerizable compound is specifically selected from compounds having at least one, preferably two or more, polymerizable groups (such as terminal ethylenically unsaturated bond). These compounds are widely known in this industrial field and in the present invention, such compounds can be used without any particular limitation. The compound may have any chemical form such as monomer, prepolymer (that is, dimer, trimer or oligomer) or a mixture or multimer thereof. As for the polymerizable compound for use in the present invention, one compound may be used alone, or two or more compounds may be used in combination.

The reactive compound having a polymerizable group specifically includes (B 1) a radical polymerizable compound and (B2) ionic polymerizable compound.

The radical polymerizable compound usually has a radical polymerizable group. The radical polymerizable group is preferably an ethylenically unsaturated group, and the ethylenically unsaturated group is preferably a styryl group, a (meth)acryloyl group or an allyl group.

More specifically, examples of the monomer and a prepolymer thereof include an unsaturated carboxylic acid (such as acrylic acid, methacrylic acid, itaconic acid, crotonic acid, isocrotonic acid and maleic acid), its esters and amides, and a multimer thereof. Esters of an unsaturated carboxylic acid and an aliphatic polyhydric alcohol compound, amides of an unsaturated carboxylic acid and a polyvalent amine compound, and multimers thereof are preferred. In addition, for example, an addition reaction product of unsaturated carboxylic acid esters or amides having a nucleophilic substituent such as hydroxyl group, amino group and mercapto group, with monofunctional or polyfunctional isocyanates or epoxies, and a dehydration condensation reaction product with a monofunctional or polyfunctional carboxylic acid, may be also suitably used. Furthermore, an addition reaction product of unsaturated carboxylic acid esters or amides having an electrophilic substituent such as isocyanate group and epoxy group, with monofunctional or polyfunctional alcohols, amines or thiols, and a substitution reaction product of unsaturated carboxylic acid esters or amides having a leaving substituent such as halogen group and tosyloxy group, with monofunctional or polyfunctional alcohols, amines or thiols, are also preferred. As other examples, compounds where the above-described unsaturated carboxylic acid is replaced by an unsaturated phosphonic acid, a vinylbenzene derivative such as styrene, a vinyl ether, an allyl ether or the like, may be also used.

As for specific examples of the ester monomer of a polyhydric alcohol compound with an unsaturated carboxylic acid, examples of the acrylic acid ester include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, dipentaerythritol diacrylate, dipentaerythritol hexaacrylate, pentaerythritol tetraacrylate, sorbitol triacrylate, sorbitol tetraacrylate, sorbitol pentaacrylate, sorbitol hexaacrylate, tri(acryloyloxyethyl)isocyanurate, isocyanuric acid ethylene oxide (EO)-modified triacrylate, and polyester acrylate oligomer.

Examples of the methacrylic acid ester include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane and bis[p-(methacryloxyethoxy)phenyl]dimethylmethane.

Examples of the itaconic acid ester include ethylene glycol diitaconate, propylene glycol diitaconate, 1,3-butanediol diitaconate, 1,4-butanediol diitaconate, tetramethylene glycol diitaconate, pentaerythritol diitaconate and sorbitol tetraitaconate.

Examples of the crotonic acid ester include ethylene glycol dicrotonate, tetramethylene glycol dicrotonate, pentaerythritol dicrotonate and sorbitol tetradicrotonate.

Examples of the isocrotonic acid ester include ethylene glycol diisocrotonate, pentaerythritol diisocrotonate and sorbitol tetraisocrotonate.

Examples of the maleic acid ester include ethylene glycol dimaleate, triethylene glycol dimaleate, pentaerythritol dimaleate and sorbitol tetramaleate.

Other examples of the ester, which are suitably used, include aliphatic alcohol-based esters described in JP-B-46-27926 (the term “JP-B” as used herein means an “examined Japanese patent publication”), JP-B-51-47334 and JP-A-57-196231, those having an aromatic skeleton described in JP-A-59-5240, JP-A-59-5241 and JP-A-2-226149, and those containing an amino group described in JP-A-1-165613.

Specific examples of the amide monomer of a polyvalent amine compound with an unsaturated carboxylic acid include methylenebis-acrylamide, methylenebis-methacrylamide, 1,6-hexamethylenebis-acrylamide, 1,6-hexamethylenebis-methacrylamide, diethylenetriamine trisacrylamide, xylylenebisacrylamide and xylylenebismethacrylamide.

Other preferred examples of the amide-based monomer include those having a cyclohexylene structure described in JP-B-54-21726.

A urethane-based addition-polymerizable compound produced using an addition reaction of isocyanate with a hydroxyl group is also preferred, and specific examples thereof include a vinyl urethane compound having two or more polymerizable vinyl groups per molecule described in JP-B-48-41708, which is obtained by adding a hydroxyl group-containing vinyl monomer represented by the following formula (A) to a polyisocyanate compound having two or more isocyanate groups per molecule:

CH₂═C(R₄)COOCH₂CH(R₅)OH (A)

(wherein each of R₄ and R₅ represents H or CH₃).

In addition, urethane acrylates described in JP-A-51-37193, JP-B-2-32293 and JP-B-2-16765, and urethane compounds having an ethylene oxide-based skeleton described in JP-B-58-49860, JP-B-56-17654, JP-B-62-39417 and JP-B-62-39418 are also suitably used.

As for the polymerizable compound (radical polymerizable compound), the compounds described in paragraphs 0095 to 0108 of JP-A-2009-288705 may be suitably used also in the present invention.

An the polymerizable compound (radical polymerizable compound), an ethylenically unsaturated group-containing compound having, as a polymerizable monomer, at least one addition-polymerizable ethylene group and having a boiling point of 100° C. or more under normal pressure is also preferred. Examples thereof include a monofunctional acrylate or methacrylate such as polyethylene glycol mono(meth)acrylate, polypropylene glycol mono(meth)acrylate and phenoxyethyl (meth)acrylate; a polyfunctional acrylate or methacrylate such as polyethylene glycol di(meth)acrylate, trimethylolethane tri(meth)acrylate, neopentyl glycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl)isocyanurate, compound obtained by adding ethylene oxide or propylene oxide to a polyfunctional alcohol (e.g., glycerin, trimethylolethane) and (meth)acrylating the adduct, urethane (meth)acrylates described in JP-B-48-41708, JP-B-50-6034 and JP-A-51-37193, polyester acrylates described in JP-A-48-64183, JP-B-49-43191 and JP-B-52-30490, and epoxy acrylates as a reaction product of epoxy resin and (meth)acrylic acid; and a mixture thereof.

Examples of the compound further include a polyfunctional (meth)acrylate obtained by reacting a polyfunctional carboxylic acid with a compound having a cyclic ether group and an ethylenically unsaturated group, such as glycidyl (meth)acrylate.

As other preferred polymerizable compounds, the compounds having a fluorene ring and a bifunctional or higher functional ethylenically polymerizable group, described in JP-A-2010-160418, JP-A-2010-129825 and Japanese Patent 4,364,216, and a cardo resin may be also used.

Other examples of the polymerizable compound include specific unsaturated compounds described in JP-B-46-43946, JP-B-1-40337 and JP-B-1-40336, and a vinyl phosphonic acid-based compound described in JP-A-2-25493. In some cases, a structure containing a perfluoroalkyl group described in JP-A-61-22048 is suitably used. Furthermore, those described as a photocurable monomer or oligomer in Adhesion, Vol. 20, No. 7, pp. 300-308 (1984) may be also used.

As the compound having a boiling point of 100° C. or more under normal pressure and having at least one addition-polymerizable ethylenically unsaturated group, the compounds described in paragraphs [0254] to [0257] of JP-A-2008-292970 are also preferred.

In addition, radical polymerizable monomers represented by the following formulae (MO-1) to (MO-5) may be suitably used. In the formulae, when T is an oxyalkylene group, R is bonded to the terminal on the carbon atom side.

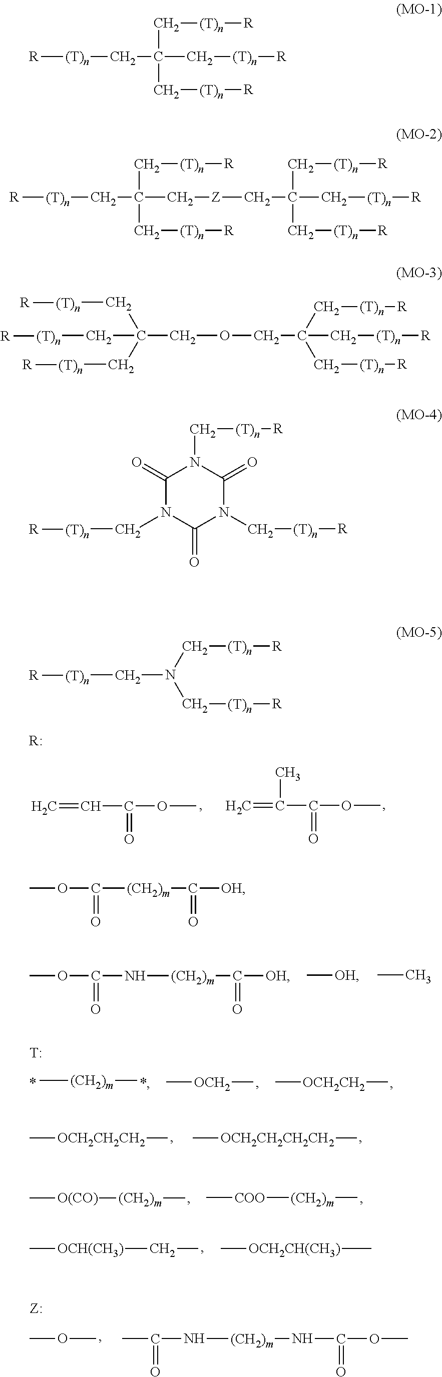

In the formulae, n is from 0 to 14 and m is from 1 to 8. Each R or T may be the same as or different from every other R or T present in one molecule.

In each of the radical polymerizable compounds represented by formulae (MO-1) to (MO-5), at least one of the plurality of R's represents a group represented by —OC(═O)CH═CH₂ or —OC(═O)C(CH₃)═CH₂.

As for specific examples of the radical polymerizable compounds represented by formulae (MO-1) to (MO-5), the compounds described in paragraphs 0248 to 0251 of JP-A-2007-269779 may be suitably used also in the present invention.

Compounds obtained by adding an ethylene oxide or a propylene oxide to the above-described polyfunctional alcohol and (meth)acrylating the adduct, described as the compounds of formulae (1) and (2) together with their specific examples in JP-A-10-62986, may be also used as the polymerizable compound.

Above all, preferred polymerizable compounds (radical polymerizable compounds) are dipentaerythritol triacrylate (as a commercial product, KAYARAD D-330, produced by Nippon Kayaku Co., Ltd.), dipentaerythritol tetraacrylate (as a commercial product, KAYARAD D-320, produced by Nippon Kayaku Co., Ltd.), dipentaerythritol penta(meth)acrylate (as a commercial product, KAYARAD D-310, produced by Nippon Kayaku Co., Ltd.), dipentaerythritol hexa(meth)acrylate (as a commercial product, KAYARAD DPHA, produced by Nippon Kayaku Co., Ltd.), and structures where the (meth)acryloyl group of these compounds is bonded through an ethylene glycol or propylene glycol residue. Their oligomer types may be also used.

The polymerizable compound (radical polymerizable compound) may be a polyfunctional monomer having an acid group such as carboxyl group, sulfonic acid group and phosphoric acid group. Accordingly, an ethylenic compound having an unreacted carboxyl group as in the case of the mixture above may be directly used, but, if desired, a non-aromatic carboxylic anhydride may be reacted with a hydroxyl group of the above-described ethylenic compound to introduce an acid group. In this case, specific examples of the non-aromatic carboxylic anhydride include tetrahydrophthalic anhydride, alkylated tetrahydrophthalic anhydride, hexahydrophthalic anhydride, alkylated hexahydrophthalic anhydride, succinic anhydride, and maleic anhydride.

In the present invention, the acid group-containing monomer is preferably a polyfunctional monomer which is an ester of an aliphatic polyhydroxy compound and an unsaturated carboxylic acid and is imparted with an acid group by reacting a non-aromatic carboxylic anhydride with an unreacted hydroxyl group of an aliphatic polyhydroxy compound, more preferably the ester above where the aliphatic polyhydroxy compound is pentaerythritol and/or dipentaerythritol. Examples of the commercial product thereof include polybasic acid-modified acryl oligomers M-510 and M-520 produced by Toagosei Co., Ltd.

One of these monomers may be used alone, but since it is difficult in view of production to use a single compound, two or more monomers may be mixed and used. Also, as the monomer, an acid group-free polyfunctional monomer and an acid group-containing monomer may be used in combination, if desired. The acid value of the acid group-containing polyfunctional monomer is preferably from 0.1 to 40 mg-KOH/g, more preferably from 5 to 30 mg-KOH/g. If the acid value of the polyfunctional monomer is too low, the developer solubility characteristics are reduced, whereas if it is excessively high, production or handling becomes difficult and the photopolymerization performance is reduced to impair the curability such as surface smoothness of pixel. Accordingly, in the case where two or more polyfunctional monomers differing in the acid group are used in combination or where an acid group-free polyfunctional monomer is used in combination, the monomers must be adjusted such that the acid value of the entire polyfunctional monomer falls in the range above.

Also, it is preferred to contain, as a polymerizable monomer, a polyfunctional monomer having a caprolactone structure.

The polyfunctional monomer having a caprolactone structure is not particularly limited as long as it has a caprolactone structure in a molecule thereof, but examples thereof include an ε-caprolactone-modified polyfunctional (meth)acrylate obtained by esterifying a polyhydric alcohol such as trimethylolethane, ditrimethylolethane, trimethylolpropane, ditrimethylolpropane, pentaerythritol, dipentaerythritol, tripentaerythritol, glycerin, diglycerol, trimethylolmelamine, with a (meth)acrylic acid and ε-caprolactone. Among others, a polyfunctional monomer having a caprolactone structure represented by the following formula (1) is preferred:

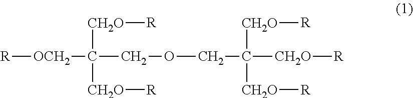

(wherein all of six R's are a group represented by the following formula (2) or from 1 to 5 members out of six R's are a group represented by the following formula (2), with the remaining members being a group represented by the following formula (3)):

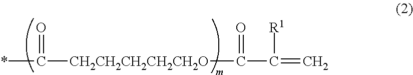

(wherein R¹ represents a hydrogen atom or a methyl group, m represents a number of 1 or 2, and “*” indicates a bond).

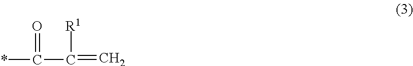

(wherein R¹ represents a hydrogen atom or a methyl group, and “*” indicates a bond).

The polyfunctional monomer having a caprolactone structure is commercially available as KAYARAD DPCA Series from Nippon Kayaku Co., Ltd., and examples thereof include DPCA-20 (a compound where in formulae (1) to (3), m=1, the number of groups represented by formula (2)=2, and all R¹s are a hydrogen atom), DPCA-30 (a compound where in the same formulae, m=1, the number of groups represented by formula (2)=3, and all R¹s are a hydrogen atom), DPCA-60 (a compound where in the same formulae, m=1, the number of groups represented by formula (2)=6, and all R¹s are a hydrogen atom), and DPCA-120 (a compound where in the same formulae, m=2, the number of groups represented by the general formula (2)=6, and all R¹s are a hydrogen atom). In the present invention, as for the polyfunctional monomer having a caprolactone structure, one monomer may be used alone, or two or more monomers may be mixed and used.

It is also preferred that the polyfunctional monomer is at least one compound selected from the group consisting of the compounds represented by the following formulae (i) and (ii):

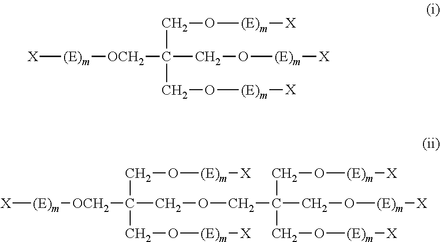

In formulae (i) and (ii), each E independently represents —((CH₂)_{y}CH₂O)— or —((CH₂)_{y}CH(CH₃)O)—, each y independently represents an integer of 0 to 10, and each X independently represents an acryloyl group, a methacryloyl group, a hydrogen atom or a carboxyl group.

In formula (i), the total number of acryloyl groups and methacryloyl groups is 3 or 4, each m independently represents an integer of 0 to 10, and the total of respective m is an integer of 0 to 40, provided that when the total of respective m is 0, any one X is a carboxyl group.

In formula (ii), the total number of acryloyl groups and methacryloyl group is 5 or 6, each n independently represents an integer of 0 to 10, and the total of respective n is an integer of 0 to 60, provided that when the total of respective n is 0, any one X is a carboxyl group.

In formula (i), m is preferably an integer of 0 to 6, more preferably an integer of 0 to 4, and the total of respective m is preferably an integer of 2 to 40, more preferably an integer of 2 to 16, still more preferably an integer of 4 to 8.

In formula (ii), n is preferably an integer of 0 to 6, more preferably an integer of 0 to 4, and the total of respective n is preferably an integer of 3 to 60, more preferably an integer of 3 to 24, still more preferably an integer of 6 to 12.

In a preferred embodiment of —((CH₂)_{y}CH₂O)— or —((CH₂)_{y}CH(CH₃)O)— in formula (i) or (ii), the terminal on the oxygen atom side is bonded to X.

As for the compound represented by formula (i) or (ii), one compound may be used alone, or two or more compounds may be used in combination. In particular, an embodiment where all of 6 X's in formula (Ii) are an acryloyl group is preferred.

The total content of the compound represented by formula (i) or (ii) in the polymerizable compound is preferably 20 mass % or more, more preferably 50 mass % or more.

The compound represented by formula (i) or (ii) can be synthesized through a step of binding a ring-opened skeleton of ethylene oxide or propylene oxide to pentaerythritol or dipentaerythritol by a ring-opening addition reaction, and a step of introducing a (meth)acryloyl group into the terminal hydroxyl group of the ring-opened skeleton by reacting, for example, (meth)acryloyl chloride, which are conventionally known steps. Each step is a well-known step, and the compound represented by formula (i) or (ii) can be easily synthesized by one skilled in the art.

Among the compounds represented by formulae (i) and (ii), a pentaerythritol derivative and/or a dipentaerythritol derivative are preferred.

The compounds specifically include the compounds represented by the following formulae (a) to (f) (hereinafter, sometimes referred to as “compounds (a) to (f)”), and compounds (a), (b), (e) and (f) are preferred.

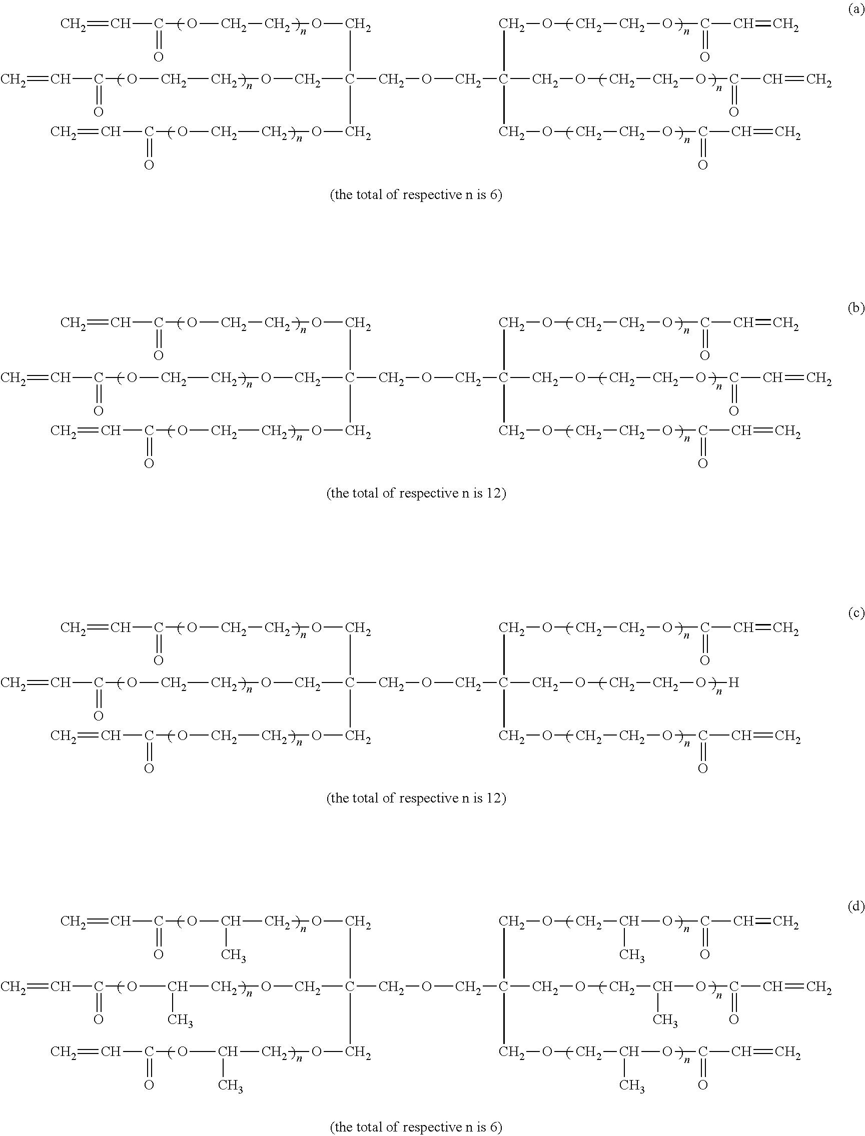

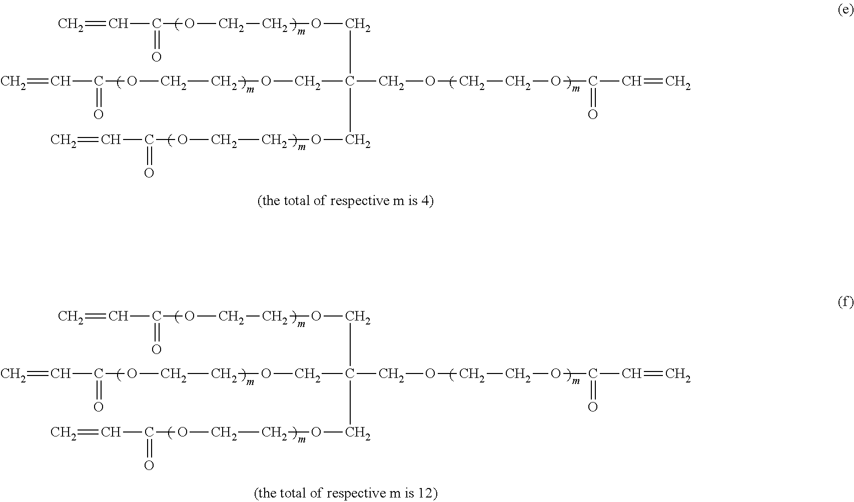

Examples of the commercial product of the monomers (radical polymerizable compounds) represented by formulae (i) and (ii) include SR-494 produced by Sartomer Company, Inc., which is a tetrafunctional acrylate having four ethyleneoxy chains; and DPCA-60 which is a hexafunctional acrylate having six pentyleneoxy chains, and TPA-330 which is a trifunctional acrylate having three isobutyleneoxy chains, both produced by Nippon Kayaku Co., Ltd.

Furthermore, urethane acrylates described in JP-B-48-41708, JP-A-51-37193, JP-B-2-32293 and JP-B-2-16765, and urethane compounds having an ethylene oxide-based skeleton described in JP-B-58-49860, JP-B-56-17654, JP-B-62-39417 and JP-B-62-39418, are also suitable as the polymerizable compound (radical polymerizable compound). In addition, addition-polymerizable compounds having an amino structure or a sulfide structure in the molecule described in JP-A-63-277653, JP-A-63-260909 and JP-A-1-105238 may be also used as the polymerizable compound.

Examples of the commercial product of the polymerizable compound include Urethane Oligomers UAS-10, UAB-140 (both produced by Sanyo Kokusaku Pulp Co., Ltd.), UA-7200 (produced by Shin-Nakamura Chemical Co., Ltd.), DPHA-40H (produced by Nippon Kayaku Co., Ltd.), UA-306H, UA-306T, UA-306I, AH-600, T-600, and AI-600 (all produced by Kyoeisha Chemical Co., Ltd.).

A polyfunctional thiol compound having two or more mercapto (SH) group in the same molecule is also suitable as the polymerizable compound (radical polymerizable compound). In particular, a compound represented by the following formula (I) is preferred:

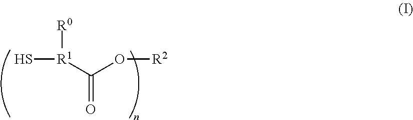

(wherein R¹ represents an alkyl group, R² represents an n-valent aliphatic group which may contain an atom other than carbon, R⁰ represents an alkyl group but not H, and n represents 2 to 4).

Specific examples of the polyfunctional thiol compound represented by formula (I) include compounds having the following structural formulae, that is, 1,4-bis(3-mercaptobutyryloxy)butane [formula (II)], 1,3,5-tris(3-mercaptobutyryloxyethyl)-1,3,5-triazine-2,4,6(1H,3H,5H)-trione [formula (III)], and pentaerythritol tetrakis(3-mercaptobutyrate) [formula (IV)]. One of these polyfunctional thiols may be used, or a plurality thereof may be used in combination.

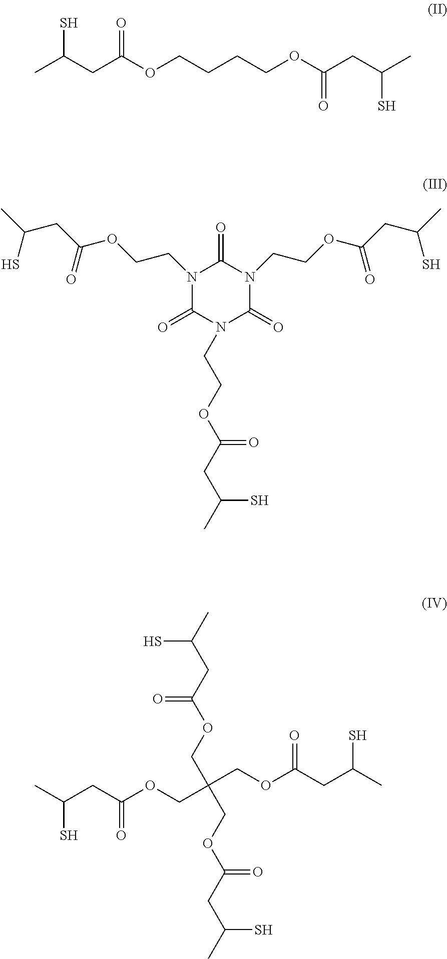

The blending amount of the polyfunctional thiol compound in the adhesive composition is preferably from 0.3 to 8.9 wt %, more preferably from 0.8 to 6.4 wt %, based on the total solid content excluding the solvent. By the addition of the polyfunctional thiol, the stability, odor, sensitivity, adherence and the like of the adhesive composition can be improved.

As for the polymerizable compound (radical polymerizable compound), details of the structure and the use method such as single or combination use and added amount, may be arbitrarily set according to the design of final performance of the adhesive composition. For example, in view of sensitivity (efficiency in decreasing the adhesiveness with respect to irradiation with an actinic ray or radiation), a structure having a large unsaturated group content per molecular is preferred, and in many cases, a bifunctional or higher functional structure is preferred. From the standpoint of increasing the strength of the adhesive layer, a trifunctional or higher functional compound is preferred, and a method where polymerizable groups differing in the functional number or differing in the polymerizable group (for example, an acrylic acid ester, a methacrylic acid ester, a styrene-based compound and a vinyl ether-based compound) are used in combination to control both the sensitivity and the strength, is also effective. Furthermore, a combination use of trifunctional or higher functional polymerizable compounds differing in the ethylene oxide chain length is preferred. The selection and use method of the polymerizable compound are also important factors for the compatibility and dispersibility with other components (for example, the resin (A) and a polymerization initiator) contained in the adhesive composition. For example, the compatibility can be sometimes enhanced by using a low-purity compound or using two or more kinds of compounds in combination. Also, a specific structure may be selected with the purpose of improving the adherence to a carrier substrate.

The ionic polymerizable compound (B2) includes, for example, (B21) an epoxy compound having a carbon number of 3 to 20 and (B22) an oxetane compound having a carbon number of 4 to 20.

The epoxy compound (B21) having a carbon number of 3 to 20 includes, for example, the following monofunctional or polyfunctional epoxy compounds.

Examples of the monofunctional epoxy compound include phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cylcohexene oxide, 3-methacryloyloxymethylcylcohexeneoxide, 3-acryloyloxymethylcylcohexeneoxide, and 3-vinylcylcohexeneoxide.

Examples of the polyfunctional epoxy compound include bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, epoxy novolak resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexane carboxylate, 2-(3,4-epoxycyclohexyl-5,5-spiro-3,4-epoxy)cyclohexane-meta-dioxane, bis(3,4-epoxycyclohexylmethyl) adipate, vinylcylcohexene oxide, 4-vinylepoxycyclohexane, bis(3,4-epoxy-6-methylcyclohexylmethyl) adipate, 3,4-epoxy-6-methylcyclohexyl-3′,4′-epoxy-6′-methylcyclohexane carboxylate, methylenebis(3,4-epoxycyclohexane), dicyclopentadiene diepoxide, ethylene glycol di(3,4-epoxycyclohexylmethyl)ether, ethylenebis(3,4-epoxycyclohexane carboxylate), dioctyl epoxyhexahydrophthalate, di-2-ethylhexyl epoxyhexahydrophthalate, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers, 1,1,3-tetradecadiene dioxide, limonene dioxide, 1,2,7,8-diepoxyoctane, and 1,2,5,6-diepoxycyclooctane.

Among these epoxy compounds, in view of excellent polymerization speed, an aromatic epoxide and an alicyclic epoxide are preferred, and an alicyclic epoxide is more preferred.

The oxetane compound (B22) having a carbon number of 4 to 20 includes, for example, compounds having from one to six oxetane rings.

Examples of the compound having one oxetane ring include 3-ethyl-3-hydroxymethyloxetane, 3-(meth)allyloxymethyl-3-ethyloxetane, (3-ethyl-3-oxetanylmethoxy)methylbenzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenyl ether, isobutoxymethyl(3-ethyl-3-oxetanylmethyl)ether, isobornyloxyethyl(3-ethyl-3-oxetanylmethyl)ether, isobornyl(3-ethyl-3-oxetanylmethyl)ether, 2-ethylhexyl(3-ethyl-3-oxetanylmethyl)ether, ethyldiethylene glycol(3-ethyl-3-oxetanylmethyl)ether, dicyclopentadiene(3-ethyl-3-oxetanylmethyl)ether, dicyclopentenyloxyethyl(3-ethyl-3-oxetanylmethyl)ether, dicyclopentenyl(3-ethyl-3-oxetanylmethypether, tetrahydrofurfuryl(3-ethyl-3-oxetanylmethyl)ether, tetrabromophenyl(3-ethyl-3-oxetanylmethyl)ether, 2-tetrabromophenoxyethyl(3-ethyl-3-oxetanylmethyl)ether, tribromophenyl(3-ethyl-3-oxetanylmethypether, 2-tribromophenoxyethyl(3-ethyl-3-oxetanylmethyl)ether, 2-hydroxyethyl(3-ethyl-3-oxetanylmethyl)ether, 2-hydroxypropyl(3-ethyl-3-oxetanylmethyl)ether, butoxyethyl(3-ethyl-3-oxetanylmethyl)ether, pentachlorophenyl(3-ethyl-3-oxetanylmethyl)ether, pentabromophenyl(3-ethyl-3-oxetanylmethypether, and bornyl(3-ethyl-3-oxetanylmethyl)ether.

Examples of the compound having two to six oxetane rings include 3,7-bis(3-oxetanyl)-5-oxa-nonane, 3,3′-(1,3-(2-methylenyl)propanediyl bis(oxymethylene))bis-(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methyl]propane, ethylene glycol bis(3-ethyl-3-oxetanylmethypether, dicyclopentenyl bis(3-ethyl-3-oxetanylmethyl)ether, triethylene glycol bis(3-ethyl-3-oxetanylmethypether, tetraethylene glycol bis(3-ethyl-3-oxetanylmethypether, tricyclodecanediyl dimethylene(3-ethyl-3-oxetanylmethyl)ether, trimethylolpropane tris(3-ethyl-3-oxetanylmethypether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethypether, polyethylene glycol bis(3-ethyl-3-oxetanylmethypether, dipentaerythritol hexakis(3-ethyl-3-oxetanylmethypether, dipentaerythritol pentakis(3-ethyl-3-oxetanylmethypether, dipentaerythritol tetrakis(3-ethyl-3-oxetanylmethypether, caprolactone-modified dipentaerythritol hexakis(3-ethyl-3-oxetanylmethypether, caprolactone-modified dipentaerythritol pentakis(3-ethyl-3-oxetanylmethypether, ditrimethylolpropane tetrakis(3-ethyl-3-oxetanylmethypether, EO-modified bisphenol A bis(3-ethyl-3-oxetanylmethyl)ether, PO-modified bisphenol A bis(3-ethyl-3-oxetanylmethypether, EO-modified hydrogenated bisphenol A bis(3-ethyl-3-oxetanylmethypether, PO-modified hydrogenated bisphenol A bis(3-ethyl-3-oxetanylmethypether, and EO-modified bisphenol F (3-ethyl-3-oxetanylmethypether.

The content of the polymerizable compound in the adhesive composition of the present invention is preferably from 20 to 95 mass %, more preferably from 25 to 90 mass %, still more preferably from 30 to 80 mass %, based on the solid content in the adhesive composition.

The ratio (mass ratio) of the contents of the polymerizable compound (B) and the resin (A) is preferably from 90/10 to 10/90, more preferably from 20/80 to 80/20.

### (C) Polymerization Initiator

From the standpoint of enhancing the sensitivity, the adhesive composition of the present invention preferably contains a polymerization initiator.

The polymerization initiator for use in the present invention includes a photopolymerization initiator (typically a compound capable of generating a radical or an acid upon irradiation with an actinic ray or radiation) and a thermal polymerization initiator (typically a compound capable of generating a radical or an acid by heat).

### (Photopolymerization Initiator)

By containing a photopolymerization initiator in the adhesive composition of the present invention, when the adhesive layer is irradiated with light, curing of the adhesive composition by a radical or an acid takes place, and the adhesiveness in the light-irradiated area is decreased. For example, when the irradiation is applied to the central part of the adhesive layer and the adhesiveness is allowed to remain only in the marginal part, this has not only the above-described advantage but also the advantage that the adhesive layer is reduced in the area to be dissolved by dipping in a solvent at the separation and the time required until separation is shortened.

As for the compound capable of generating a radical or an acid upon irradiation with an actinic ray or radiation, the following compounds known as a polymerization initiator can be used.

The polymerization initiator is not particularly limited as long as it has an ability of initiating the polymerization of the resin (A) or the polymerizable compound, and the initiator can be appropriately selected from known polymerization initiators. For example, a compound having photosensitivity to light in the region from ultraviolet to visible is preferred. The initiator may be an activator causing a certain action with a photoexcited sensitizer to produce an active radical or an initiator capable of initiating cationic polymerization according to the kind of the monomer.

The polymerization initiator preferably contains at least one compound having a molecule extinction coefficient of at least about 50 in the range of approximately from 300 to 800 nm (more preferably from 330 to 500 nm).

As the polymerization initiator, known compounds can be used without limitation, but examples thereof include a halogenated hydrocarbon derivative (for example, a compound having a triazine skeleton, a compound having an oxadiazole skeleton, and a compound having a trihalomethyl group), an acylphosphine compound such as acylphosphine oxide, hexaarylbiimidazole, an oxime compound such as oxime derivative, an organic peroxide, a thio compound, a ketone compound, an aromatic onium salt, a ketoxime ether, an aminoacetophenone compound, hydroxyacetophenone, an azo-based compound, an azide compound, a metallocene compound, an organoboron compound, and an iron-arene complex.

Examples of the halogenated hydrocarbon compound having a triazine skeleton include the compounds described in Wakabayashi et al., Bull. Chem. Soc. Japan, 42, 2924 (1969), the compounds described in Britain Patent 1,388,492, the compounds described in JP-A-53-133428, the compounds described in Germany Patent 3,337,024, the compounds described in F. C. Schaefer et al., J. Org. Chem., 29, 1527 (1964), the compounds described in JP-A-62-58241, the compounds described in JP-A-5-281728, the compounds described in JP-A-5-34920, and the compounds described in U.S. Pat. No. 4,212,976.

The compounds described in U.S. Pat. No. 4,212,976 include, for example, a compound having an oxadiazole skeleton (e.g., 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole, 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxystyryl)-1,3,4-oxadiazole, 2-tribromomethyl-5-styryl-1,3,4-oxadiazole).

Examples of the polymerization initiator other than those described above include an acridine derivative (such as 9-phenylacridine and 1,7-bis(9,9′-acridinyl)heptane), N-phenylglycine, a polyhalogen compound (such as carbon tetrabromide, phenyl tribromomethyl sulfone and phenyl trichloromethyl ketone), coumarins (such as 3-(2-benzofuranoyl)-7-diethylaminocoumarin, 3-(2-benzofuroyl)-7-(1-pyrrolidinyl)coumarin, 3-benzoyl-7-diethylaminocoumarin, 3-(2-methoxybenzoyl)-7-diethylaminocoumarin, 3-(4-dimethylaminobenzoyl)-7-diethylaminocoumarin, 3,3′-carbonylbis(5,7-di-n-propoxycoumarin), 3,3′-carbonylbis(7-diethylaminocoumarin), 3-benzoyl-7-methoxycoumarin, 3-(2-furoyl)-7-diethylaminocoumarin, 3-(4-diethylaminocinnamoyl)-7-diethylaminocoumarin, 7-methoxy-3-(3-pyridylcarbonyl)coumarin, 3-benzoyl-5,7-dipropoxycoumarin, 7-benzotriazol-2-ylcoumarin and coumarin compounds described in JP-A-5-19475, JP-A-7-271028, JP-A-2002-363206, JP-A-2002-363207, JP-A-2002-363208 and JP-A-2002-363209), acylphosphine oxides (such as bis(2,4,6-trimethylbenzoyl)-phenylphosphine oxide, bis(2,6-dimethoxybenzoyl)-2,4,4-trimethyl-pentylphenylphosphine oxide and Lucirin TPO), metallocenes (such as bis(η5-2,4-cyclopentadien-1-yl)-bis(2,6-difluoro-3-(1H-pyrrol-1-yl)-phenyptitanium and η5-cyclopentadienyl-η6-cumenyl-iron(1+)-hexafluorophosphate (1−)), and the compounds described in JP-A-53-133428, JP-B-57-1819, JP-B-57-6096, and U.S. Pat. No. 3,615,455.

Examples of the ketone compound include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, a benzophenonetetracarboxylic acid or a tetramethyl ester thereof, 4,4′-bis(dialkylamino)benzophenones (such as 4,4′-bis(dimethylamino)benzophenone, 4,4′-bis(dicyclohexylamino)benzophenone, 4,4′-bis(diethylamino)benzophenone, 4,4′-bis(dihydroxyethylamino)benzophenone, 4-methoxy-4′-dimethylaminobenzophenone, 4,4′-dimethoxybenzophenone, 4-dimethylaminobenzophenone, 4-dimethylaminoacetophenone, benzyl, anthraquinone, 2-tert-butylanthraquinone, 2-methylanthraquinone, phenanthraquinone, xanthone, thioxanthone, 2-chloro-thioxanthone, 2,4-diethylthioxanthone, fluorenone, 2-benzyl-dimethylamino-1-(4-morpholinophenyl)-1-butanone, 2-methyl-[4-(methylthio)phenyl]-2-morpholino-1-propanone, 2-hydroxy-2-methyl-[4-(1-methylvinyl)phenyl]propanol oligomer, benzoin, benzoin ethers (such as benzoin methyl ether, benzoin ethyl ether, benzoin propyl ether, benzoin isopropyl ether, benzoin phenyl ether, benzyl dimethyl ketal), acridone, chloroacridone, N-methylacridone, N-butylacridone, and N-butyl-chloroacridone.

As the polymerization initiator (photopolymerization initiator), a hydroxyacetophenone compound, an aminoacetophenone compound, and an acylphosphine compound may be also suitably used. More specifically, for example, an aminoacetophenone-based initiator described in JP-A-10-291969 and an acylphosphine oxide-based initiator described in Japanese Patent 4225898 may be used.

As for the hydroxyacetophenone-based initiator, IRGACURE-184, DAROCUR-1173, IRGACURE-500, IRGACURE-2959 and IRGACURE-127 (trade names, all produced by CIBA Japan) may be used. As for the aminoacetophenone-based initiator, commercial products IRGACURE-907, IRGACURE-369 and IRGACURE-379 (trade names, all produced by CIBA Japan) may be used. The compounds described in JP-A-2009-191179, where the absorption wavelength is adjusted to match the long wavelength light source of, for example, 365 nm or 405 nm, may be also used as the aminoacetophenone-based initiator. As for the acylphosphine-based initiator, commercial products IRGACURE-819 and DAROCUR-TPO (trade names, both produced by CIBA Japan) may be used.

The polymerization initiator (photopolymerization initiator) is more preferably an oxime-based compound. Specific examples of the oxime-based initiator which can be used include the compounds described in JP-A-2001-233842, the compounds describe in JP-A-2000-80068, and the compounds described in JP-A-2006-342166.

Examples of the oxime compound such as oxime derivative, which is suitably used as the polymerization initiator in the present invention, include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Examples of the oxime ester compound include the compounds described in J. C. S. Perkin II, pp. 1653-1660 (1979), J. C. S. Perkin II, pp. 156-162 (1979), Journal of Photopolymer Science and Technology, pp. 202-232 (1995), JP-A-2000-66385, JPA-2000-80068, JP-T-2004-534797, and JP-A-2006-342166.

As the commercial product, IRGACURE-OXE01 (produced by CIBA Japan), IRGACURE-OXE02 (produced by CIBA Japan) and TR-PBG-304 (produced by Changzhou Tronly New Electronic Materials Co., Ltd.) may be also suitably used.

As the oxime ester compound other than those described above, there may be used, for example, the compounds described in JP-T-2009-519904, where oxime is connected to the N-position of carbazole, the compounds described in U.S. Pat. No. 7,626,957, where a hetero-substituent is introduced into the benzophenone moiety, the compounds described in JP-A-2010-15025 and U.S. Patent Application Publication 2009-292039, where a nitro group is introduced into the dye moiety, the ketoxime-based compounds described in International Publication 2009-131189, the compounds described in U.S. Pat. No. 7,556,910, containing a triazine skeleton and an oxide skeleton within the same molecule, and the compounds described in JP-A-2009-221114, having an absorption maximum at 405 nm and exhibiting good sensitivity to a g-line light source.

Furthermore, cyclic oxime compounds described in JP-A-2007-231000 and JP-A-2007-322744 may be also suitably used. Among cyclic oxime compounds, the cyclic oxime compounds fused to a carbazole dye, described in JP-A-2010-32985 and JP-A-2010-185072, have high light absorptivity and are preferred in view of achieving high sensitivity.

Also, the compounds described in JP-A-2009-242469, having an unsaturated bond at a specific site of an oxime compound, can achieve high sensitivity by regenerating an active radical from a polymerization inactive radical and therefore, can be suitably used.

Most preferred compounds are an oxime compound having a specific substituent described in JP-A-2007-269779 and an oxime compound having a thioaryl group described in JP-A-2009-191061.

Specifically, the oxime-based polymerization initiator is preferably a compound represented by the following formula (OX-1). Incidentally, the compound may be an oxime compound where the N—O bond of oxime is (E) form, an oxime compound of (Z) form, or a mixture of (E) form and (Z) form.

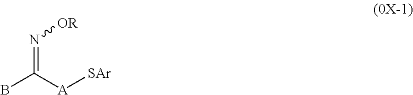

(In formula (OX-1), each of R and B independently represents a monovalent substituent, A represents a divalent organic group, and Ar represents an aryl group.)

In formula (OX-1), the monovalent substituent represented by R is preferably a monovalent nonmetallic atom group.

Examples of the monovalent nonmetallic atom group include an alkyl group, an aryl group, an acyl group, an alkoxycarbonyl group, an aryloxycarbonyl group, a heterocyclic group, an alkylthiocarbonyl group, and an arylthiocarbonyl group. These groups may have one or more substituents. Also, the substituent may be further substituted with another substituent.

Examples of the substituent include a halogen atom, an aryloxy group, an alkoxycarbonyl group, an aryloxycarbonyl group, an acyloxy group, an acyl group, an alkyl group, an aryl group.

The alkyl group which may have a substituent is preferably an alkyl group having a carbon number of 1 to 30, and specific examples thereof include a methyl group, an ethyl group, a propyl group, a butyl group, a hexyl group, an octyl group, a decyl group, a dodecyl group, an octadecyl group, an isopropyl group, an isobutyl group, a sec-butyl group, a tert-butyl group, a 1-ethylpentyl group, a cyclopentyl group, a cyclohexyl group, a trifluoromethyl group, a 2-ethylhexyl group, a phenacyl group, a 1-naphthoylmethyl group, a 2-naphthoylmethyl group, a 4-methylsulfanylphenacyl group, a 4-phenylsulfanylphenacyl group, a 4-dimethylaminophenacyl group, a 4-cyanophenacyl group, a 4-methylphenacyl group, a 2-methylphenacyl group, a 3-fluorophenacyl group, a 3-trifluoromethylphenacyl group, and a 3-nitrophenacyl group.

The aryl group which may have a substituent is preferably an aryl group having a carbon number of 6 to 30, and specific examples thereof include a phenyl group, a biphenyl group, a 1-naphthyl group, a 2-naphthyl group, a 9-anthryl group, a 9-phenanthryl group, a 1-pyrenyl group, a 5-naphthacenyl group, a 1-indenyl group, a 2-azulenyl group, a 9-fluorenyl group, a terphenyl group, a quaterphenyl group, an o-tolyl group, an m-tolyl group, a p-tolyl group, a xylyl group, an o-cumenyl group, an m-cumenyl group, a p-cumenyl group, a mesityl group, a pentalenyl group, a binaphthalenyl group, a ternaphthalenyl group, a quaternaphthalenyl group, a heptalenyl group, a biphenylenyl group, an indacenyl group, a fluoranthenyl group, an acenaphthylenyl group, an aceanthrylenyl group, a phenalenyl group, a fluorenyl group, an anthryl group, a bianthracenyl group, a teranthracenyl group, a quateranthracenyl group, an anthraquinolyl group, a phenanthryl group, a triphenylenyl group, a pyrenyl group, a chrysenyl group, a naphthacenyl group, a pleiadenyl group, a picenyl group, a perylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

The acyl group which may have a substituent is preferably an acyl group having a carbon number of 2 to 20, and specific examples thereof include an acetyl group, a propanoyl group, a butanoyl group, a trifluoroacetyl group, a pentanoyl group, a benzoyl group, a 1-naphthoyl group, a 2-naphthoyl group, a 4-methylsulfanylbenzoyl group, a 4-phenylsulfanylbenzoyl group, a 4-dimethylaminobenzoyl group, a 4-diethylaminobenzoyl group, a 2-chlorobenzoyl group, a 2-methylbenzoyl group, a 2-methoxybenzoyl group, a 2-butoxybenzoyl group, a 3-chlorobenzoyl group, a 3-trifluoromethylbenzoyl group, a 3-cyanobenzoyl group, a 3-nitrobenzoyl group, a 4-fluorobenzoyl group, a 4-cyanobenzoyl group, and a 4-methoxybenzoyl group.

The alkoxycarbonyl group which may have a substituent is preferably an alkoxycarbonyl group having a carbon number of 2 to 20, and specific examples thereof include a methoxycarbonyl group, an ethoxycarbonyl group, a propoxycarbonyl group, a butoxycarbonyl group, a hexyloxycarbonyl group, an octyloxycarbonyl group, a decyloxycarbonyl group, an octadecyloxycarbonyl group, and a trifluoromethyloxycarbonyl group.

Specific examples of the aryloxycarbonyl group which may have a substituent include a phenoxycarbonyl group, a 1-naphthyloxycarbonyl group, a 2-naphthyloxycarbonyl group, a 4-methylsulfanylphenyloxycarbonyl group, a 4-phenylsulfanylphenyloxycarbonyl group, a 4-dimethylaminophenyloxycarbonyl group, a 4-diethylaminophenyloxycarbonyl group, a 2-chlorophenyloxycarbonyl group, a 2-methylphenyloxycarbonyl group, a 2-methoxyphenyloxycarbonyl group, a 2-butoxyphenyloxycarbonyl group, a 3-chlorophenyloxycarbonyl group, a 3-trifluoromethylphenyloxycarbonyl group, a 3-cyanophenyloxycarbonyl group, a 3-nitrophenyloxycarbonyl group, a 4-fluorophenyloxycarbonyl group, a 4-cyanophenyloxycarbonyl group, and a 4-methoxyphenyloxycarbonyl group.

The heterocyclic group which may have a substituent is preferably an aromatic or aliphatic heterocyclic ring containing a nitrogen atom, an oxygen atom, a sulfur atom or a phosphorus atom.

Specific examples thereof include a thienyl group, a benzo[b]thienyl group, a naphtho[2,3-b]thienyl group, a thianthrenyl group, a furyl group, a pyranyl group, an isobenzofuranyl group, a chromenyl group, a xanthenyl group, a phenoxathiinyl group, a 2H-pyrrolyl group, a pyrrolyl group, an imidazolyl group, a pyrazolyl group, a pyridyl group, a pyrazinyl group, a pyrimidinyl group, a pyridazinyl group, an indolizinyl group, an isoindolyl group, a 3H-indolyl group, an indolyl group, a 1H-indazolyl group, a purinyl group, a 4H-quinolizinyl group, an isoquinolyl group, a quinolyl group, a phthalazinyl group, a naphthyridinyl group, a quinoxalinyl group, a quinazolinyl group, a cinnolinyl group, a pteridinyl group, a 4aH-carbazolyl group, a carbazolyl group, a β-carbolinyl group, a phenanthridinyl group, an acridinyl group, a perimidinyl group, a phenanthrolinyl group, a phenazinyl group, a phenarsazinyl group, an isothiazolyl group, a phenothiazinyl group, an isoxazolyl group, a furazanyl group, a phenoxazinyl group, an isochromanyl group, a chromanyl group, a pyrrolidinyl group, a pyrrolinyl group, an imidazolidinyl group, an imidazolinyl group, a pyrazolidinyl group, a pyrazolinyl group, a piperidyl group, a piperazinyl group, an indolinyl group, an isoindolinyl group, a quinuclidinyl group, a morpholinyl group, and a thioxanthonyl group.

Specific examples of the alkylthiocarbonyl group which may have a substituent include a methylthiocarbonyl group, a propylthiocarbonyl group, a butylthiocarbonyl group, a hexylthiocarbonyl group, an octylthiocarbonyl group, a decylthiocarbonyl group, an octadecylthiocarbonyl group, and a trifluoromethylthiocarbonyl group.

Specific examples of the arylthiocarbonyl group which may have a substituent include a 1-naphthylthiocarbonyl group, a 2-naphthylthiocarbonyl group, a 4-methylsulfanylphenylthiocarbonyl group, a 4-phenylsulfanylphenylthiocarbonyl group, a 4-dimethylaminophenylthiocarbonyl group, a 4-diethylaminophenylthiocarbonyl group, a 2-chlorophenylthiocarbonyl group, a 2-methylphenylthiocarbonyl group, a 2-methoxyphenylthiocarbonyl group, a 2-butoxyphenylthiocarbonyl group, a 3-chlorophenylthiocarbonyl group, a 3-trifluoromethylphenylthiocarbonyl group, a 3-cyanophenylthiocarbonyl group, a 3-nitrophenylthiocarbonyl group, a 4-fluorophenylthiocarbonyl group, a 4-cyanophenylthiocarbonyl group, and a 4-methoxyphenylthiocarbonyl group.

The monovalent substituent represented by B in formula (OX-1) indicates an aryl group, a heterocyclic group, an arylcarbonyl group or a heterocyclic carbonyl group. These groups may have one or more substituents. Examples of the substituent include the substituents described above. Also, the substituent described above may be further substituted with another substituent.

Among others, structures shown below are preferred.

In the following structures, Y, X and n have the same meanings as Y, X and n, respectively, in formula (OX-2) described later, and preferred examples thereof are also the same.

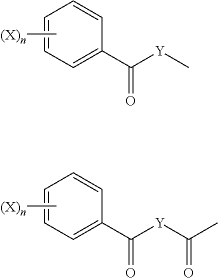

The divalent organic group represented by A in formula (OX-1) includes an alkylene group having a carbon number of 1 to 12, a cyclohexylene group, and an alkynylene group. These groups may have one or more substituents. Examples of the substituent include the substituents described above. Also, the substituent described above may be further substituted with another substituent.

Among others, from the standpoint of increasing the sensitivity and suppressing the coloration due to heating or aging, A in formula (OX-1) is preferably an unsubstituted alkylene group, an alkylene group substituted with an alkyl group (such as methyl group, ethyl group, tert-butyl group or dodecyl group), an alkylene group substituted with an alkenyl group (such as vinyl group or allyl group), or an alkylene group substituted with an aryl group (such as phenyl group, p-tolyl group, xylyl group, cumenyl group, naphthyl group, anthryl group, phenanthryl group or styryl group).

The aryl group represented by Ar in formula (OX-1) is preferably an aryl group having a carbon number of 6 to 30 and may have a substituent. Examples of the substituent are the same as those of the substituent introduced into a substituted aryl group described above as specific examples of the aryl group which may have a substituent.

Among others, from the standpoint of increasing the sensitivity and suppressing the coloration due to heating or aging, a substituted or unsubstituted phenyl group is preferred.

In formula (OX-1), in view of sensitivity, the structure “SAr” formed by Ar and S adjacent thereto in formula (OX-1) is preferably a structure shown below. Here, Me stands for a methyl group, and Et stands for an ethyl group.

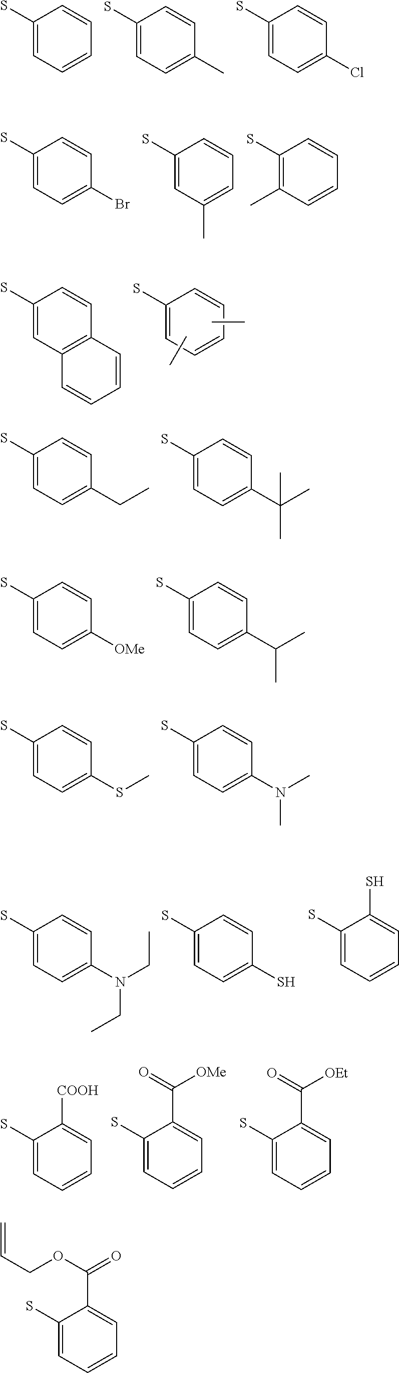

The oxime compound is preferably a compound represented by the following formula (OX-2):

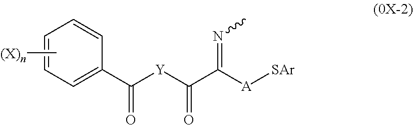

(In formula (OX-2), each of R and X independently represents a monovalent substituent, each of A and Y independently represents a divalent organic group, Ar represents an aryl group, and n is an integer of 0 to 5.)

R, A and Ar in formula (OX-2) have the same meanings as R, A and Ar in formula (OX-1), and preferred examples thereof are also the same.

Examples of the monovalent substituent represented by X in formula (OX-2) include an alkyl group, an aryl group, an alkoxy group, an aryloxy group, an acyloxy group, an acyl group, an alkoxycarbonyl group, an amino group, a heterocyclic group, and a halogen group. These groups may have one or more substituents. Examples of the substituent include the substituents described above. Also, the substituent described above may be further substituted with another substituent.

Among these, from the standpoint of enhancing the solvent solubility and absorption efficiency in the long wavelength region, X in formula (OX-2) is preferably an alkyl group.

In formula (OX-2), n represents an integer of 0 to 5 and is preferably an integer of 0 to 2.

The divalent organic group represented by Y in formula (OX-2) includes the following structures. In the groups shown below, “*” indicates a bonding position between Y and the adjacent carbon atom in formula (OX-2).

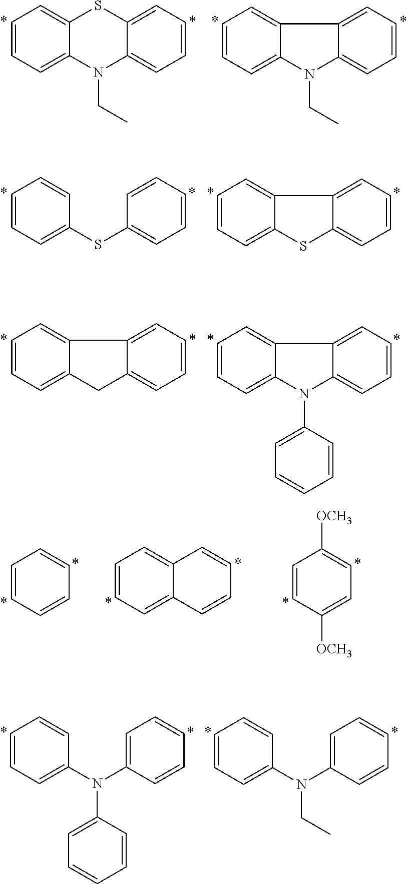

Among these, from the standpoint of achieving high sensitivity, structures shown below are preferred.

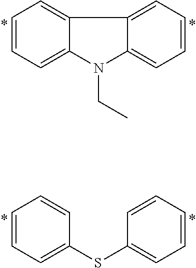

Furthermore, the oxime compound is preferably a compound represented by the following formula (OX-3):

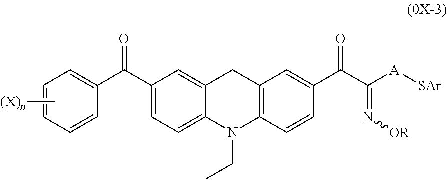

(In formula (OX-3), each of R and X independently represents a monovalent substituent, A represents a divalent organic group, Ar represents an aryl group, and n is an integer of 0 to 5.)

R, X, A, Ar and n in formula (OX-3) have the same meanings as R, X, A, Ar and n, respectively, in formula (OX-2), and preferred examples thereof are also the same.

Specific examples (B-1) to (B-10) of the oxime compound which is suitably used are illustrated below, but the present invention is not limited thereto.

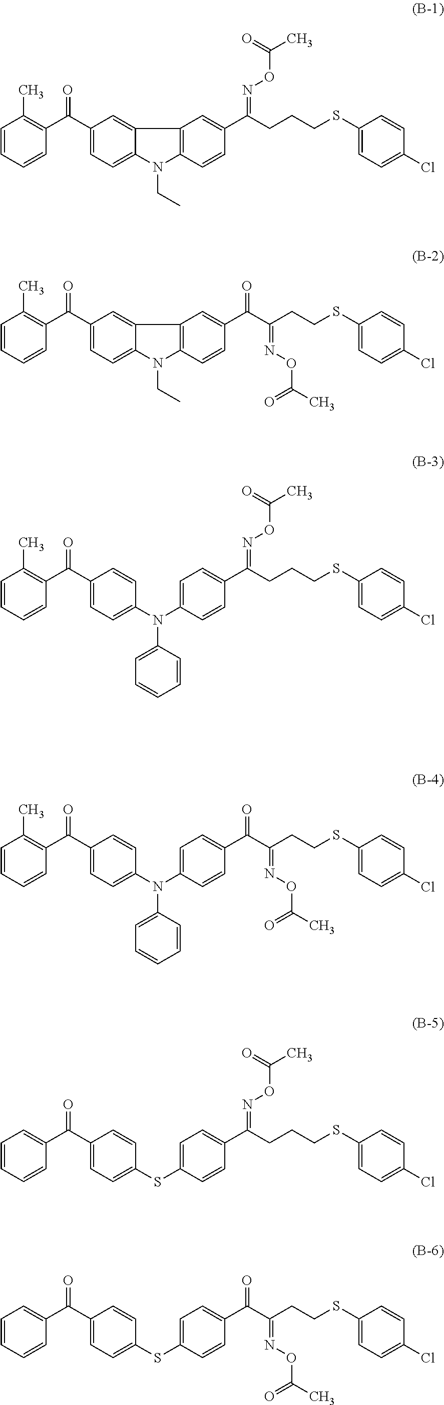 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCCSc1ccc(Cl)cc1)c1ccc(N(c2ccccc2)c2ccc(C(=O)c3ccccc3C)cc2)cc1 ; CC(=O)O/N=C(\CCSc1ccc(Cl)cc1)C(=O)c1ccc(N(c2ccccc2)c2ccc(C(=O)c3ccccc3C)cc2)cc1 ; CC(=O)O/N=C(\CCCSc1ccc(Cl)cc1)c1ccc(Sc2ccc(C(=O)c3ccccc3)cc2)cc1 ; CC(=O)O/N=C(\CCSc1ccc(Cl)cc1)C(=O)c1ccc(Sc2ccc(C(=O)c3ccccc3)cc2)cc1]

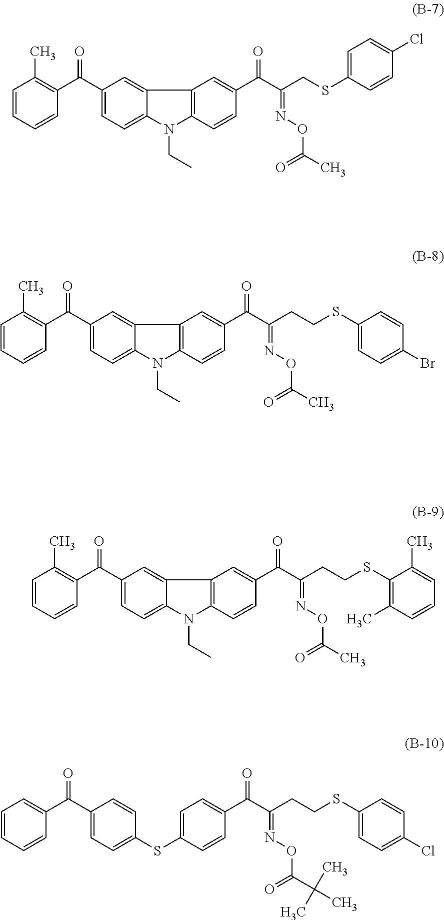 [SMILES: CCn1c2ccc(C(=O)/C(CSc3ccc(Cl)cc3)=N/OC(C)=O)cc2c2cc(C(=O)c3ccccc3C)ccc21 ; CCn1c2ccc(C(=O)/C(CCSc3ccc(Br)cc3)=N/OC(C)=O)cc2c2cc(C(=O)c3ccccc3C)ccc21 ; CCn1c2ccc(C(=O)/C(CCSc3c(C)cccc3C)=N/OC(C)=O)cc2c2cc(C(=O)c3ccccc3C)ccc21 ; CC(C)(C)C(=O)O/N=C(\CCSc1ccc(Cl)cc1)C(=O)c1ccc(Sc2ccc(C(=O)c3ccccc3)cc2)cc1]

The oxime compound has a maximum absorption wavelength in the wavelength region of 350 to 500 nm. A compound having an absorption wavelength in the wavelength region of 360 to 480 nm is preferred, and a compound having high absorbance in 365 or 455 nm is more preferred.

In view of sensitivity, the molar extinction coefficient at 365 nm or 405 nm of the oxime compound is preferably from 1,000 to 300,000, more preferably from 2,000 to 300,000, still more preferably from 5,000 to 200,000.

The molar extinction coefficient of the compound can be measured by a known method but specifically, the molar extinction coefficient is preferably measured, for example, by an ultraviolet-visible spectrophotometer (Carry-5 spectrophotometer, manufactured by Varian Inc.) at a concentration of 0.01 g/L by using an ethyl acetate solvent.

As to the polymerization initiator for use in the present invention, two or more initiators may be used in combination, if desired.

In view of exposure sensitivity, the compound capable of generating a radical or an acid upon irradiation with an actinic ray or radiation is preferably a compound selected from the group consisting of a trihalomethyltriazine compound, a benzyldimethyl ketal compound, an α-hydroxyketone compound, an α-aminoketone compound, an acylphosphine compound, a phosphine oxide compound, a metallocene compound, an oxime compound, a triallylimidazole dimer, an onium compound, a benzothiazole compound, a benzophenone compound, an acetophenone compounds and derivatives thereof, a cyclopentadiene-benzene-iron complex and a salt thereof, a halomethyloxadiazole compound, and a 3-aryl substituted coumarin compound.

The compound is more preferably a trihalomethyltriazine compound, an α-aminoketone compound, an acylphosphine compound, a phosphine oxide compound, an oxime compound, a triallylimidazole dimer, an onium compound, a benzophenone compound or an acetophenone compound, and most preferably at least one compound selected from the group consisting of a trihalomethyltriazine compound, an α-aminoketone compound, an oxime compound, a triallylimidazole dimer and a benzophenone compound.

Among the compounds capable of generating an acid upon irradiation with an actinic ray or radiation, a compound capable of generating an acid group having a pKa of 4 or less is preferred, and a compound capable of generating an acid having a pKa of 3 or less is more preferred.

Examples of the compound capable of generating an acid include trichloromethyl-s-triazines, sulfonium or iodonium salts, quaternary ammonium salts, diazomethane compounds, imidosulfonate compounds, and oxime sulfonate compounds. Among these, an oxime sulfonate compound is preferably used in view of high sensitivity. One of these acid generators may be used alone, or two or more kinds thereof may be used in combination.

The acid generator specifically includes the acid generators described in paragraphs [0073] to [0095] of JP-A-2012-8223.

### (Thermal Polymerization Inhibitor)

It is also preferred that the adhesive composition of the present invention contains a thermal polymerization inhibitor.

Containing a thermal polymerization initiator in the adhesive composition of the present invention has the advantage that when the adhesive layer is adhered to a device wafer and heated to a temperature not lower than the decomposition temperature of the thermal polymerization initiator, thanks to curing of the adhesive layer, adhesion with higher heat resistance and chemical resistance can be achieved.

### [Compound Capable of Generating Radical by Heat]

As the compound capable of generating a radical by heat (hereinafter, sometimes simply referred to as “thermal radical generator”), a known thermal radical generator can be used.

The thermal radical generator is a compound capable of generating a radical by heat energy to initiate or promote the polymerization reaction of a polymerizable group-containing polymer compound and a polymerizable monomer. By adding a thermal radical generator, in the case where the adhesive layer formed using the adhesive composition is irradiated with heat and a to-be-treated member is then temporarily adhered to the adhesive support, a crosslinking reaction in the reactive compound having a crosslinking group proceeds due to heat and, as described in detail later, the adhesiveness (that is, tackiness and tack property) of the adhesive layer can be thereby reduced in advance.

On the other hand, in the case where a to-be-treated member is temporarily adhered to the adhesive support and the adhesive layer in the adhesive support is then irradiated with heat, a crosslinking reaction in the reactive compound having a crosslinking group proceeds due to heat and the adhesive layer becomes tougher, as a result, the adhesive layer can be prevented from a cohesion failure that is liable to occur during a mechanical or chemical treatment of the to-be-treated member. That is, the adhesiveness in the adhesive layer can be enhanced.

Preferred thermal radical generators include the above-described compound capable of generating an acid or a radical upon irradiation with an actinic ray or radiation, but a compound having a thermal decomposition temperature of 130 to 250° C., preferably from 150 to 220° C., can be preferably used.

Examples of the thermal radical generator include aromatic ketones, an onium salt compound, an organic peroxide, a thio compound, a hexaarylbiimidazole compound, a keto oxime ester compound, a borate compound, an azinium compound, a metallocene compound, an active ester compound, a compound having a carbon-halogen bond, and an azo-based compounds. Among these, an organic peroxide and an azo-based compound are preferred, and an organic peroxide is more preferred.

The thermal radical generator specifically includes the compounds described in paragraphs 0074 to 0118 of JP-A-2008-63554.

### [Compound Capable of Generating Acid by Heat]

As the compound capable of generating an acid by heat (hereinafter, sometimes simply referred to as “thermal acid generator”), a known thermal acid generator can be used.

The thermal acid generator includes a compound having a thermal decomposition temperature of preferably from 130 to 250° C., more preferably from 150 to 220° C.

The thermal acid generator is, for example, a compound capable of generating a low nucleophilic acid such as sulfonic acid, carboxylic acid and disulfonylimide by heat.

The acid generated from the thermal acid generator is preferably, for example, a strong sulfonic acid having a pKa of 2 or less, an alkyl- or aryl-carboxylic acid substituted with an electron-withdrawing group, or a disulfonylimide substituted with an electron-withdrawing group. The electron-withdrawing group includes a halogen atom such as fluorine atom, a haloalkyl group such as trifluoromethyl group, a nitro group, and a cyano group.

As the thermal acid generator, the above-described photoacid generator (D) capable of generating an acid upon irradiation with an actinic ray or radiation may be applied. Examples thereof include an onium salt such as sulfonium salt and iodonium salt, an N-hydroxyimidosulfonate compound, an oxime sulfonate, and an o-nitrobenzyl sulfonate.

In the present invention, it is also preferred to use a sulfonic acid ester substantially incapable of generating an acid upon irradiation with an actinic ray or radiation but capable of generating an acid by heat.

When substantially no acid is generated upon irradiation with an actinic ray or radiation, this can be judged by measuring an infrared absorption (IR) spectrum or a nuclear magnetic resonance (NMR) spectrum before and after exposure of the compound and confirming that there is no change in the spectrum.

The molecular weight of the sulfonic acid ester is preferably from 230 to 1,000, more preferably from 230 to 800.

The sulfonic acid ester which may be used in the invention may be a commercial product or a sulfonic acid ester synthesized by a known method. The sulfonic acid ester can be synthesized, for example, by reacting a sulfonyl chloride or a sulfonic anhydride with a corresponding polyhydric alcohol under basic conditions.

As for the thermal acid generator, one compound may be used alone, or two or more compounds may be used in combination.

The content of the polymerization initiator (in the case of using two or more compounds, the total content) is preferably from 0.1 to 50 mass %, more preferably from 0.1 to 30 mass %, still more preferably from 0.1 to 20 mass %, based on the total solid content of the adhesive composition. Within this range, good sensitivity is obtained.

### (D) Surfactant

From the standpoint of more enhancing the coatability, various surfactants may be added to the adhesive composition of the present invention. As the surfactant, various surfactants such as fluorine-containing surfactant, nonionic surfactant, cationic surfactant, anionic surfactant and silicone-containing surfactant may be used.

In particular, by containing a fluorine-containing surfactant in the adhesive composition of the present invention, the liquid characteristics (particularly fluidity) of a coating solution prepared is more enhanced, so that the coating thickness uniformity or the liquid-saving property can be more improved.

That is, in the case of forming a film by using a coating solution to which the adhesive composition containing a fluorine-containing surfactant is applied, the interface tension between a to-be-coated surface and the coating solution is reduced, whereby wettability to the to-be-coated surface is improved and the coatability on the to-be-coated surface is enhanced. This is effective in that even when a thin film of about several μm is formed with a small liquid volume, formation of a film with little thickness unevenness and uniform thickness can be performed in a more preferable manner.

The fluorine content in the fluorine-containing surfactant is preferably from 3 to 40 mass %, more preferably from 5 to 30 mass %, still more preferably from 7 to 25 mass %. The fluorine-containing surfactant having a fluorine content in the range above is effective in view of thickness uniformity of the coated film and liquid-saving property and also exhibits good solubility in the adhesive composition.

Examples of the fluorine-containing surfactant include Megaface F171, Megaface F172, Megaface F173, Megaface F176, Megaface F177, Megaface F141, Megaface F142, Megaface F143, Megaface F144, Megaface R30, Megaface F437, Megaface F475, Megaface F479, Megaface F482, Megaface F554, Megaface F780, Megaface F781 (all produced by DIC Corp.), Florad FC430, Florad FC431, Florad FC171 (all produced by Sumitomo 3M Ltd.), Surflon S-382, Surflon SC-101, Surflon SC-103, Surflon SC-104, Surflon SC-105, Surflon SC-1068, Surflon SC-381, Surflon SC-383, Surflon 5393, Surflon KH-40 (all produced by Asahi Glass Co., Ltd.), PF636, PF656, PF6320, PF6520, and PF7002 (all produced by OMNOVA).

Specific examples of the nonionic surfactant include glycerol, trimethylolpropane, trimethylolethane, their ethoxylate and propoxylate (such as glycerol propoxylate and glycerin ethoxy late), polyoxyethylene lauryl ether, polyoxyethylene stearyl ether, polyoxyethylene oleyl ether, polyoxyethylene octylphenyl ether, polyoxyethylene nonylphenyl ether, polyethylene glycol dilaurate, polyethylene glycol distearate, and sorbitan fatty acid ester (PLURONIC L10, L31, L61, L62, 10R5, 17R2 and 25R2, TETRONIC 304, 701, 704, 901, 904 and 150R1 (all produced by BASF), and Solsperse 20000 (produced by The Lubrizol Corporation)).

Specific examples of the cationic surfactant include a phthalocyanine derivative (EFKA-745, trade name, produced by Morishita Sangyo K.K.), an organosiloxane polymer KP341 (produced by Shin-Etsu Chemical Co., Ltd.), (meth)acrylic acid-based (co)polymers Polyflow No. 75, No. 90, No. 95 (produced by Kyoeisha Chemical Co., Ltd.), and W001 (produced by Yusho Co., Ltd.).

Specific examples of the anionic surfactant include W004, W005 and W017 (all produced by Yusho Co., Ltd.).

Examples of the silicone-containing surfactant include “Toray Silicone DC3PA”, “Toray Silicone SH7PA”, “Toray Silicone DC11PA”, “Toray Silicone SH21PA”, “Toray Silicone SH28PA”, “Toray Silicone SH29PA”, “Toray Silicone SH30PA” and “Toray Silicone SH8400”, produced by Dow Corning Toray Silicone Co., Ltd.; “TSF-4440”, “TSF-4300”, “TSF-4445”, “TSF-4460” and “TSF-4452”, produced by Momentive Performance Materials; “KP341”, “KF6001” and “KF6002”, produced by Shin-Etsu Silicone Co., Ltd.; and “BYK307”, “BYK323” and “BYK330”, produced by Byk Chemie.

Only one surfactant may be used, or two or more kinds of surfactants may be combined.

The amount of the surfactant added is preferably from 0.001 to 2.0 mass %, more preferably from 0.005 to 1.0 mass %, based on the total mass of the adhesive composition.

### [E] Solvent

The adhesive composition of the present invention can be generally constructed by using a solvent (usually an organic solvent.). The solvent is fundamentally not particularly limited as long as it satisfies the solubility of each component and the coatability of the adhesive composition.

Preferred examples of the organic solvent include esters, for example, ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, alkyl oxyacetate (such as methyl oxyacetate, ethyl oxyacetate and butyl oxyacetate (e.g., methyl methoxyacetate, ethyl methoxyacetate, butyl methoxyacetate, methyl ethoxyacetate, ethyl ethoxyacetate)), 3-oxypropionic acid alkyl esters (such as methyl 3-oxypropionate and ethyl 3-oxypropionate (e.g., methyl 3-methoxypropionate, ethyl 3-methoxypropionate, methyl 3-ethoxypropionate, ethyl 3-ethoxypropionate)), 2-oxypropionic acid alkyl esters (such as methyl 2-oxypropionate, ethyl 2-oxypropionate and propyl 2-oxypropionate (e.g., methyl 2-methoxypropionate, ethyl 2-methoxypropionate, propyl 2-methoxypropionate, methyl 2-ethoxypropionate, ethyl 2-ethoxypropionate)), methyl 2-oxy-2-methylpropionate or ethyl 2-oxy-2-methylpropionate (such as methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate and ethyl 2-oxobutanoate; ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate and propylene glycol monopropyl ether acetate; ketones such as methyl ethyl ketone (2-butanone), cyclohexanone, 2-heptanone (methyl amyl ketone), 3-heptanone and 4-heptanone; aromatic hydrocarbons such as toluene and xylene; and, as other organic solvents, N-methyl-2-pyrrolidone and limonene.

Among these organic solvents, N-methyl-2-pyrrolidone, methyl ethyl ketone, methyl amyl ketone, limonene and propylene glycol monoethyl ether acetate are more preferred.

From the standpoint of, for example, improving the coated surface state, an embodiment of mixing two or more of these organic solvents is also preferred. In this case, a mixed solution composed of two or more members selected from methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether and propylene glycol methyl ether acetate, is particularly preferred.

In view of coatability, the content of the solvent in the adhesive composition is preferably adjusted such that the total solid content concentration of the composition becomes preferably from 5 to 80 mass %, more preferably from 5 to 70 mass %, still more preferably from 10 to 60 mass %.

In the adhesive composition of the present invention, if desired, various additives such as curing agent, curing catalyst, polymerization inhibitor, silane coupling agent, filler, adherence accelerator, antioxidant, ultraviolet absorber, aggregation inhibitor, sensitizing dye and chain transfer agent can be blended as long as the effects of the present invention are not impaired.

In the foregoing pages, the adhesive composition of the present invention is described in detail, but the adhesive composition (in turn, the adhesive layer) of the present invention preferably contains a photopolymerization initiator and a polymerizable compound.

The adhesive composition (in turn, the adhesive layer) of the present invention preferably further contains (A) a resin.

The adhesive composition (in turn, the adhesive layer) of the present invention preferably further contains a thermal polymerization initiator.

As described above, in this description, a manufacturing method of a semiconductor device indicated by the following [1] to [28] is disclosed.

[1] A method for manufacturing a semiconductor device with a treated member, comprising:

subjecting an adhesive support having a substrate and an adhesive layer capable of increasing or decreasing in the adhesiveness upon irradiation with an actinic ray or radiation to pattern exposure of the adhesive layer to provide a high adhesive region and a low adhesive region in the adhesive layer,

adhering (bonding) a first surface of a to-be-treated member to the adhesive layer of the adhesive support,

applying a mechanical or chemical treatment to a second surface different from the first surface of the to-be-treated member to obtain a treated member, and detaching the first surface of the treated member from the adhesive layer of the adhesive support.

[2] The method for manufacturing a semiconductor device as described in [1] above, wherein the pattern exposure is exposure making the central region of the adhesive layer as the low adhesive region and the peripheral region surrounding the central region of the adhesive layer as the high adhesive region.

[3] The method for manufacturing a semiconductor device as described in [1] above, wherein the pattern exposure is exposure by which the central region of the adhesive layer and a plurality of first peripheral regions surrounding the central region are made as the low adhesive region and a plurality of second peripheral regions surrounding the central region of the adhesive layer and being different from the plurality of first peripheral regions are made as the high adhesive region.

[4] The method for manufacturing a semiconductor device as described in [1] above, wherein:

a device chip is provided on the first surface of the to-be-treated member,

the pattern exposure is exposure by which a first region of the adhesive layer determined to correspond to the arranged position of the device chip is made as the low adhesive region and a second region of the adhesive layer different from the first region is made as the high adhesive region, and

the first surface of the to-be-treated member is adhered to the adhesive layer of the adhesive support such that the device chip comes into contact with the first region of the adhesive layer.

[5] A method for manufacturing a semiconductor device with a treated member, comprising:

preparing an adhesive support having a substrate and an adhesive layer in which a high adhesive region and a low adhesive region are provided to form a dot pattern,

adhering a first surface of a to-be-treated member to the adhesive layer of the adhesive support,

applying a mechanical or chemical treatment to a second surface different from the first surface of the to-be-treated member to obtain a treated member, and

detaching the first surface of the treated member from the adhesive layer of the adhesive support.

[6] The method for manufacturing a semiconductor device as described in [5] above, wherein the dot region of the dot pattern is made as the high adhesive region and the peripheral region surrounding the dot region is made as the low adhesive region.

[7] The method for manufacturing a semiconductor device as described in [5] or [6] above, wherein the adhesive layer is an adhesive layer capable of increasing or decreasing in the adhesiveness upon irradiation with an actinic ray or radiation and the high and low adhesive regions forming the dot pattern are provided by performing dot-imagewise pattern exposure of the adhesive layer.

[8] The method for manufacturing a semiconductor device as described in [7] above, wherein the dot-imagewise pattern exposure is exposure defining the dot region of the dot pattern in the adhesive layer as the high adhesive region and the peripheral region surrounding the dot region as the low adhesive region.

[9] The method for manufacturing a semiconductor device as described in [7] or [8] above, wherein the dot-imagewise pattern exposure is exposure through a photomask having a dot pattern formed by a light-transmitting region and a light-shielding region.

[10] The method for manufacturing a semiconductor device as described in any one of [1] to [9] above, wherein:

the to-be-treated member has a to-be-treated base material and a protective layer provided on the first surface of the to-be-treated base material,

a surface of the protective layer opposite the to-be-treated base material is the first surface of the to-be-treated member, and

a second surface different from the first surface of the to-be-treated base material is the second surface of the to-be-treated member.

[11] The method for manufacturing a semiconductor device as described in [10] above, wherein the to-be-treated member is a to-be-treated member in which a device chip is provided on the first surface of the to-be-treated base material and the device chip is protected by the protective layer.

[12] The method for manufacturing a semiconductor device as described in any one of [1] to [4] and [7] to [9] above, wherein the low adhesive region is formed by performing pattern exposure of the adhesive layer to decrease the adhesiveness toward the outer surface from the inner surface on the base material side of the adhesive layer.

[13] The method for manufacturing a semiconductor device as described in any one of [1] to [12] above, wherein the to-be-treated member is a silicon substrate or a compound semiconductor substrate.

[14] The method for manufacturing a semiconductor device as described in [13] above, wherein the to-be-treated member is a silicon substrate.

[15] The method for manufacturing a semiconductor device as described in [14] above, wherein the mechanical or chemical treatment includes a thinning treatment of the silicon substrate.

[16] The method for manufacturing a semiconductor device as described in [15] above, wherein the mechanical or chemical treatment includes, after the thinning treatment of the silicon substrate, a treatment of forming a through hole in the silicon substrate and forming a through-silicon via in the through hole.

[17] The method for manufacturing a semiconductor device as described in any one of [14] to [16] above, wherein the to-be-treated member is a silicon substrate having a thickness of 200 to 1,200 μm.

[18] The method for manufacturing a semiconductor device as described in any one of [14] to [17] above, wherein the to-be-treated member is a silicon substrate having a thickness of 1 to 200 μm.

[19] The method for manufacturing a semiconductor device as described in [13] above, wherein the to-be-treated member is a compound semiconductor substrate and the compound semiconductor substrate is an SiC substrate, an SiGe substrate, a ZnS substrate, a ZnSe substrate, a GaAs substrate, an InP substrate or a GaN substrate.

[20] The method for manufacturing a semiconductor device as described in any one of [1] to [19] above, wherein the adhesive layer is an adhesive layer capable of decreasing in the adhesiveness upon irradiation with an actinic ray or radiation.

[21] The method for manufacturing a semiconductor device as described in any one of [1] to [20] above, wherein an organic solvent is contacted with the outer edge part of the adhesive layer of the adhesive support adhering to the treated member and thereafter, the first surface of the treated member is detached from the adhesive layer of the adhesive support.

[22] The method for manufacturing a semiconductor device as described in any one of [1] to [21] above, wherein the treated member is detached from the adhesive support by sliding the treated member with respect to the adhesive layer of the adhesive support or separating the treated member from the adhesive layer of the adhesive support.

[23] The method for manufacturing a semiconductor device as described in any one of [1] to [22] above, wherein the adhesive layer has a multilayer structure.

[24] The method for manufacturing a semiconductor device as described in any one of [1] to [23] above, wherein an organic solvent is contacted with the adhesive layer of the adhesive support adhering to the treated member and thereafter, the first surface of the treated member is detached from the adhesive layer of the adhesive support.

[25] The method for manufacturing a semiconductor device as described in any one of [1] to [23] above, wherein the first surface of the treated member is detached from the adhesive layer of the adhesive support without applying any treatment to the adhesive layer of the adhesive support adhering to the treated member.

[26] The method for manufacturing a semiconductor device as described in any one of [1] to [25] above, wherein the adhesive layer contains a photopolymerization initiator and a polymerizable compound.

[27] The method for manufacturing a semiconductor device as described in [26] above, wherein the adhesive layer further contains a resin.

[28] The method for manufacturing a semiconductor device as described in [26] or [27] above, wherein the adhesive layer further contains a thermal polymerization initiator.

### EXAMPLES

### Formation (1) of Adhesive Support

Each adhesive composition according to the formulation shown in Table 1 below was coated on a 4-inch Si wafer having a thickness of 525 μm by a spin coater (Opticoat MS-A100, manufactured by Mikasa, 1,200 rpm, 30 seconds) and then baked at 100° C. for 30 seconds to form Wafer 1 having provided thereon an adhesive layer with a thickness of 5 vim (that is, adhesive support).

### <Exposure (1)>

From the adhesive layer side of Wafer 1, the entire surface of the adhesive layer was exposed using a UV exposure apparatus (LC8, manufactured by Hamamatsu Photonics K.K.). The exposure was performed by changing the exposure dose as shown in Table 2 below in each of Examples.

### <Preparation (1) of Test Piece>

Wafer 1 after exposure of the adhesive layer was cut in a rectangle shape of 0.5 cm×2 cm.

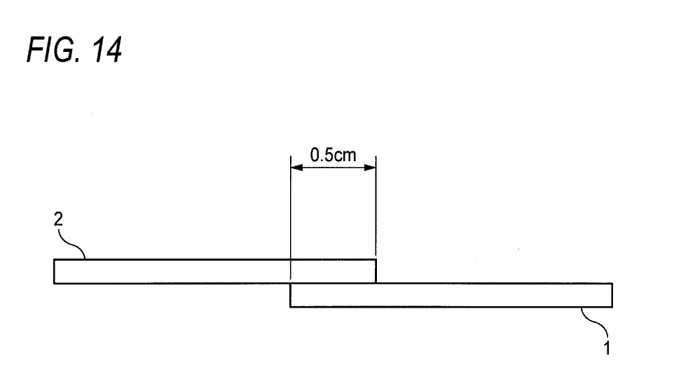

Wafer 2 in which nothing is coated on the surface was cut in a rectangle shape of 0.5 cm×2 cm. Wafer 1 and Wafer 2 were adhered under pressure of 20 N/cm² such that the region up to 0.5 cm from the longitudinal edge part of the adhesive layer of Wafer 1 overlaps with the region up to 0.5 cm from the longitudinal edge part of Wafer 2 (see, the schematic cross-sectional view of the test piece shown in FIG. 14).

### <Measurement of Adhesive Force>

The shear adhesive force of the test piece prepared above was subjected to tensile measurement under the condition of 250 mm/min by using a tensile tester (manufactured by IMADA). The results are shown in Table 2 below.

TABLE 1

| Adhesive | Resin | | Polymerizable Compound | | Polymerization Initiator | | Surfactant | | Solvent | |
|---|---|---|---|---|---|---|---|---|---|---|
| Composition | Kind | Content (g) | Kind | Content (g) | Kind | Content (g) | Kind | Content (g) | Kind | Content (g) |
| Composition 1 | A | 25 | C | 75 | E | 6 | F | 0.02 | MEK | 150 |
| Composition 2 | A | 25 | D | 75 | E | 6 | F | 0.02 | MEK | 150 |
| Composition 3 | B | 50 | C | 50 | E | 6 | F | 0.02 | PGMEA | 150 |
| Composition 4 | B | 50 | D | 50 | E | 6 | F | 0.02 | PGMEA | 150 |

Abbreviations in Table 1 stand for the followings.
Resin A: 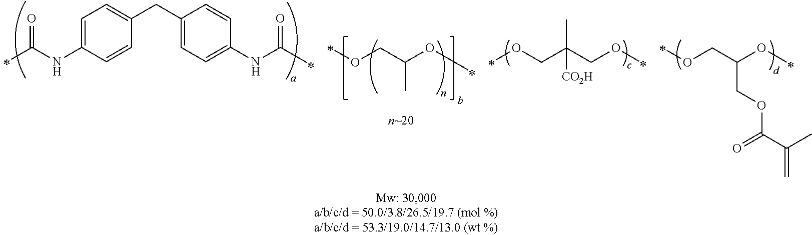
Resin B: 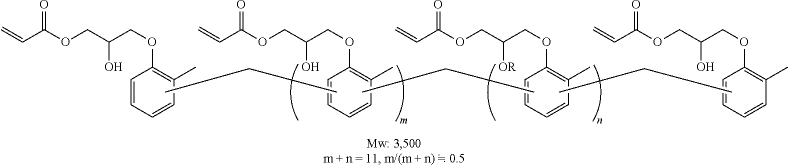 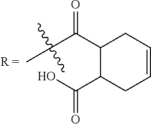 [SMILES: *C(=O)C1CC=CCC1C(=O)O]
Polymerizable Compound C: 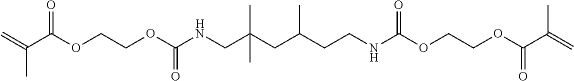 [SMILES: C=C(C)C(=O)OCCOC(=O)NCCC(C)CC(C)(C)CNC(=O)OCCOC(=O)C(=C)C] 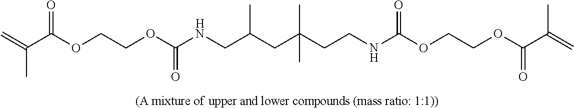 [SMILES: C=C(C)C(=O)OCCOC(=O)NCCC(C)(C)CC(C)CNC(=O)OCCOC(=O)C(=C)C]
Polymerizable Compound D: 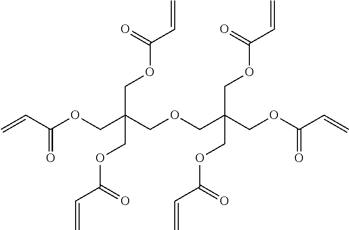 [SMILES: C=CC(=O)OCC(COCC(COC(=O)C=C)(COC(=O)C=C)COC(=O)C=C)(COC(=O)C=C)COC(=O)C=C]
Polymerization Initiator E: 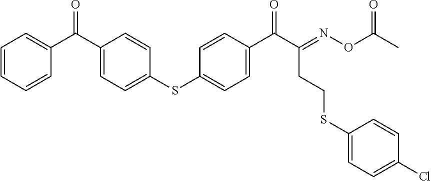 [SMILES: CC(=O)O/N=C(\CCSc1ccc(Cl)cc1)C(=O)c1ccc(Sc2ccc(C(=O)c3ccccc3)cc2)cc1]
Surfactant F: 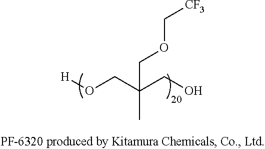
MEK: Methyl ethyl ketone
PGMEA: Propylene glycol monomethyl ether acetate

TABLE 2

| | Exposure Dose (mJ/cm²) | Shear Adhesive |
|---|---|---|
| | (in terms of wavelength of 254 nm) | Force (N/25 mm²) |
| Composition 1 | 0 | 35 |
| | 0.2 | 10 |
| | 100 | 0* |
| Composition 2 | 0 | 27 |
| | 0.2 | 9 |
| | 100 | 0* |
| Composition 3 | 0 | 35 |
| | 0.2 | 11 |
| | 100 | 0* |
| Composition 4 | 0 | 10 |
| | 0.2 | 2 |
| | 100 | 0* |

*Separated on fixing to the measuring machine.

As seen above, the adhesive layer formed using any of Compositions 1 to 4 was decreased in the adhesiveness by exposure.

Accordingly, when such an adhesive layer is used as the adhesive layer of an adhesive support and pattern exposure is applied to the adhesive layer (that is, an exposed area and an unexposed area are provided), a high adhesive region and a low adhesive region can be provided in the adhesive layer, so that, as described above, a to-be treated member can be temporarily supported in a reliable and easy manner while suppressing the effect on the treatment accuracy when applying a mechanical or chemical treatment to the to-be-treated member and at the same time, the temporary support for the treated member can be easily released without damaging the treated member.

### <Formation (2) of Adhesive Support>

Each adhesive composition according to the formulation shown in Table 3 below was coated on a 4-inch Si wafer having a thickness of 525 μm by a spin coater (Opticoat MS-A100, manufactured by Mikasa, 1,200 rpm, 30 seconds) and then baked at 100° C. for 30 seconds to form Wafer 1 having provided thereon an adhesive layer with a thickness of 5 μm (that is, adhesive support).

### <Exposure (2)>

From the adhesive layer side of Wafer 1, the adhesive layer was exposed dot-imagewise through a photomask having a dot pattern formed by a light-transmitting region and a light-shielding region and allowing the dot region of the dot pattern to serve as the light-shielding region, by using a UV exposure apparatus (LC8, manufactured by Hamamatsu Photonics K.K.). The exposure was performed by changing the exposure dose and the shape of the dot region (light-shielding region) of the photomask as shown in Table 4 below in each of Examples (in Table 4, the area ratio of the light-transmitting region in each photomask is shown together).

### <Preparation (2) of Test Piece>

Wafer 1 after exposure of the adhesive layer was cut in a rectangle shape of 0.5 cm×2 cm.

A wafer in which nothing is coated on the surface or a wafer having provided therein a protective layer (these wafers are collectively referred to as Wafer 2) was cut in a rectangle shape of 0.5 cm×2 cm. Wafer 1 and Wafer 2 were adhered under pressure of 20 N/cm² such that the region up to 0.5 cm from the longitudinal edge part of the adhesive layer of Wafer 1 overlaps with the region up to 0.5 cm from the longitudinal edge part of Wafer 2 (see, the schematic cross-sectional view of the test piece shown in FIG. 14).

Here, the wafer having provided therein a protective layer is a wafer with a protective layer having a thickness of 20 μm, which was obtained by applying Coating Solution (1) for Protective Layer according to the following formulation on a 4-inch Si wafer by a spin coater (Opticoat MS-A100, manufactured by Mikasa, 1,200 rpm, 30 seconds) and then baking it at 100° C. for 30 seconds.

[Coating Solution (1) for Protective Layer]

| | |
|---|---|
| Clearon P-135 (produced by Yasuhara | 25 parts by weight |
| Chemical Co., Ltd.) | |
| (R)-(+)-Limonene (produced by Wako Pure | 75 parts by weight |
| Chemical Industries, Ltd.) | |

TABLE 3

| | | | | | | | Thermal | | | |
|---|---|---|---|---|---|---|---|---|---|---|
| | Photopoly- | | Poly- | | | | Poly- | | | |
| | merization | | merizable | | | | merization | | | |
| | Initiator | | Compound | | Resin | | Initiator | | Solvent | |
| Adhesive | | Content | | Content | | Content | | Content | | Content |
| Composition | Kind | (g) | Kind | (g) | Kind | (g) | Kind | (g) | Kind | (g) |
| Composition 5 | (1) | 2 | (1) | 25 | (1) | 13 | none | 0 | PGMEA | 60 |
| Composition 6 | (2) | 2 | (1) | 25 | (1) | 13 | none | 0 | PGMEA | 60 |
| Composition 7 | (1) | 2 | (2) | 25 | (1) | 13 | none | 0 | PGMEA | 60 |
| Composition 8 | (1) | 2 | (1) | 25 | (2) | 13 | none | 0 | PGMEA | 60 |
| Composition 9 | (1) | 2 | (1) | 24 | (1) | 12 | (1) | 2 | PGMEA | 60 |

Resin (1): ESTYRENE MS200NT (produced by Nippon Steel Chemical Co., Ltd., MS resin)
Resin (2): NK Oligo EA7440 (produced by Shin-Nakamura Chemical Co., Ltd., novolak resin)
Polymerizable compound (1): A-DCP (produced by Shin-Nakamura Chemical Co., Ltd., bifunctional acrylate)
Polymerizable compound (2): A-BPE-4 (produced by Shin-Nakamura Chemical Co., Ltd., bifunctional acrylate)
Photopolymerization Initiator (1): IRGACURE OXE 02 (produced by BASF)
Photopolymerization Initiator (2): KAYACURE DETX-2 (produced by Nippon Kayaku Co., Ltd., 2,4-dimethylthioxanthone)
Thermal polymerization Initiator (1): PERBUTYL Z (produced by NOF Corporation, tert-butyl peroxybenzoate)
PGMEA: Propylene glycol monomethyl ether acetate

### <Measurement of Adhesive Force>

The shear adhesive force of the test piece prepared above was subjected to tensile measurement under the condition of 250 mm/min in the direction parallel to the adhesion surface by using a tensile tester (manufactured by IMADA). The results are shown in Table 4 below.

<Measurement of Peel Force (not Treated with Solvent)>

The tensile adhesive force of the test piece prepared above was measured by tensile measurement under the condition of 250 mm/min in the direction perpendicular to the adhesion surface by using a tensile tester (manufactured by IMADA). The results are shown in Table 4 below.

<Measurement of Peel Force (Treated with Solvent)>

The test piece prepared above was dipped in the solvent shown in Table 4 for 1 hour and taken out from the solvent, and the solvent was dried at room temperature. The tensile adhesive force of the thus-prepared test piece was measured by tensile measurement under the condition of 250 mm/min in the direction perpendicular to the adhesion surface by using a tensile tester (manufactured by IMADA). The results are shown in Table 4 below.

TABLE 4

| | | | | Area | | | | | |
|---|---|---|---|---|---|---|---|---|---|
| | | | | Ratio of | | | | Species | |
| | | Wafer 2, | | Light- | Exposure | | | of | Peel |
| | | Coating | | Trans- | Dose | | | Solvent | Force |
| | Wafer 1, | Solution for | Shape and Dimension of | mitting | (mJ/cm², | Adhesive | Peel Force | Use for | (N) |
| | Adhesive | Protective | Dot (light-shielding | Region | wavelength = | Force | (N) | Solvent | (solvent- |
| | Composition | Layer | region) of Photomask | (%) | 254 nm) | (N) | (untreated) | Treatment | treated) |
| Example 1 | 5 | | square (one side = 1 mm) | 95 | 1000 | 8.0 | 1.0 | 2-pentanone | 0.5 |
| Example 2 | 6 | | square (one side = 1 mm) | 95 | 1000 | 8.0 | 1.0 | 2-pentanone | 0.5 |
| Example 3 | 7 | | square (one side = 1 mm) | 95 | 1000 | 7.0 | 1.0 | 2-pentanone | 0.5 |
| Example 4 | 8 | | square (one side = 1 mm) | 95 | 1000 | 7.0 | 1.0 | 2-pentanone | 0.5 |
| Example 5 | 9 | | square (one side = 1 mm) | 95 | 1000 | 20.0 | 3.0 | 2-pentanone | 1.5 |
| Example 6 | 5 | (1) | square (one side = 1 mm) | 95 | 1000 | 8.0 | 1.0 | (R)-(+)- | 0.5 |
| | | | | | | | | limonene | |
| Example 7 | 6 | (1) | square (one side = 1 mm) | 95 | 1000 | 8.0 | 1.0 | (R)-(+)- | 0.5 |
| | | | | | | | | limonene | |
| Example 8 | 7 | (1) | square (one side = 1 mm) | 95 | 1000 | 7.0 | 1.0 | (R)-(+)- | 0.5 |
| | | | | | | | | limonene | |
| Example 9 | 8 | (1) | square (one side = 1 mm) | 95 | 1000 | 7.0 | 1.0 | (R)-(+)- | 0.5 |
| | | | | | | | | limonene | |
| Example 10 | 9 | (1) | square (one side = 1 mm) | 95 | 1000 | 20.0 | 3.0 | (R)-(+)- | 1.5 |
| | | | | | | | | limonene | |
| Example 11 | 5 | | square (one side = 1 mm) | 90 | 1000 | 15.0 | 2.0 | 2-pentanone | 1 |
| Example 12 | 5 | | square (one side = 1 mm) | 80 | 1000 | 30.0 | 3.0 | 2-pentanone | 1.5 |
| Example 13 | 5 | | square (one side = 1 mm) | 50 | 1000 | 50.0 | 5.0 | 2-pentanone | 2.5 |
| Example 14 | 5 | | square (one side = 1 mm) | 98 | 1000 | 5.0 | 0.5 | 2-pentanone | 0.3 |
| Example 15 | 5 | | square (one side = 0.1 mm) | 95 | 1000 | 8.0 | 1.0 | 2-pentanone | 0.5 |
| Example 16 | 5 | | square (one side = 2.0 mm) | 95 | 1000 | 8.0 | 1.0 | 2-pentanone | 0.5 |
| Example 17 | 5 | | circular (radius: 0.5 mm) | 95 | 1000 | 8.0 | 1.0 | 2-pentanone | 0.5 |
| Example 18 | 5 | | rhombic (diagonal: 1 mm, | 95 | 1000 | 8.0 | 1.0 | 2-pentanone | 0.5 |
| | | | 2 mm) | | | | | | |
| Example 19 | 5 | | triangular (one side = 1 mm) | 95 | 1000 | 7.0 | 1.0 | 2-pentanone | 0.5 |
| Example 20 | 9 | | square (one side = 0.1 mm) | 95 | 1000 | 8.0 | 1.0 | 2-pentanone | 0.5 |
| Example 21 | 9 | | square (one side = 2.0 mm) | 95 | 1000 | 8.0 | 1.0 | 2-pentanone | 0.5 |
| Example 22 | 9 | | circular (radius: 0.5 mm) | 95 | 1000 | 8.0 | 1.0 | 2-pentanone | 0.5 |
| Example 23 | 9 | | rhombic (diagonal: 1 mm, | 95 | 1000 | 8.0 | 1.0 | 2-pentanone | 0.5 |
| | | | 2 mm) | | | | | | |
| Example 24 | 9 | | triangular (one side = 1 mm) | 95 | 1000 | 7.0 | 1.0 | 2-pentanone | 0.5 |
| Comparative | 5 | | none | 100 | none | 50 | 30 | 2-pentanone | 15 |
| Example 1 | | | | | | | | | |
| Comparative | 5 | | none | 100 | 40 | 2 | 1 | 2-pentanone | 1 |
| Example 2 | | | | | | | | | |
| Comparative | 5 | | none | 100 | 1000 | 0 | 0 | 2-pentanone | 0 |
| Example 3 | | | | | | | | | |

It is seen from Table 4 that when dot-imagewise pattern exposure is performed to define high and low adhesive regions forming a dot pattern as in Examples, the adhesive force in the direction perpendicular to the adhesion surface, which is required at the separation, can be weakened while keeping the adhesive force in the direction parallel to the adhesion surface, which is required at the treatment of the to-be-treated member. Accordingly, a to-be-treated member can be temporarily supported in a reliable and easy manner while suppressing the effect on the treatment accuracy when applying a mechanical or chemical treatment to the to-be-treated member and at the same time, the temporary support for the treated member can be easily released without damaging the treated member.

This application is based on Japanese Patent application JP 2012-046855, filed on Mar. 2, 2012, Japanese Patent application JP 2012-134187, filed on Jun. 13, 2012 and Japanese Patent application JP 2012-232417, filed on Oct. 19, 2012, the entire contents of which are hereby incorporated by reference, the same as if fully set forth herein.

1. A method for manufacturing a semiconductor device with a treated member, comprising:
subjecting an adhesive support having a substrate and an adhesive layer capable of increasing or decreasing in adhesiveness upon irradiation with an actinic ray or radiation to pattern exposure of the adhesive layer to provide a high adhesive region and a low adhesive region in the adhesive layer,
adhering a first surface of a to-be-treated member to the adhesive layer of the adhesive support,
applying a mechanical or chemical treatment to a second surface different from the first surface of the to-be-treated member to obtain a treated member, and detaching the first surface of the treated member from the adhesive layer of the adhesive support.

2. The method for manufacturing a semiconductor device as claimed in claim 1, wherein the pattern exposure is exposure making a central region of the adhesive layer as the low adhesive region and a peripheral region surrounding the central region of the adhesive layer as the high adhesive region.

3. A method for manufacturing a semiconductor device with a treated member, comprising:
preparing an adhesive support having a substrate and an adhesive layer in which a high adhesive region and a low adhesive region are provided to form a dot pattern,
adhering a first surface of a to-be-treated member to the adhesive layer of the adhesive support,
applying a mechanical or chemical treatment to a second surface different from the first surface of the to-be-treated member to obtain a treated member, and
detaching the first surface of the treated member from the adhesive layer of the adhesive support.

4. The method for manufacturing a semiconductor device as claimed in claim 3, wherein the adhesive layer is an adhesive layer capable of increasing or decreasing in adhesiveness upon irradiation with an actinic ray or radiation and the high and low adhesive regions forming the dot pattern are provided by performing dot-imagewise pattern exposure of the adhesive layer.

5. The method for manufacturing a semiconductor device as claimed in claim 4, wherein the dot-imagewise pattern exposure is exposure through a photomask having a dot pattern formed by a light-transmitting region and a light-shielding region.

6. The method for manufacturing a semiconductor device as claimed in claim 1, wherein:
the to-be-treated member comprises a to-be-treated base material and a protective layer provided above the first surface of the to-be-treated base material,
a surface of the protective layer opposite the to-be-treated base material is the first surface of the to-be-treated member, and
a second surface different from the first surface of the to-be-treated base material is the second surface of the to-be-treated member.

7. The method for manufacturing a semiconductor device as claimed in claim 1, wherein the to-be-treated member is a silicon substrate or a compound semiconductor substrate.

8. The method for manufacturing a semiconductor device as claimed in claim 7, wherein the to-be-treated member is a silicon substrate, and the mechanical or chemical treatment comprises a thinning treatment of the silicon substrate.

9. The method for manufacturing a semiconductor device as claimed in claim 1, wherein the to-be-treated member is a silicon substrate having a thickness of 1 to 200 μm.

10. The method for manufacturing a semiconductor device as claimed in claim 7, wherein the to-be-treated member is a compound semiconductor substrate and the compound semiconductor substrate is an SiC substrate, an SiGe substrate, a ZnS substrate, a ZnSe substrate, a GaAs substrate, an InP substrate or a GaN substrate.

11. The method for manufacturing a semiconductor device as claimed in claim 1, wherein the adhesive layer is an adhesive layer capable of decreasing in adhesiveness upon irradiation with an actinic ray or radiation.

12. The method for manufacturing a semiconductor device as claimed in claim 1, wherein the treated member is detached from the adhesive support by sliding the treated member with respect to the adhesive layer of the adhesive support or separating the treated member from the adhesive layer of the adhesive support.

13. The method for manufacturing a semiconductor device as claimed in claim 1, wherein the adhesive layer has a multilayer structure.

14. The method for manufacturing a semiconductor device as claimed in claim 1, wherein the first surface of the treated member is detached from the adhesive layer of the adhesive support without applying any treatment to the adhesive layer of the adhesive support adhering to the treated member.

15. The method for manufacturing a semiconductor device as claimed in claim 1, wherein the adhesive layer contains a photopolymerization initiator and a polymerizable compound.

16. The method for manufacturing a semiconductor device as claimed in claim 15, wherein the adhesive layer further contains a resin.

17. The method for manufacturing a semiconductor device as claimed in claim 15, wherein the adhesive layer further contains a thermal polymerization initiator.
